(19) United States
(12) Patent Application Publication
(10) Pub. No.: US 2024/0356552 A1
(43) Pub. Date: Oct. 24, 2024

(54) LOW CONTENTION CURRENT CIRCUITS

(71) Applicant: Intel Corporation, Santa Clara, CA (US)

(72) Inventors: Steven Hsu, Lake Oswego, OR (US); Amit Agarwal, Hillsboro, OR (US); Ram Krishnamurthy, Portland, OR (US)

(21) Appl. No.: 18/305,147

(22) Filed: Apr. 21, 2023

(51) Int. Cl. H03K 19/0185; G06F 3/06; G11C 11/418; G11C 11/419; H03K 19/21

(52) U.S. Cl. CPC H03K 19/018521; G06F 3/0604; G06F 3/0655; G06F 3/0679; G11C 11/418; G11C 11/419; H03K 19/21

(57) ABSTRACT

A disclosed example includes a read local bitline; and a plurality of pulldown transistor circuits coupled to the read local bitline, a first one of the pulldown transistor circuits including: a first low threshold voltage transistor, the first low threshold voltage transistor including a first drain terminal coupled to the read local bitline; and a second low threshold voltage transistor, the second low threshold voltage transistor including a second drain terminal coupled to a first source terminal of the first low threshold voltage transistor, the second low threshold voltage transistor to persist a voltage level detectable at a gate terminal of the second low threshold voltage transistor, the voltage level representative of a bit of information.

### FIELD OF THE DISCLOSURE

This disclosure relates generally to electrical circuits and, more particularly, to low contention current circuits.

### BACKGROUND

Computing devices and other electronics include semiconductor chips that include large quantities of transistors to form different circuits suitable for different purposes. For example, transistor-based circuits may form cores of central processing units (CPUs), caches of CPUs, registers of CPUs, memories, buffers, etc. Transistors are central to the design of such semiconductor chips because of their configurability and versatility for implementing many different functions.

### BRIEF DESCRIPTION OF THE DRAWINGS

FIG. 1 is a block diagram of an example semiconductor device and a schematic illustration of a transistor that may be used to implement examples disclosed herein.

FIG. 2 is a schematic illustration of a prior static wordline driver.

FIGS. 3A and 3B show schematic illustrations of a prior register file read local bitline (RdLBL) circuit design that trades-off between noise performance and read delay during evaluation phases (e.g., read phases).

FIG. 4 is a schematic illustration of an example wide read local bitline (RdLBL) circuit that includes low threshold voltage (V_{TH}) pulldowns.

FIG. 5 is a schematic illustration of an example RdLBL circuit including a delayed keeper circuit that may be used to generate a long keeper delay.

FIG. 6 is a schematic illustration of an example keeperless RdLBL circuit.

FIG. 7 is a schematic illustration of a prior level-shifting interruptible domino wordline driver.

FIG. 8 is a schematic illustration of a prior level-shifting timing diagram corresponding to the prior level-shifting interruptible domino wordline driver circuit of FIG. 2.

FIG. 9 is a schematic illustration of an example contention-free keeperless domino wordline driver level-shifter circuit.

FIG. 10 is a schematic illustration of an example low-temperature optimized contention-free keeperless domino wordline driver level-shifter circuit.

FIG. 11 is a schematic illustration of an example dual-rail contention-free wordline driver level-shifter circuit.

FIG. 12 is a schematic illustration of an example low-temperature optimized dual-rail contention-free wordline driver level-shifter circuit.

FIG. 13 is a schematic illustration of a prior multi-bit fully keeperless flip-flop circuit.

FIG. 14 is a schematic illustration of an example pseudo-keeperless flip-flop circuit that includes intra-flip-flop shared clock devices.

FIG. 15 is a schematic illustration of another example pseudo-keeperless flip-flop circuit that includes intra-flip-flop shared clock devices.

FIG. 16 is a schematic illustration of an example asynchronous reset pseudo-keeperless flip-flop circuit.

FIG. 17 is a schematic illustration of an example asynchronous preset pseudo-keeperless flip-flop circuit.

FIG. 18 is an example table showing comparisons of example power, performance, and area (PPA) data between prior circuits and example pseudo-keeperless flip-flop circuits disclosed herein in connection with FIGS. 14-17.

FIG. 19 is a block diagram of an example processing platform including processor circuitry that may include examples disclosed herein and is structured to execute example machine-readable instructions and/or perform example operations in accordance with teachings of this disclosure.

FIG. 20 is a block diagram of an example implementation of the processor circuitry of FIG. 19.

FIG. 21 is a block diagram of another example implementation of the processor circuitry of FIG. 19.

FIG. 22 is a flowchart representative of example operations of the example RdLBL circuit based on a delayed keeper circuit of FIG. 5 to generate a long keeper delay.

FIG. 23 is a flowchart representative of example operations of the example dual-rail contention-free wordline driver level-shifter circuit of FIGS. 11 and 12.

FIG. 24 is a flowchart representative of example operations of the example pseudo-keeperless flip-flop circuits of FIGS. 14 and 15.

FIG. 25 is a flowchart representative of example operations of the example asynchronous reset pseudo-keeperless flip-flop circuit of FIG. 16.

FIG. 26 is a flowchart representative of example operations of the example asynchronous preset pseudo-keeperless flip-flop circuit of FIG. 17.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third.” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances, circuit operating tolerances, and/or other real-world imperfections as will be understood by persons of ordinary skill in the art. For example, “approximately” and “about” may indicate that corresponding voltages, electrical currents, electrical power, dimensions, etc. may be within a tolerance range of +/−10% unless otherwise specified in the below description.

As used herein “substantially real time” refers to an occurrence in a near instantaneous manner recognizing there may be real world delays for computing time, transmission, etc. Thus, unless otherwise specified, “substantially real time” refers to being within one second of real time.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

A design challenge of high-performance multi-core microprocessors, discrete graphics processing units (GPUs), digital signal processors (DSPs), and hardware accelerators in servers, desktop computers, laptops, and mobile computing devices is improving power efficiency or operations/watt. However, these same designs still need to meet required performance targets, while operating under a tight power envelope. Lower supply voltage level is a design characteristics (e.g., a knob) having a substantial correlation with reducing power and improving power efficiency in a system. However, lowering supply voltage can result in performance loss due to degradation in transistor-on-state electrical current (I_{ON}). Simultaneous scaling of supply voltage and transistor threshold voltage (V_{TH}) may recuperate the I_{ON} electrical current reduction due to lower supply voltage. However, such a low V_{TH} transistor significantly increases the leakage power component of total power. The selection of transistor threshold voltage (V_{TH}) affects performance of many areas in a semiconductor device including register files, read-only-memory (ROM), cache, and static random access memory (SRAM) in a central processing unit (CPU). A register file is an area in a CPU that temporarily stores data and/or addresses when one or more cores of the CPU are executing instructions or processes. For example, a register file may include a number of registers accessible by a core of the CPU to store dynamically updated information during instruction execution. In some examples, a dynamic register file can be implemented using memory structures such as static random access memory (SRAM). In some examples, a register file memory cell is implemented using eight transistors, while a SRAM memory cell is implemented using six transistors. A ROM is a permanent store subsystem of a CPU that persists information (e.g., data, addresses, instructions, etc.) pertinent to operations of the CPU. In addition, cache and SRAM are also subsystems in a CPU that store information for read and/or write accesses.

Ultra-low-temperature (ULT) operation provides an advantage of increased mobility and a steeper sub-threshold slope, resulting in enhanced transistor I_{ON}/I_{OFF} ratio. For example, the I_{ON}/I_{OFF} ratio is representative of a comparison of electrical-on-state electrical current (I_{ON}) flow through a transistor in its on state relative to electrical-off-state electrical current (I_{OFF}) flow through a transistor in its off state. During the off state of a transistor, any electrical current flow (I_{OFF}) through the transistor is referred to herein as leakage current or contention current. A low V_{TH} transistor operating under ultra-low-voltage (ULV) and ULT conditions results in a process, voltage, temperature (PVT) corner, which can achieve higher iso-performance (e.g., a comparison between circuits that is performed at a fixed performance level) while significantly reducing both dynamic power and leakage power. However, ULT requires extreme low voltage operation and low-power design to keep the overhead costs of cooling at a manageable level. Examples disclosed herein may be used to implement circuits and architectures that enable low supply voltage operation (e.g., reducing the minimum operating supply voltage (V_{MIN}) at which a circuit can operate), low power, and high performance at such low temperatures.

In examples disclosed herein, contention refers to the occurrence of contention current in a circuit resulting from electrical current leakage to ground from a point in a circuit set at a voltage level higher than ground such as a power supply voltage (e.g., VCC). Also, in examples disclosed herein, contention can refer to electrical current leakage between a first point in a circuit set at a first power supply voltage (e.g., a high VCC) and a second point in a circuit set at a second power supply voltage (e.g., a low VCC) that is at a lower voltage than the first power supply voltage.

The active minimum operating supply voltage (V_{MIN}) of a microprocessor core is limited by contention current in read/write circuits of register files, ROMs, SRAMs, etc. across semiconductor device parameter variations (e.g., semiconductor type, doping levels, etc.). The active minimum operating supply voltage (V_{MIN}) degrades with technology scaling due to: a) an increase in voltage level variation, b) sub-par scaling of the minimum device width, and c) increase in p-channel metal-oxide semiconductor (PMOS) strength relative to n-channel metal-oxide semiconductor (NMOS). The minimum operating supply voltage (V_{MIN}) useable in a core of a CPU can be improved by upsizing critical devices or adding a separate higher supply voltage for register file circuitry. To lower minimum operating supply voltage (V_{MIN}) and substantially reduce or eliminate contention current in circuits, examples disclosed herein are based on an extremely low current leakage PVT condition of ULT/ULV design to implement circuits that 1) reduce contention current during a read, 2) improve read delay at low-voltages, and 3) maintain noise associated with V_{MIN} and decrease the delay corresponding to V_{MIN} of read phases, compared to prior register file/ROM implementations without sacrificing semiconductor area. Such low power circuits enable energy-efficient ULT/ULV designs. By employing multiple supply voltages in CPUs, SRAMs can operate on a separate higher supply voltage to allow for non-SRAM logic in which voltage can be further scaled down for additional power savings. For SRAMs implemented in environments having multiple supply voltages, some examples disclosed herein may be used to implement voltage level shifters that can provide a large voltage range between V_{MIN} and the higher SRAM supply voltage while exhibiting substantially reduced or eliminated contention current.

In some integrated circuit designs, clocking is one of the most significant contributors to power consumption and one of the most significant limiters for power-constrained microprocessors and server-on-chip (SoC) designs, discrete/integrated graphics processing units (GPUs) and/or graphics accelerators, and artificial intelligence (AI)/machine-learning (ML) accelerators used for server and/or mobile solutions. Reducing power in systems with tight power budgets improves performance of mobile and/or edge devices by allowing the integration of more cores, memory, and/or processing elements, and by improving battery life. Dynamic clocking power is the largest contributor of power consumption and can consume up to 60% of the overall chip power dissipation, where most of the load is in the final flip-flop circuits.

A flip-flop is a fundamental circuit used in many digital synchronous systems and is often targeted to be the lowest power consumer since it contributes the most to the clocking power. Typically, these flip-flops already utilize minimum sized devices and cannot be further downsized to reduce power. With process technology scaling, circuits are limited by variations to enable low-voltage operation for high energy-efficiency. This limits how small the smallest allowable device size can be, which prevents any further dynamic power savings though transistor size reduction. Performance, power, and area (PPA) benefits are slowing down as process technology scales below the 7 nanometer (nm) regime. As such, examples disclosed herein implement new circuit innovations to improve PPA including, for example, reducing power consumption attributed to clocking.

Examples disclosed herein may be used to reduce power consumption in many circuits including power consumption savings for higher frequency CPUs, graphics, AI accelerators, and any circuits employing deeper pipelines that require more clocking power. In addition, examples disclosed herein may be used in quantum computing and application-specific integrated circuits (ASICs) for cryptocurrency mining. Quantum computing operates at cryogenic temperatures, in which ULT/ULV design may be used to implement examples disclosed herein to reduce contention current in circuits, thereby decreasing power consumption. State-of-the-art cryptocurrency mining accelerators (e.g., Bitcoin mining accelerators) operate at extremely low voltages and can use keeperless circuits to reduce area and power beyond conventional approaches. Due to reductions in leakage of electrical current in low-temperature and cryogenic operations, keeperless flip-flops in accordance with examples disclosed herein may be used to reduce clock power even further.

Although keeperless latches and flip-flops are a good way to reduce power, prior solutions require a minimum operating frequency (e.g., a frequency suitable for a scan) to prevent the state of a circuit from being lost. If latches and flip-flops are clock gated, state can be lost since the gating time can be indefinite. Therefore, while prior keeperless latches and flip-flops may work in ASICs for cryptocurrency mining because it is very deterministic and requires no clock gating, applications like general purpose CPU and graphics processing units (GPUs) cannot utilize these types of circuits due to the randomness and extensive use of clock gating in these systems. Examples disclosed herein enable the use of keeperless flip-flops while providing the ability to clock gate without losing state.

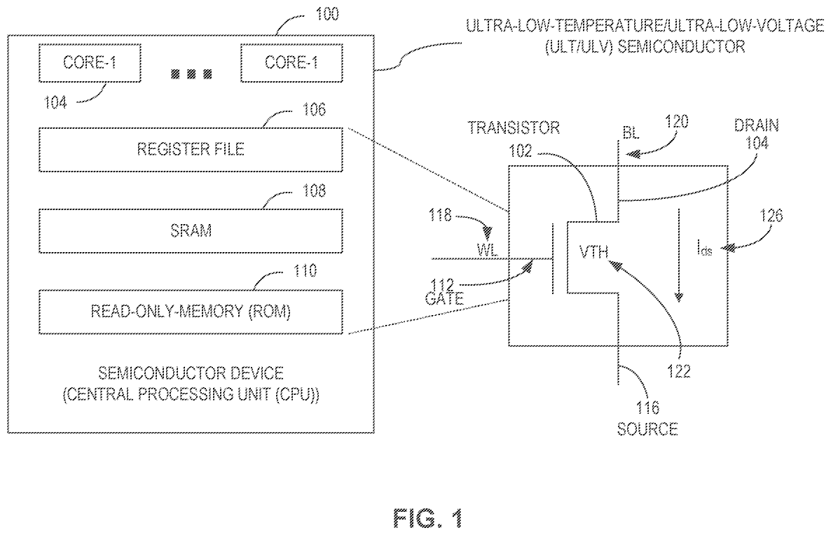

FIG. 1 is a block diagram of an example semiconductor device 100 and a schematic illustration of an example transistor 102 that may be used to implement examples disclosed herein. In example FIG. 1, the semiconductor device 100 is a central processing unit (CPU). However, examples disclosed herein may be implemented on any other type of semiconductor device. For example, the semiconductor device 100 could include and/or be programmable circuitry, processor circuitry, analog circuit(s), digital circuit(s), logic circuit(s), programmable processor(s), programmable microcontroller(s), memory controller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). The example semiconductor device 100 is a multi-core CPU that includes a plurality of cores, one of which is indicated as core 104. The example semiconductor device 100 also includes a register file 106, a static random-access memory (SRAM) 108, and a read-only-memory (ROM) 110. The example core 104 is a logic unit that executes instructions and performs operations on data accessed in, for example, the register file 106, the SRAM 108, and/or the ROM 110. The example register file 106 is an area in a CPU that temporarily stores data and/or addresses when the core(s) 104 of the CPU are executing instructions or processes. For example, the register file 106 may include a number of registers accessible by the core 104 of the semiconductor device 100 (CPU) during instruction execution. The example ROM 110 is a permanent store subsystem of a CPU that persists information (e.g., data, addresses, instructions, etc.) pertinent to operations of the CPU. The example SRAM 108 is also a subsystem of a CPU that stores information for read and/or write accesses. In some examples, SRAM and/or ROM may be implemented separate from a CPU.

The example semiconductor device 100 of FIG. 1 is an ultra-low-temperature (ULT)/ultra-low-voltage (ULV) semiconductor device. In examples disclosed herein, a ULT/ULV semiconductor device (also referred to as a ULT/ULV design) is a semiconductor device fabricated based on doping and material characteristics that enable device operation at ultra-low temperatures such as temperature ranges-40-degrees Celsius and 0-degrees Celsius and/or other temperature ranges below 0-degrees Celsius and ultra-low supply voltages such as 1.3 volts (V) and 0.9V. ULT/ULV semiconductor devices exhibit contention current (e.g., electrical current leakage) through transistors that is substantially lower than in non-ULT/ULV semiconductor devices. The capability of operating at lower supply voltages is based on the lower contention current substantially reducing the rate at which leakage current discharges state from a transistor. In turn, lower supply voltages enable using transistors having lower threshold voltages than prior transistors. For example, a transistor capable of operating at a supply voltage of 1.8 volts (e.g., VCC_{HIGH}=1.8V) has a threshold voltage (V_{TH}) of approximately 700 millivolts (mV), a transistor capable of operating at a lower supply voltage of 1.3V (e.g., VCC_{LOW}=1.3V) has a lower threshold voltage of approximately 500 mV, and a transistor capable of operating at an even lower supply voltage of 0.9V (e.g., VCC_{LOW}=0.9V) has an even lower threshold voltage of approximately 350 mV. In other examples, a transistor capable of operating at a supply voltage of 1.0 volts (e.g., VCC_{HIGH}=1.0V) has a threshold voltage (V_{TH}) of approximately 400 millivolts (mV), a transistor capable of operating at a lower supply voltage of 550 mV (e.g., VCC_{LOW}=550 mV) has a lower threshold voltage of approximately 200 mV, and a transistor capable of operating at an even lower supply voltage of 300 mV (e.g., VCC_{LOW}=300 mV) has an even lower threshold voltage of approximately 100 mV. By implementing examples disclosed herein in ULT/ULV semiconductor devices, lower threshold voltage transistors and lower electrical current leakage reduces power dissipation (e.g., power consumption) in a ULT/ULV semiconductor device relative to non-ULT/ULV semiconductor devices. Reducing power dissipation improves battery charge life of mobile electronics, reduces heat generation of integrated circuit (IC) chips, and can extend the operating life of IC chips.

The example transistor 102 of FIG. 1 represents structure and characteristics of n-channel metal-oxide semiconductor (NMOS) transistors that may be used to implement the core 104, the register file 106, the SRAM 108, the ROM 110, and/or any other circuitry of the semiconductor device 100. The example transistor 102 includes a gate terminal 112, a drain terminal 114, and a source terminal 116. In example FIG. 1, the gate terminal 112 forms a wordline (WL) input 118, and the drain terminal 114 forms a bitline (BL) input terminal 120. The example transistor 102 operates at a particular threshold voltage (V_{TH}) 122. As described above, the value of the V_{TH} 122 depends on the supply voltage level (e.g., VCC_{HIGH}, VCC_{LOW}) at which the transistor 102 is intended to operate. When a voltage level applied at the example gate terminal 112 satisfies (e.g., is greater than) the V_{TH} 122 of the transistor 102 (e.g., the applied voltage level is at logic level high “1”), the transistor 102 is referred to as being in an “on” state and creates a closed circuit between the drain terminal 114 and the source terminal 116 causing drain-to-source electrical current (I_{ds}) 126 to flow along the bitline (BL) 120 between the drain terminal 114 and the source terminal 116 of the transistor 102 (e.g., I_{ds}=I_{ON}). When the voltage level applied to the example gate terminal 112 does not satisfy (e.g., is less than) the V_{TH} 122 of the transistor 102 (e.g., the applied voltage level is at logic level low “0”), the transistor 102 is referred to as being in an “off” state and creates an open circuit between the drain terminal 114 and the source terminal 116 causing drain-to-source electrical current (las) 126 to cease (e.g., I_{ds}=I_{OFF}).

Although not shown in FIG. 1, another type of transistor is a p-channel metal-oxide semiconductor (PMOS) transistor. In examples disclosed herein, PMOS transistors are represented with circles at their gate terminals. The “on” and “off” states of a PMOS transistor are activated based on opposite inputs at its gate terminal relative to the NMOS transistor. For example, when a voltage level applied at the gate terminal of a PMOS transistor satisfies (e.g., is greater than) the V_{TH} of the PMOS transistor (e.g., the applied voltage level is at logic level high “1”), the PMOS transistor is referred to as being in an “off” state, and when a voltage level applied at the gate terminal of the PMOS transistor does not satisfy (e.g., is less than) the V_{TH} of the PMOS transistor (e.g., the applied voltage level is at logic level low “0”), the PMOS transistor is referred to as being in an “on” state.

The “on” states and “off” states in transistors can be used to store digital information (e.g., bits representing either logic “0” or logic “1”) based on the voltage measured as the difference in voltage potential between the drain terminal 114 and the source terminal 116. However, contention current (e.g., leakage of electrical current) through a transistor becomes problematic for holding state over long durations because such contention current causes a transistor charge to deplete over time. Examples disclosed herein may be used to substantially reduce or eliminate contention current in transistor circuits while allowing those circuits to maintain state.

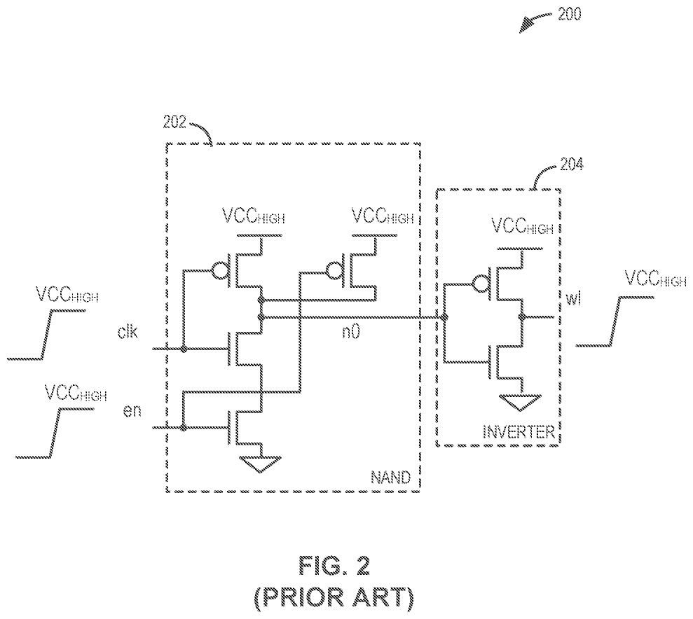

FIG. 2 is a schematic illustration of a prior static wordline driver circuit 200. The prior static wordline driver circuit 200 may be between an address decoder and a memory array in memory or a register file to access data. The prior static wordline driver 200 is a static complimentary metal-oxide semiconductor (CMOS) NAND gate circuit 202 followed by an inverter circuit 204. Prior wordline drivers such as the prior static wordline driver circuit 200 are not able to receive a higher supply voltage (VCC_{HIGH}) at a clock input line (clk) and a lower supply voltage (VCC_{LOW}) at an enable input line (en) because they cannot up-shift read and write wordline voltages (e.g., from VCC_{LOW} to VCC_{HIGH}) without causing a short circuit current.

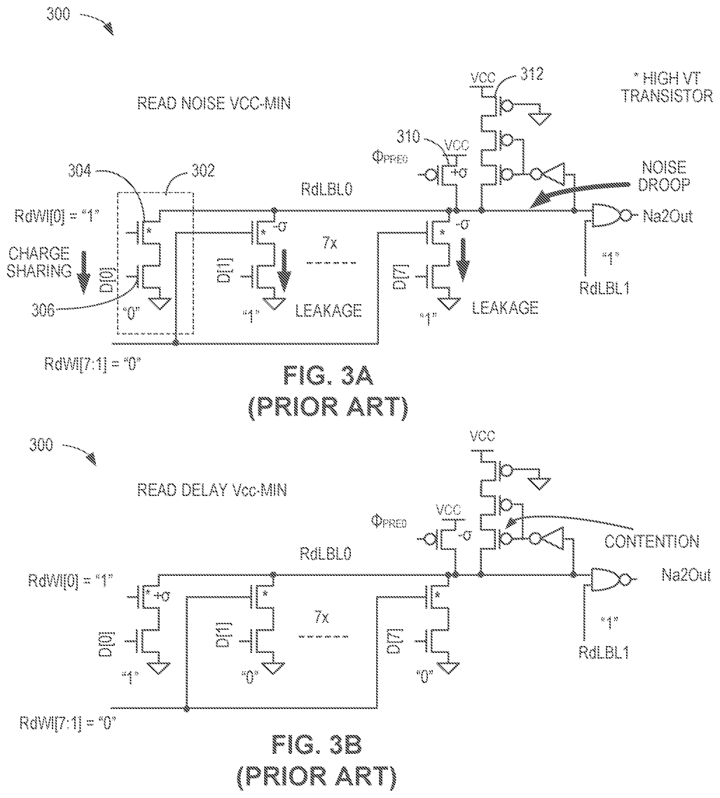

FIGS. 3A and 3B show schematic illustrations of a prior register file read local bitline (RdLBL) circuit 300 that trades-off between noise performance (FIG. 3A) and read delay (FIG. 3B) during evaluation phases (e.g., read phases). As shown in FIG. 3A, the prior RdLBL circuit 300 includes multiple pulldown circuits, one of which is indicated as pulldown circuit 302. The pulldown circuit 302 is a bitline (BL) that includes a RdW1 NMOS transistor 304 coupled to a data cell NMOS transistor 306. The RdW1 NMOS transistor 304 is a high-V_{TH} transistor. Other transistors in FIGS. 3A and 3B noted with an asterisk (*) are also high-V_{TH} transistors. The data cell NMOS transistor 306 is a low-V_{TH} transistor.

The prior RdLBL circuit 300 also includes a pre-charge circuit 310 and a keeper circuit 312. The pre-charge circuit 310 includes a PMOS transistor to gate the application of the supply voltage VCC to the RdLBL circuit 300. The keeper circuit 312 is formed by three PMOS transistors to keep the pulldown circuits charged to the supply voltage VCC.

Performance-critical RdLBL circuits of register file/ROM subsystems are designed using high fan-in wide domino OR circuits to achieve single-cycle read latencies and throughput. The prior RdLBL circuit 300 of FIGS. 3A and 3B shows a worst-case condition of a conventional eight-pulldown-wide register file RdLBL for noise performance (FIG. 3A) and read delay performance (FIG. 3B). Due to the wide domino OR gates, the prior RdLBL circuit 300 is susceptible to electrical current leakage at multiple points in the pulldowns and charge-sharing noise. Charge sharing occurs when electrical charge from one component in a circuit transfers to another component in the circuit, thereby degrading intended voltage levels or signal states in the circuit. In some instances, charge sharing could result in corrupted data. Mitigating for electrical current leakage and charge sharing requires a strong keeper circuit 312 and high-V_{TH} pulldown NMOS circuits in the pulldowns to prevent false evaluations (e.g., when reading logic “0” during a read phase). However, this increases the contention current between the PMOS keeper circuit 312 and the NMOS pulldowns during evaluation (e.g., when reading logic “1” during a read phase), resulting in increased read delay (e.g., read delay push-out). A similar trade-off exists for prior RdLBL circuits of ROM subsystems and SRAM subsystems. These contention currents degrade with variations in device parameters (e.g. transistor threshold voltage, channel length, etc.) and supply voltage scaling (e.g., scaling supply voltage down), limiting performance and the minimum operating supply voltage (V_{MIN}) of register file, ROM, and SRAM subsystems.

FIG. 3A shows a worst-case noise droop scenario in which during an evaluation phase, the RdW1 NMOS transistor 304 of the pulldown circuit 302 is fast and the keeper circuit 312 is slower, creating increased current leakage onto a RdLBL of the prior RdLBL circuit 300. However, since the current leakage is large and the keeper circuit 312 is weak, the keeper circuit 312 is unable to control the increased current leakage to preserve the state of the pulldown circuit 302. This increased current leakage creates the read noise VCC-MIN (e.g., V_{MIN}) limitation of FIG. 3A which can result in false evaluations of the data cell NMOS transistors (e.g., data cell NMOS transistor 306) in the pulldown circuits.

FIG. 3B shows a worst-case contention scenario in which during an evaluation phase, a RdW1 transistor (e.g., the RdW1 NMOS transistor 304 of FIG. 3A) of a pulldown circuit (e.g., the pulldown circuit 302 of FIG. 3A) becomes slow and a keeper circuit (e.g., the keeper circuit 312 of FIG. 3A) becomes faster, and the RdLBL may not be able to fully discharge at low supply voltages, creating a high contention between the keeper circuit and the pulldown circuit. Thus, having a slow pulldown circuit and a faster keeper circuit creates a read delay VCC-MIN (e.g., V_{MIN}) limitation because of contention between the keeper circuit and the pulldown circuits, as shown in FIG. 3B.

In the prior register file RdLBL circuit 300, the worst-case noise droop scenario of FIG. 3A and the worst-case contention scenario of FIG. 3B create a limit on the number of pulldown circuits that can be included in the RdLBL circuit 300. Therefore, increasing the number of pulldown circuits beyond eight is not feasible for proper operation in the prior register file RdLBL circuit 300.

Unlike prior RdLBL circuits such as the prior RDLBL circuit 300 of FIGS. 3A and 3B, example RdLBL circuits disclosed herein make use of an extremely low leakage PVT condition of ULT/ULV design to enable the use of low-V_{TH} pull-downs, wider RdLBL circuits (16-bit width or more), delayed keeper circuits with longer delays relative to prior circuits, and keeperless dynamic RdLBL circuits to lower the contention current during read phases. Examples disclosed herein improve (e.g., decrease) read delay at low voltages and use a smaller semiconductor area while maintaining noise performance at the minimum operating supply voltage (V_{MIN}) relative to prior RdLBL circuits of register files, ROMs, and SRAMs. In addition, examples disclosed herein can be used to enable energy-efficient designs for modern microprocessors, discrete graphics solutions (e.g., GPUs, graphics hardware accelerators, etc.), DSPs, and hardware accelerators in mobile devices, laptop computers, desktop computers, and servers. Such low-power circuits can be used to enable energy-efficient ULT/ULV designs.

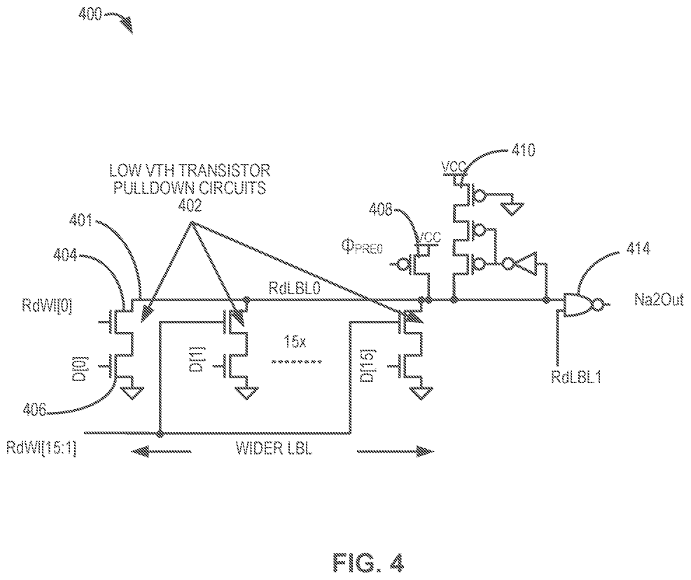

FIGS. 4-6 illustrate example circuits disclosed herein that make use of a low electrical current leakage PVT condition of ULT/ULV design to improve the minimum operating supply voltage (V_{MIN}) (e.g., reduce V_{MIN} and/or reduce noise at V_{MIN}) and improve performance of dynamic register files, ROMs, SRAMs, etc. For example, turning to FIG. 4, an example wide RdLBL circuit 400 including a read local bitline (RdLBL) 401 coupled to 16 pulldown circuits 402 (e.g., bitlines (BLs)) that include 16 data cells (D[0]-D[15]) is capable of storing 16 bits of digital information. A first one of the example pulldown circuits 402 includes a RdW1 NMOS transistor 404 and a data cell NMOS transistor 406. The example RdW1 NMOS transistor 404 includes a drain terminal coupled to the RdLBL 401 and a gate terminal forming a read wordline (RdW1 [0]) input line. The example data cell NMOS transistor 406 includes a drain terminal coupled to a source terminal of the RdW1 NMOS transistor 404. A source terminal of the example data cell NMOS transistor 406 is coupled to ground. The example data cell NMOS transistor 406 also includes a gate terminal forming a data input line (D[0]). A voltage charge at the gate terminal in the example data cell NMOS transistor 406 creates a state persisted and detectable (e.g., by sensing or evaluating) at the gate terminal of the example data cell NMOS transistor 406 to represent a stored bit of digital information. As such, the example data cells (D[0]-D[15]) of the pulldown circuits 402 are register cells or memory cells that persist voltage levels representative of bits of digital information. Although referred to as “data cells”, the example data cells (D[0]-D[15]) of the pulldown circuits 402 may store any type of digital information including data, instructions, addresses, etc.

The example RdW1 NMOS transistor 404 and the other RdW1 NMOS transistors of the pulldown circuits 402 are coupled to corresponding read wordline inputs (RdW1 [0]-RdW1 [15]). The read wordlines (RdW1 [0]-RdW1 [15]) are provided to selectively activate different ones of the example data cells (D[0]-D[15]) to access stored information from one or more of the data lines. The stored digital information in each pulldown circuit 402 can be read (e.g., evaluated) based on appropriate assertions of the RdW1 input signals.

In example FIG. 4, the RdLBL 401 and the 16 pulldown circuits 402 are coupled to a pre-charge circuit (PRE0) 408 and a keeper circuit 410. The example pre-charge circuit 408 includes a PMOS transistor to gate the application of a supply voltage VCC to the RdLBL 401. The example pre-charge circuit 408 allows charging of the pulldown circuits 402 during a pre-charge phase in preparation for an evaluation phase (e.g., a read phase) of the bit values stored in the pulldown circuits 402. That is, the example pre-charge circuit 408 receives a clock signal and is provided to activate the RdLBL circuit 400 in preparation for sensing the voltage levels of the data cell NMOS transistors (e.g., the data cell NMOS transistor 406) forming the example data cells (D[0]-D[15]) in the pulldown circuits 402. Bits stored in the data cells (D[0]-D[15]) are accessed by activating (e.g., pre-charging) the RdLBL circuit 400 and one or more read wordlines (RdW1 [0]-RdW1 [15]) during an evaluation phase. In examples disclosed herein, an evaluation phase (e.g., a read phase) is a time during which voltage charges at the data cells (D[0]-D[15]) are evaluated to determine information stored in the pulldown circuits 402. During the evaluation phase, the activating or pre-charging of the RdLBL circuit 400 and a corresponding read wordline (RdW1) allows drain-to-source current (I_{ds}) (e.g., the drain-to-source electrical current (I_{ds}) 126 of FIG. 1) to flow from a drain terminal to a source terminal of a RdW1 NMOS transistor (e.g., the RdW1 NMOS transistor 404) of an activated pulldown circuit 402 which enables evaluating or sensing the voltage level of a data cell NMOS transistor (e.g., the data cell NMOS transistor 406) at a corresponding data cells (D[0]-D[15]). In this manner, the stored information of that activated data line can be determined based on the gate voltage of the corresponding data cell NMOS transistor. During an evaluation phase, the example RdLBL circuit 400 outputs read data (Na2Out) via a NAND gate 414 which indicates the information bits in the data cells (D[0]-D[15]). The example keeper circuit 410 is formed by three PMOS transistors to keep the pulldown circuits 402 charged to the supply voltage VCC if the evaluated data cell is storing a value of zero (“0”).

The example RdLBL circuit 400 may be employed as a read circuit in register files, memory, and/or storage devices. For example, the example RdLBL circuit 400 may be used to implement a read circuit in memory cells of a dynamic register file and/or SRAM. Additionally or alternatively, the example RdLBL circuit 400 may be used to implement ROM such as flash ROMs, one-time-programmable (OTP) ROMs, and/or any other suitable type of ROMs.

Unlike prior RdLBL circuits that employ smaller-width bit lines such as 8-bit wide RdLBLs, the example wide RdLBL circuit 400 includes low threshold voltage (V_{TH}) transistors in the pulldown circuits 402 to form the 16 data cells (D[0]-D[15]). That is, in example FIG. 4, the RdLBL circuit 400 uses low-V_{TH} NMOS transistors for both RdW1 NMOS transistors (e.g., the RdW1 NMOS transistor 404) and data cell NMOS transistors (e.g., the data cell NMOS transistor 406) of the pulldown circuits 402. The example RdLBL circuit 400 is formed in a ULT/ULV semiconductor device (e.g., the ULT/ULV semiconductor device 100 of FIG. 1) and advantageously employs the low-leakage PVT condition of ULT/ULV semiconductor design to improve the minimum operating supply voltage (V_{MIN}) and performance of dynamic register files, ROMs, SRAMs, etc. That is, since electrical current leakage is substantially lower in ULT/ULV designs relative to non-ULT/ULV designs, the example pulldown circuits 402 of FIG. 4 can be implemented using only low-V_{TH} NMOS transistors without increasing read noise under the minimum operating supply voltage (V_{MIN}). Using low-V_{TH} NMOS transistors makes the pulldown circuits 402 of the example RdLBL circuit 400 stronger, thereby, improving contention current (e.g., substantially reducing or eliminating contention current) in the keeper circuit and improving (e.g., decreasing) read delay of the RdLBL circuit 400 relative to prior RdLBL circuits. In addition, the stronger pulldown circuits 402 enable widening the number of bitlines (BLs) in the RdLBL circuit 400 (e.g., 16-way, 32-way, 64-way domino OR) relative to prior RdLBL circuits (e.g., prior RdLBL circuits having 8-way or smaller LBLs). The wider bit-width of the example RdLBL circuit 400 results in using substantially less semiconductor area to store more bits relative to prior RdLBL circuits. For example, prior RdLBL circuits that have only 8-bit wide LBLs require using a pre-charge circuit and a keeper circuit per each 8-bit LBL. As such, storing 16 bits of digital information in a prior memory circuit requires two pre-charge circuits and two keeper circuits. Unlike such prior RdLBL circuits, the example RdLBL circuit 400 of FIG. 4 can store 16 or more bits, thereby employing only one pre-charge circuit and one keeper circuit for those 16 or more bits. In addition, using low-V_{TH} NMOS transistors for both the RdW1 transistors (e.g., the RdW1 transistor 404) and the data cell transistors (e.g., the data cell transistors 406) in the pulldown circuits 402 substantially reduces or eliminates the need to use dual threshold voltages (V_{TH}) for register file read circuits, ROMs, SRAMs, etc.

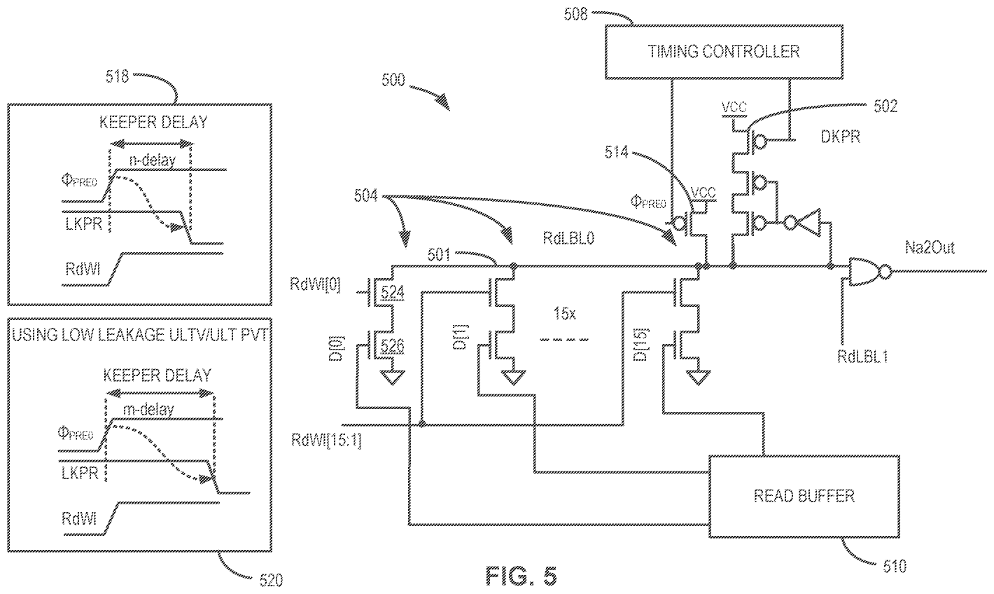

FIG. 5 is a schematic illustration of an example RdLBL circuit 500 that includes a RdLBL 501 coupled to a delayed keeper circuit 502 that may be used to generate a substantially long keeper delay relative to prior RdLBL circuits. The example RdLBL circuit 500 is implemented in a ULT/ULV semiconductor device (e.g., the ULT/ULV semiconductor device 100 of FIG. 1). The example RdLBL circuit 500 may be employed as a read circuit in a memory or storage device. For example, the example RdLBL circuit 500 may be used to implement a read circuit in memory cells of a dynamic register file, ROM, SRAM, etc.

The example RdLBL 501 is coupled to pulldown circuits 504 that form corresponding data cells (D[0], D[1] . . . . D[15]). The example data cells (D[0]-D[15]) are register cells or memory cells that persist voltages representative of bits of digital information. The example pulldown circuits 504 are implemented using low threshold voltage (low-V_{TH}) pulldown NMOS transistor circuits. The example RdLBL 501 is also coupled to a plurality of read wordlines (RdW1 [0]-RdW1 [15]) and a pre-charge circuit (PRE0) 514. The example read wordlines (RdW1 [0]-RdW1 [15]) function substantially similar to the read wordlines (RdW1 [0]-RdW1 [15]) of FIG. 4. The example pre-charge circuit 514 functions substantially similar to the pre-charge circuit 408 of FIG. 4.

The example RdLBL circuit 500 is in circuit with an example timing controller 508 and an example read buffer 510. The example timing controller 508 controls activation and deactivation signaling in the example RdLBL circuit 500 to allow reading information from the example data cells (D[0]-D[15]) in the pulldown circuits 504. The example read buffer 510 is coupled to output lines of the data cells (D[0]-D[15]) to temporarily store/hold values that are read from the data cells (D[0]-D[15]) during an evaluation phase.

Unlike prior RdLBL circuits in which a keeper circuit is always on, allowing contention current for the entirety of an evaluation phase, the keeper circuit 502 of the example RdLBL circuit 500 is a contention-free delayed keeper circuit. As used herein, contention-free refers to a substantially reduced or eliminated contention current. The example keeper circuit 502 is disabled when the timing controller 508 causes an high input (e.g., logic level high (VCC)) to be applied to a DKPR input line and is enabled when the timing controller 508 causes an active-low input (e.g., logic level low (zero volts)) to be applied to the DKPR input line. When the example keeper circuit 502 is disabled, the keeper circuit 502 does not generate significant contention current. However, enabling the example keeper circuit 502 increases the likelihood of the keeper circuit 502 generating contention current. This contention results in slower delay during read evaluation.

To reduce contention current, the example timing controller 508 of FIG. 5 is configured to intermittently activate and deactivate the keeper circuit 502 to decrease the duration during which the keeper circuit 502 can generate contention current. That is, although contention current is generated by the keeper circuit 502 when it is active, contention current is substantially reduced during inactive states of the keeper circuit 502. Unlike prior keeper circuits that are constantly active and generating contention current throughout the operation of a corresponding circuit (e.g., the read local bitline (RdLBL)), the keeper circuit 502 of FIG. 5 can be operated at an active-inactive duty cycle to substantially reduce or eliminate contention current of the keeper circuit 502 during the inactive states.

Since the example keeper circuit 502 is used to retain states of a read local bitline when reading stored bit values of “0” in the transistors forming the example data cells (D[0]-D[15]) in the pulldown circuits 504, the timing controller 508 can activate the keeper circuit 502 periodically but maintain it in an inactive state during parts of the evaluation phases (e.g., read phases) in which values are read from the example data cells (D[0]-D[15]). As such, to substantially reduce or eliminate the likelihood of the keeper circuit 502 generating a substantial amount of contention current during an evaluation phase of the data cells (D[0]-D[15]), the example timing controller 508 can operate the keeper circuit 502 as a contention-free delayed keeper circuit by delaying a duration (e.g., a keeper delay) before activating the keeper circuit 502 (e.g., n-inverter delay) with respect to a pre-charge clock at the pre-charge circuit 514. Such delayed duration allows evaluating the voltage levels at the data cells (D[0]-D[15]) before the keeper circuit 502 turns on and, thus, before the keeper circuit 502 generates substantial contention current when in its active state. When reading stored bit values of one (“1”) from the data cells (D[0]-D[15]), extending the delay duration before the keeper circuit 502 is activated reduces the contention current generated by the keeper circuit 502 and improves (e.g., increases) the amount of read delay available between the time the pre-charge circuit 514 is deactivated and the time by which the voltage levels at the data cells (D[0]-D[15]) must be evaluated to read the information in the data cells (D[0]-D[15]). However, when reading stored bit values of zero (“0”), the RdLBL circuit 500 is floating for the duration of the keeper delay of the keeper circuit 502 and is susceptible to noise droop at drain terminals of RdW1 transistors of the pulldown circuits 504. Although the keeper circuit 502 activates after the keeper delay and recovers the noise droop to bring the RdLBL circuit 500 back to its operating voltage level at the drain terminals of RdW1 transistors of the pulldown circuits 504, such noise droop during the evaluation phase can contribute to inaccurate readings of the bit values stored in the data cells (D[0]-D[15]). Thus, although maximizing the keeper delay for the keeper circuit 502 is desirable to reduce contention current in the keeper circuit 502, setting the keeper delay to a duration that is too long can create undesirable results when reading stored bit values of zero (“0”).

In example FIG. 5, consecutive active states of the keeper circuit 502 are sufficiently close in time to one another (e.g., shorter periods between consecutive active states) to prevent leakage currents through the pulldown circuits 504 from creating enough noise droop to cause false evaluations of the data cells (D[0]-D[15]). Using prior semiconductor materials in which leakage of electrical current is substantially high, the useable duration for the keeper delay gets smaller, especially with variations in supply voltage and supply voltage scaling. An example prior timing diagram 518 shows a relatively short prior “n-delay” which is short for “n-inverters delay.” The “n-inverters delay” is used to activate a keeper circuit in prior semiconductor materials for an evaluation phase between a time at which a timing controller causes de-assertion of a pre-charge circuit (e.g., PRE0 transitions from low to high) and a subsequent time at which the timing controller causes activation of the keeper circuit 502 (e.g., DKPR transitions from high to low). During the evaluation phase, when the keeper circuit 502 is inactive, the pulldown circuits 504 are pulling electrical current charge down in the RdLBL circuit 500, and the keeper circuit 502 is activated based on the “n-inverts delay” to recover the charge and prevent a substantial noise droop in the RdLBL circuit 500 that could corrupt data. An example approximate duration that can be used for “n-inverters delay” in prior semiconductor materials is approximately a five-inverters delay (e.g., a duration for a signal to propagate through five inverters connected in series if the five inverters were implemented using a same semiconductor, a same semiconductor material, and/or a same semiconductor process technology as used for the RdLBL circuit 500). Such prior semiconductor materials limit the improvements for reducing contention current in a delayed keeper circuit because of the need to overcome or compensate for the substantially high leakage of electrical current characteristics of such prior semiconductor materials. This, in turn, limits gains in performance of electrical circuits because keeping a keeper circuit in its active state for longer durations (e.g., a shorter n-inverters delay) increases contention and increases read delay. Substantially high electrical current leakage of prior semiconductor materials also limits the minimum operating supply voltage (V_{MIN}) that can be employed to operate transistors because lower voltage levels will deplete faster through the electrical current leakage, requiring a keeper circuit to be in its active state for longer durations (e.g., a shorter n-inverters delay).

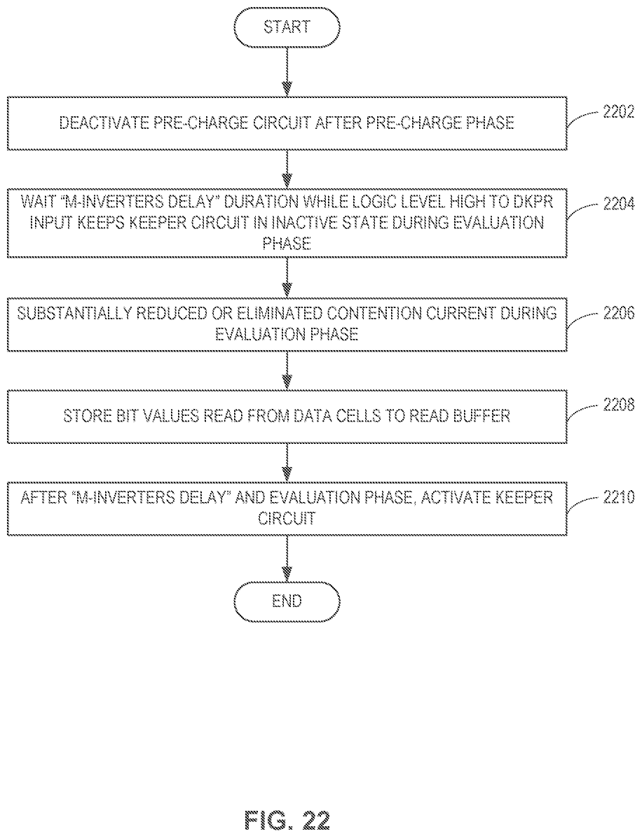

Unlike prior semiconductor materials that have substantially high electrical current leakage, implementing the example RdLBL circuit 500 of FIG. 5 using a ULT/ULV semiconductor enables using a longer keeper delay to increase the duration between consecutive active states of the keeper circuit 502 without decreasing noise robustness and without causing false evaluations of the data cells (D[0]-D[15]) during evaluation phases. This is due to the low leakage of electrical current attributed to the PVT condition of ULT/ULV design. For example, a low-leakage timing diagram 520 in FIG. 5 shows a relatively long “m-delay” which is short for “m-inverters delay.” The “m-inverters delay” is used by the timing controller 508 to delay activation of the keeper circuit 502 in a ULT/ULV semiconductor device. That is, the timing controller 508 uses the “m-inverters delay” to create a relatively longer duration for an evaluation phase between a first time at which the timing controller 508 deactivates the pre-charge circuit 514 (e.g., PRE0 transitions from logic level low to logic level high) and a subsequent, second time at which the timing controller 508 activates the keeper circuit 502 (e.g., DKPR transitions from logic level high to logic level low). During the first time when the timing controller 508 deactivates the pre-charge circuit 514, the keeper circuit 502 is in an inactive state, during which time the keeper circuit 502 does not cause contention. During the evaluation phase between the first time and the second time defined by the “m-inverters delay” (e.g., when both the keeper circuit 502 and the pre-charge circuit 514 are inactive), the read buffer 510 stores values read from the data cells (D[0]-D[15]) of the pulldown circuits 504. An example flowchart representative of example operations of the example RdLBL circuit 500 of FIG. 5 to generate a long keeper delay is described below in connection with FIG. 22.

In example FIG. 5, the “m-inverters delay” corresponding to the keeper circuit 502 in a ULT/ULV semiconductor device is longer than the “n-inverters delay” (e.g., m>n) corresponding to a keeper circuit implemented in prior semiconductor materials that do not include ultra-low-voltage and ultra-low-temperature characteristics. An example approximate duration that can be used for “m-inverters delay” in the RdLBL circuit 500 is approximately seven to nine-inverters delay (e.g., a duration for a signal to propagate through seven, eight, or nine inverters connected in series if the inverters were implemented using a same semiconductor, a same semiconductor material, and/or a same semiconductor process technology as used for the RdLBL circuit 500). This longer “m-inverters delay” increases the amount of time that the keeper circuit 502 is inactive, thereby, reducing the amount of time during which contention current can be generated in the keeper circuit 502. Maintaining the keeper circuit 502 inactive for longer durations in this manner improves both the performance of the RdLBL circuit 500 and the minimum useable operating supply voltage (e.g., V_{MIN}). For example, the performance of the RdLBL circuit 500 is improved because the lower electrical current leakage of a ULT/ULV semiconductor device allows the pulldown circuits 504 to retain voltage charges in the data cells (D[0]-D[15]) for a longer duration (e.g., a longer m-inverters delay) without needing the keeper circuit 502 to be active as long and/or as often. This enables accurate evaluations and readouts of the data cells (D[0]-D[15]) to the read buffer 510 during evaluation phases even when the timing controller 508 keeps the keeper circuit 502 inactive for longer durations (e.g., a longer “m-inverters delay”). The minimum useable operating supply voltage (e.g., V_{MIN}) is also improved because the minimum operating supply voltage (V_{MIN}) that can be employed to operate transistors can be set to a lower voltage level. Such lower voltage level is useable when the example RdLBL circuit 500 is implemented in a ULT/ULV semiconductor device because the lower electrical current leakage of a ULT/ULV semiconductor device depletes electrical charges in the pulldown circuits 504 much slower, allowing the keeper circuit 502 to be in its inactive state for longer durations (e.g., a longer “m-inverters delay”). In examples disclosed herein, the “m-inverters delay” (and the “n-inverters delay”) may be referred to as a number-of-inverters delay that elapse before activating an inverting function of the keeper circuit 502 after a pre-charge clock signal is deactivated (e.g., PRE0 transitions from logic level low to logic level high) to recover noise droop in the RdLBL circuit 500.

In addition, implementing the example RdLBL circuit 500 in a ULT/ULV semiconductor device enables implementing the pulldown circuits 504 using transistors of mixed high and low threshold voltages (V_{TH}) or transistors of all the same low V_{TH}. That is, due to the lower electrical current leakage of a ULT/ULV semiconductor device, the improved minimum useable operating supply voltage (e.g., V_{MIN}) of the example RdLBL circuit 500 allows use of two low-V_{TH} transistors in each pulldown circuit 504. Thus, in some examples, each pulldown circuit 504 can be implemented using two low-V_{TH} transistors. For example, in example FIG. 5, a RdW1 transistor 524 may be a low-V_{TH} transistor to implement a read wordline (RdW1) input line and a data cell transistor 526 may be a low-V_{TH} transistor to implement a data cell (D[0] . . . . D[15]) to persist a voltage value that is representative of a stored bit value and that may be evaluated (e.g., detected or sensed) at its gate terminal. In some such examples, the low-V_{TH} transistors may have V_{TH} values of 500 mV or V_{TH} values of 350 mV or lower V_{TH} values. Alternatively, in other examples, each pulldown circuit 504 can be implemented using a high-V_{TH} transistor and a low-V_{TH} transistor. For example, the RdW1 transistor 524 may be a high-V_{TH} transistor to implement a read wordline (RdW1) input line and the data cell transistor 526 may be a low-V_{TH} transistor to implement a data cell (D[0] . . . . D[15]) to persist a voltage value that is representative of a stored bit value and that may be evaluated (e.g., detected or sensed) at its gate terminal. In some such examples, the high-V_{TH} transistors may have V_{TH} values of 700 mV, and the low-V_{TH} transistors may have V_{TH} values of 500 mV or V_{TH} values of 350 mV or lower.

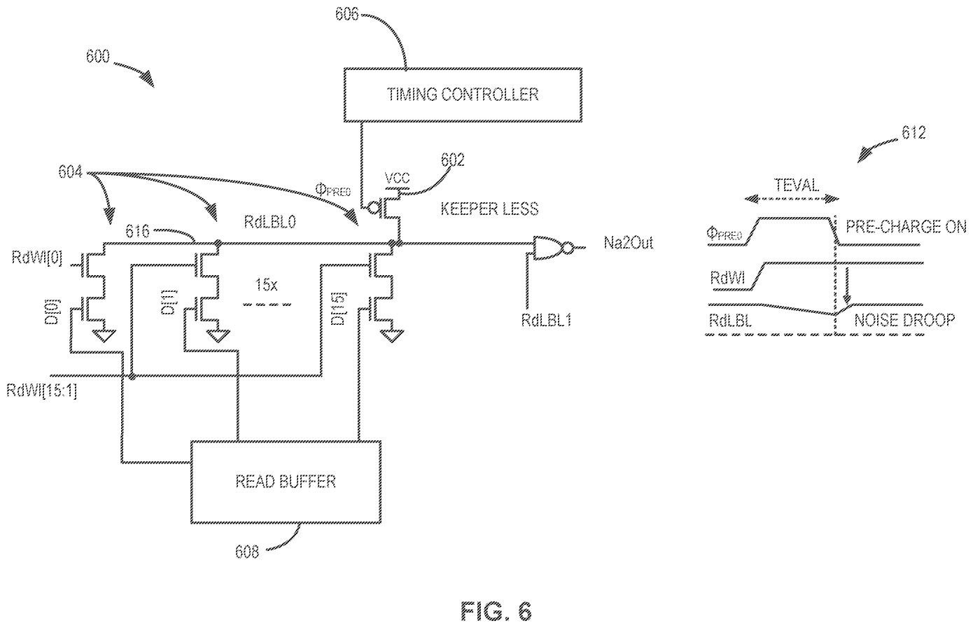

FIG. 6 is a schematic illustration of an example keeperless RdLBL circuit 600. The example keeperless RdLBL circuit 600 is implemented in a ULT/ULV semiconductor device (e.g., the ULT/ULV semiconductor device 100 of FIG. 1) which enables omitting a keeper circuit (e.g., the keeper circuit 502 of FIG. 5). As such, the example keeperless RdLBL circuit 600 is not coupled to a keeper circuit. Eliminating a keeper circuit in the keeperless RdLBL circuit 600 eliminates contention current ordinarily generated by such keeper circuit. This results in a faster RdLBL delay (e.g., a faster RdLBL delay relative to a RdLBL with a keeper circuit) and using lower minimum operating supply voltages (V_{MIN}) during read delays. For example, false evaluations during evaluation phases in RdLBL circuits when a noise condition is present at a minimum operating supply voltage (V_{MIN}) depends on the magnitude of a RdLBL noise droop during the evaluation phase.

In example FIG. 6, the keeperless RdLBL circuit 600 is coupled to a pre-charge circuit 602, pulldown circuits 604, a timing controller 606, and a read buffer 608. The example pre-charge circuit 602 is substantially similar or identical to the pre-charge circuit 514 of FIG. 5. The example pulldown circuits 604 are substantially similar or identical to the pulldown circuits 504 of FIG. 5. FIG. 6 also shows an example timing diagram 612 in which an evaluation phase is labelled as “TEVAL”. After the “TEVAL” duration, the example timing controller 606 causes activation of the pre-charge circuit 602, which causes recovery of noise droop at a RdLBL 616 to bring the keeperless RdLBL circuit 600 back to its operating voltage level. The maximum noise droop depends on the leakage current through the pulldown circuits 604 and the duration of the evaluation phase “TEVAL” during which the pre-charge circuit 602 is off (e.g., inactive). Using prior semiconductor materials in which leakage of electrical current is substantially high, using a “TEVAL” duration that is too long (e.g., a lower frequency than required) results in read failures. However, the low leakage of electrical current attributed to the PVT condition of ULT/ULV design enables using a longer “TEVAL” duration without contributing to RdLBL noise droop, thereby, meeting the required frequency of operation for the keeperless RdLBL circuit 600 and resulting in high-performance evaluations of the data cells (D[0]-D[15]) in the pulldown circuits 604 of the keeperless RdLBL circuit 600. As such, implementing the keeperless RdLBL circuit 600 in a ULT/ULV semiconductor device allows operating the keeperless RdLBL circuit 600 without a keeper circuit and creating an evaluation phase without significant noise droop that would result in false evaluations of the data cells (D[0]-D[15]).

In the keeperless RdLBL circuit 600, the timing controller 606 causes the pre-charge circuit 602 to deactivate at a first time. Subsequently, the example timing controller 606 causes the pre-charge circuit 602 to transition to an active state at a second time (e.g., the second time is after the first time). In example FIG. 6, the duration between the first time and the second time is the evaluation phase during which the values stored in data cells (D[0]-D[15]) of the pulldown circuits 604 are evaluated (e.g., read). The example read buffer 608 stores the values read from the pulldown circuits 604 of the keeperless RdLBL circuit 600 during the evaluation phase. Since noise droop is insignificant during such evaluation phase in the ULT/ULV semiconductor device, the reading of bit values from the data cells (D[0]-D[15]) in the pulldown circuits 604 is more accurate than would be if a keeperless RdLBL circuit were implemented in a non-ULT/ULV semiconductor device.

In addition, implementing the keeperless RdLBL circuit 600 in a ULT/ULV semiconductor device enables implementing the pulldown circuits 604 using transistors of mixed high and low threshold voltages (V_{TH}) or transistors of all the same low threshold voltages (V_{TH}). That is, due to the lower electrical current leakage of a ULT/ULV semiconductor device, the improved useable minimum operating supply voltage (e.g., V_{MIN}) of the keeperless RdLBL circuit 600 allows use of two low-V_{TH} transistors in each pulldown circuit 604. Thus, in some examples, each pulldown circuit 604 can be implemented using two low-V_{TH} transistors in which a RdW1 low-V_{TH} transistor is used for a read wordline (RdW1) input line and a data cell low-V_{TH} transistor is used as a data cell (D[0]-D[15]) to persist a voltage value that is representative of a stored bit value and that may be evaluated (e.g., detected or sensed) at its gate terminal. Alternatively, in other examples, each pulldown circuit 604 can be implemented using a high-V_{TH} transistor and a low-V_{TH} transistor in which the high-V_{TH} transistor is used for a read wordline (RdW1) input line and the low-V_{TH} transistor is used as a data cell (D[0]-D[15]) to persist a voltage value that representative of a stored bit value and that may be evaluated (e.g., detected or sensed) at its gate terminal.

The example timing controller 508 and the example read buffer 510 of FIG. 5 and the example timing controller 606 and the example read buffer 608 of FIG. 6 may be implemented in the example semiconductor device 100 of FIG. 1 or separate from the example semiconductor device 100. In some examples, the timing controller 508 may be combined with the example read buffer 510, and the timing controller 606 may be combined with the read buffer 608. In some examples, the timing controller 508, the example read buffer 510, the timing controller 606, and the read buffer 608 may be implemented by hardware alone or by hardware in combination with software and/or firmware. Thus, for example, any of the timing controller 508, the example read buffer 510, the timing controller 606, and/or the read buffer 608 could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAS.

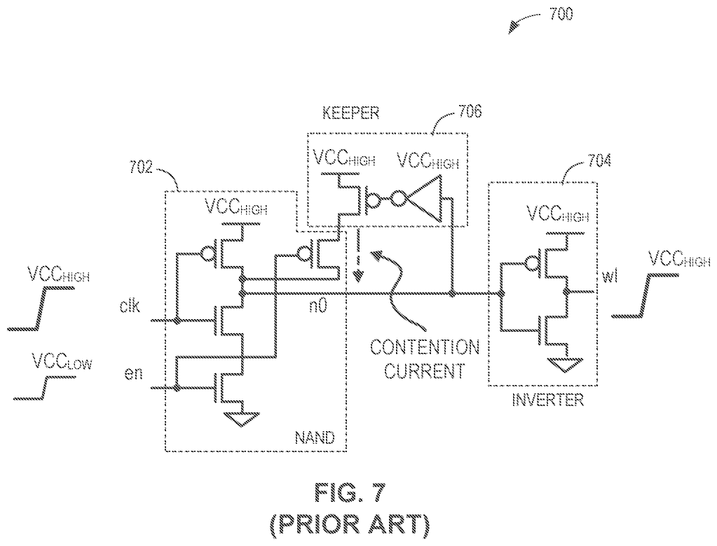

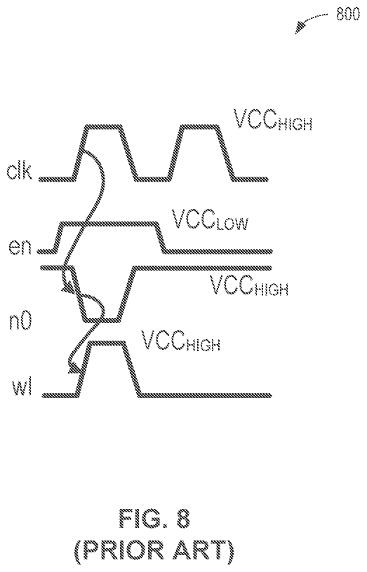

FIG. 7 is a schematic illustration of a prior level-shifting interruptible domino wordline driver circuit 700, and FIG. 8 is a schematic illustration of a prior level-shifting timing diagram 800 corresponding to the prior level-shifting interruptible domino wordline driver circuit 700. The prior level-shifting interruptible domino wordline driver circuit 700 includes a NAND gate circuit 702, an inverter circuit 704, and a keeper circuit 706. The prior level-shifting interruptible domino wordline driver circuit 700 is capable of level-shifting in that it can up-shift voltages between a lower supply voltage (VCC_{LOW}) applied at a wordline driver enable input line (en) and a higher supply voltage (VCC_{HIGH}) applied at a clock input line (clk). The prior level-shifting interruptible domino wordline driver circuit 700 has the same number of gate stages as a prior non-level-shifting wordline driver. However, unlike a prior non-level-shifting wordline driver in which both the clock input line (clk) and the wordline driver enable input line (en) are at the same supply voltage levels, the prior level-shifting interruptible domino wordline driver circuit 700 of FIG. 7 requires the clock input line (clk) to be at a higher supply voltage (VCC_{HIGH}) to eliminate a short circuit electrical current caused by the clock signal. Also, since the wordline driver enable input line (en) is at VCC_{LOW}, there is contention current from the keeper circuit 706 which limits the voltage range of the prior level-shifting interruptible domino wordline driver circuit 700. Although interruptible keeper feedback produced by the keeper circuit 706 does help with the contention current, the keeper circuit 706 does not fully eliminate the contention current. In addition, the prior level-shifting interruptible domino wordline driver circuit 700 of FIG. 7 limits the difference (e.g., the voltage range or distance) between VCC_{HIGH} and VCC_{LOW} because if the difference is too wide of a gap, the prior level-shifting interruptible domino wordline driver circuit 700 cannot overcome the keeper circuit 706 when the wordline driver enable input line (en) transitions to logic level high.

FIG. 8 is a schematic illustration of a prior level-shifting timing diagram 800 corresponding to the prior level-shifting interruptible domino wordline driver circuit 700 of FIG. 7. In FIG. 8, a logic level high signal (e.g., logic “1”) at the enable input line (en) at the low supply voltage (VCC_{LOW}) represents an evaluation phase (e.g., a read phase) for a memory read. During the evaluation phase, a logic-low-to-high transition of the clock input line (clk) at the higher supply voltage (VCC_{HIGH}) discharges a node “no” of the NAND gate circuit 702 from logic level high (e.g., at VCC_{HIGH}) to logic level low (e.g., zero volts) and generates logic level high (e.g., at VCC_{HIGH}) at the wordline (w1) output. However, due to the voltage level separation between VCC_{HIGH} and VCC_{LOW}, this causes leakage of electrical current noted in FIG. 7 as contention current. Thus, prior wordline level-shifting solutions still have contention current, which limits the voltage conversion range that can be achieved between a high supply voltage (VCC_{HIGH}) and a lowest possible supply voltage (VCC_{LOW}). As such, an ability of a prior wordline driver circuit to generate a wordline (w1) output at a high supply voltage (VCC_{HIGH}) based on a clock input line (clk) at the high supply voltage (VCC_{HIGH}) and an enable input line (en) at a low supply voltage (VCC_{LOW}) is limited by the lowest possible minimum operating supply voltage (V_{MIN}) that can be used for the low supply voltage (VCC_{LOW}) without generating an overly significant amount of contention current that exceeds an acceptable power consumption of a circuit. This limits voltage scaling, thereby, preventing the use of lower supply voltages in decoder logic and CPU cores for additional power savings.

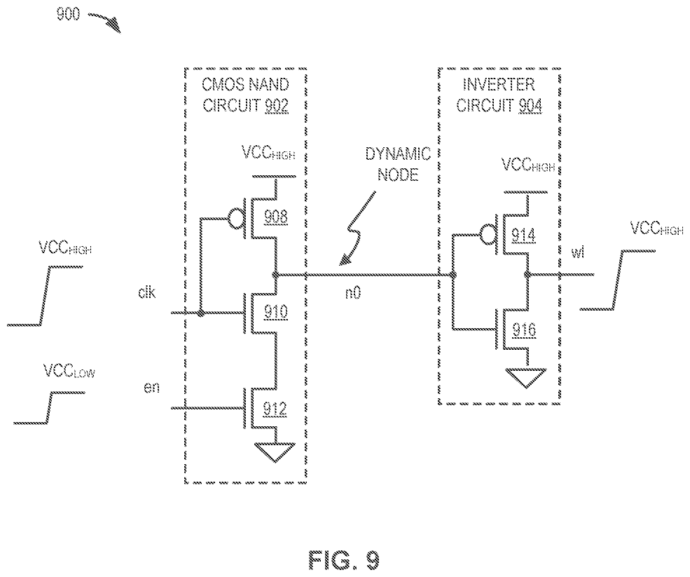

FIGS. 9-12 are schematic illustrations of contention-free wordline driver level-shifter circuits implemented in accordance with teachings of this disclosure that provide improved performance relative to the prior level-shifting interruptible domino wordline driver circuit 700 of FIG. 7. The example contention-free wordline driver level-shifter circuits of FIGS. 9-12 may be used to drive a wordline (w1) of a register file or memory circuit to access data cells in the register file or memory circuit (e.g., during an evaluation phase) in response to, for example, read and/or write requests from a CPU. A level-converting wordline driver implemented in accordance with one or more of the example contention-free wordline driver level-shifter circuits of FIGS. 9-12 takes a VCC_{HIGH} signal at a clock input line (clk) and a VCC_{LOW} signal at a decoded address enable input line (en) and produces an up-shifted read and write wordline (w1) during low supply voltage operation to the VCC_{HIGH} voltage level, without imposing any delay penalty at high-performance and high-voltage operation. In example FIGS. 9-12, the VCC_{HIGH} signal at the clock input line (clk) corresponds to the VCC_{HIGH} supply voltage of memory (e.g., the register file 106, the SRAM 108, the ROM 110 of FIG. 1), and the VCC_{LOW} signal at the decoded address enable input line (en) corresponds to the VCC_{LOW} supply voltage of a CPU core (e.g., the core 104 of FIG. 1). In some examples, to provide voltage level shifting between different voltage levels, the example contention-free wordline driver level-shifter circuits of FIGS. 9-12 are implemented on a ULT/ULV semiconductor material. A circuit may be configured to include two or more subcircuits that operate at different voltage levels to improve power efficiency and/or to satisfy different timing (delay) requirements of those respective subcircuits. For example, a processor may operate a clock line (clk) at a higher voltage level (e.g., VCC_{HIGH}) to satisfy a low noise tolerance at a high clock frequency and/or may run portions of memory at a higher voltage level (e.g., VCC_{HIGH}) to increase memory retention capabilities. The same processor may operate a decoded address enable input line (en) at a relatively lower voltage level (e.g., VCC_{LOW}) based on such decoded address enable input line (en) producing lower noise due to having a lower frequency of switching relative to high-speed clock lines. Such selective use of a lower voltage level (e.g., VCC_{LOW}), in turn, reduces power consumption related to controlling memory accesses.

In some examples, if VCC_{HIGH} is approximately 1.2 volts, transistors in the example contention-free wordline driver level-shifter circuits of FIGS. 9-12 that operate at the VCC_{HIGH} voltage have a threshold voltage (V_{TH}) of approximately 350 millivolts. In such some examples, if VCC_{LOW} is approximately 500 millivolts, transistors in the example contention-free wordline driver level-shifter circuits of FIGS. 9-12 that operate at the VCC_{LOW} voltage have a threshold voltage (V_{TH}) of approximately 350 millivolts. Alternatively, if VCC_{LOW} is approximately 500 millivolts, transistors in the example contention-free wordline driver level-shifter circuits of FIGS. 9-12 that operate at the VCC_{LOW} voltage have an example threshold voltage (V_{TH}) of approximately sub-350 millivolts (e.g., less than 350 millivolts). Of course, transistors with any other suitable threshold voltages may be used to operate at corresponding supply voltages (e.g., high supply voltages (VCC_{HIGH}), low supply voltages (VCC_{LOW}), etc.). Alternative example supply voltage pairings may be VCC_{HIGH}=1.0V and VCC_{LOW}=550 mV, or VCC_{HIGH}=1.0V and VCC_{LOW}=300 mV.

Up-shifting wordlines (e.g., a read w1 and/or a write w1) to VCC_{HIGH} (e.g., in a multi-VCC SRAM) using the example contention-free wordline driver level-shifter circuits of FIGS. 9-12 lowers contention current during read/write operations, improves read/write delay across different voltage levels, and lowers the minimum useable supply voltage (e.g., VCC_{MIN}) relative to prior level-shifting wordline drivers. For example, lowering the minimum useable supply voltage (e.g., VCC_{MIN}) using examples disclosed herein enables using a lower voltage level (e.g., VCC_{LOW}) at the decoded address enable input line (en) while employing a relatively higher voltage level (e.g., VCC_{HIGH}) at the clock input line (en). This is an improvement over prior level-shifting wordline drivers in which the larger the difference between VCC_{HIGH} and VCC_{LOW}, the larger the level-shifting voltage range (e.g., the voltage level conversion range) which increases the likelihood of contention current in a circuit due to the higher propensity for electrical current to leak between the VCC_{HIGH} voltage rail and the VCC_{LOW} voltage rail. Using the example contention-free wordline driver level-shifter circuits of FIGS. 9-12 allows a CPU and SRAM decoder to operate below a minimum operating supply voltage (V_{MIN}) than useable with prior level-shifting wordline drivers such as the prior level-shifting interruptible domino wordline driver circuit 700 of FIG. 7.

The example contention-free wordline driver level-shifter circuits of FIGS. 9-12 enable a dynamic level-shifting wordline driver that is contention-free (e.g., substantially reduced or eliminated contention current) for multi-VCC SRAMs to enable a wide voltage level translation (e.g., a translation between VCC_{HIGH} and VCC_{LOW}). For use in high-performance and high-voltage operations, each of the example contention-free wordline driver level-shifter circuits of FIGS. 9-12 has the same number of gate stages as corresponding conventional wordline drivers in which level conversion is not required and, thus, the example contention-free wordline driver level-shifter circuits of FIGS. 9-12 impose no additional evaluation delay overhead during high voltage, high performance operation. For example, level conversion is not required when the clock input line (clk) and the decoded address enable input line (en) are both operated at the same VCC level (e.g., are both operated at VCC_{HIGH} or are both operated at VCC_{LOW}). However, when one input (e.g., the clock input line (clk)) and another input (e.g., the decoded address enable input line (en)) are operated at different VCC levels (e.g., one is at VCC_{HIGH} and the other at VCC_{LOW}), the example contention-free wordline driver level-shifter circuits of FIGS. 9-12 level shift the wordline to VCC_{HIGH}, eliminating contention at low supply voltages (e.g., VCC_{LOW}) and enabling voltage scaling of an entire CPU core and SRAM decoder. In turn, this lowers the overall power of a corresponding circuit. In addition, since contention current is substantially reduced or eliminated, evaluation delay is improved when VCC_{LOW} is much lower than VCC_{HIGH} (e.g., VCC_{LOW}<<VCC_{HIGH}).

Up-shifting can be used to accommodate circuits that are operated at multiple supply voltage levels. For example, core circuitry of a CPU may be operated at a low supply voltage (e.g., VCC_{LOW}) while memory circuitry is operated at a relatively higher supply voltage (e.g., VCC_{HIGH}). Operating a core at a lower supply voltage decreases power consumption and heat generation during processing intensive operations relative to using higher supply voltages. Operating memory (e.g., SRAM, register files, etc.) at a higher supply voltage improves retention capabilities of memory cells. As such, up-shifting wordlines allows memory cells to be on higher supply voltages (e.g., VCC_{HIGH}) to improve information retention while operating other circuitry (e.g., core circuitry) to run on lower supply voltages (e.g., VCC_{LOW}) to reduce power consumption of processing intensive operations. The example contention-free wordline driver level-shifter circuits of FIGS. 9-12 may be used in any suitable application including new and emerging applications such as low temperature applications, cryogenic applications, and ULV keeperless circuits.

FIG. 9 is a schematic illustration of an example contention-free keeperless domino wordline driver level-shifter circuit 900. The example contention-free keeperless domino wordline driver level-shifter circuit 900 may be implemented in a ULT/ULV semiconductor device (e.g., the ULT/ULV semiconductor device 100 of FIG. 1) to make it suitable for lower temperatures (e.g., temperatures below 0-degrees Celsius, temperatures between −40 and 0-degrees Celsius, etc.) in which electrical current leakage is substantially less than at higher temperatures (e.g., temperatures above 0-degrees Celsius). The substantially lower electrical current leakage allows omitting a keeper circuit from the example contention-free keeperless domino wordline driver level-shifter circuit 900 without creating significant noise droop. The example contention-free keeperless domino wordline driver level-shifter circuit 900 includes a static complementary metal-oxide semiconductor (CMOS) NAND gate circuit 902 coupled to an inverter circuit 904 via dynamic node (n0). The example NAND gate circuit 902 includes clock input circuitry and decoded address enable input circuitry. The example clock input circuitry includes a first PMOS transistor 908 coupled to a first NMOS transistor 910. The decoded address enable input circuitry includes an example second NMOS transistor 912. In the example contention-free keeperless domino wordline driver level-shifter circuit 900, a first gate terminal of the first PMOS transistor 908 is coupled to a second gate terminal of the first NMOS transistor 910 to form a clock input line (clk) of the NAND gate circuit 902. A drain terminal of the example first PMOS transistor 908 is coupled to a high supply voltage (e.g., VCC_{HIGH}), a source terminal of the first PMOS transistor 908 is coupled to a drain terminal of the first NMOS transistor 910, and a source terminal of the first NMOS transistor 910 is coupled to a drain terminal of the second NMOS transistor 912. Also in the example contention-free keeperless domino wordline driver level-shifter circuit 900, a third gate terminal of the second NMOS transistor 912 is coupled to a decoded address enable input (en) of the NAND gate circuit 902, and a source terminal of the second NMOS transistor 912 is coupled to ground.

The example inverter circuit 904 includes a second PMOS transistor 914 and a third NMOS transistor 916. A fourth gate terminal of the example second PMOS transistor 914 and a fifth gate terminal of the third NMOS transistor 916 are coupled to a source terminal of the first PMOS transistor 908 and a drain terminal of the first NMOS transistor 910 at the dynamic node (n0) without being coupled to a keeper circuit. In the example inverter circuit 904, a source terminal of the second PMOS transistor 914 is coupled to a drain terminal of the third NMOS transistor 916 to form a wordline (w1) output line. The example wordline (w1) output can be used to drive a wordline of a register file or memory circuit to access data cells in a register file or memory circuit (e.g., during an evaluation phase) in response to, for example, read and/or write requests from a CPU. Also in the example inverter circuit 904, a drain terminal of the second PMOS transistor 914 is coupled to the high supply voltage (e.g., VCC_{HIGH}) and a source terminal of the third NMOS transistor 916 is coupled to ground. In the example contention-free keeperless domino wordline driver level-shifter circuit 900, the first PMOS transistor 908, the first NMOS transistor 910, and the second NMOS transistor 912 of the NAND gate circuit 902 are implemented using high threshold voltage (high-V_{TH}) transistors.

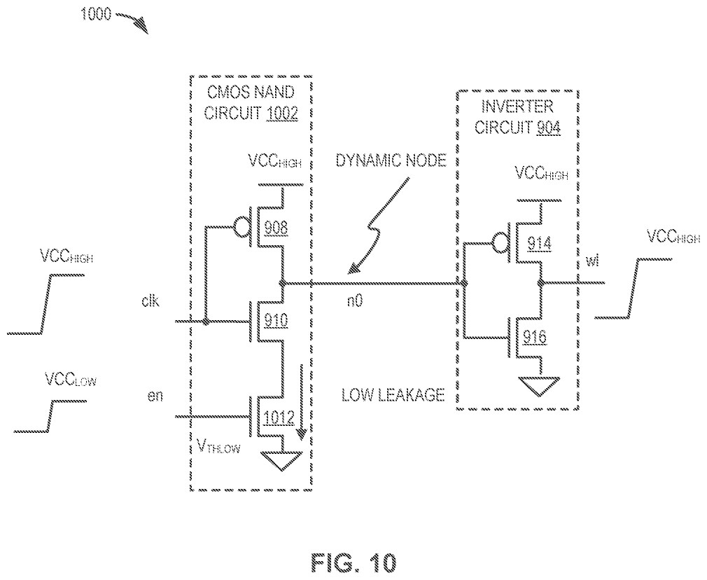

Alternatively, to improve level shifting voltage range, FIG. 10 is a schematic illustration of an example low-temperature optimized contention-free keeperless domino wordline driver level-shifter circuit 1000. The example low-temperature optimized contention-free keeperless domino wordline driver level-shifter circuit 1000 may be implemented by modifying the example contention-free keeperless domino wordline driver level-shifter circuit 900 so that a second NMOS transistor 1012 at the decoded address enable input (en) of a NAND gate circuit 1002 is implemented using a low threshold voltage (low-V_{TH}) transistor. In the example contention-free keeperless domino wordline driver level-shifter circuit 900, the low-V_{TH} transistor 1012 at the decoded address enable input (en) has a lower threshold voltage (e.g., an ultra-low-V_{TH}=sub-350 mV, an ultra-low-V_{TH}=100 mV, etc.) than the high-V_{TH} transistors used to implement the first PMOS transistor 908 and the first NMOS transistor 910 corresponding to the clock input circuitry of the NAND gate circuit 1002. Use of the lower threshold voltage of the low-V_{TH} transistor 1012 at the decoded address enable input (en) is possible because of low-temperature characteristics of a ULT/ULV semiconductor device which exhibits lower electrical current leakage at lower temperatures. The example low-temperature optimized contention-free keeperless domino wordline driver level-shifter circuit 1000 may be used in circuits having multiple supply voltage levels such as a higher supply voltage level (e.g., VCC_{HIGH}) for a clock signal and a relatively lower supply voltage level (e.g., VCC_{LOW}) for register file circuitry, ROM, SRAM, etc. In some examples, the example low-temperature optimized contention-free keeperless domino wordline driver level-shifter circuit 1000 may be implemented with the first PMOS transistor 908 and the first NMOS transistor 910 of the clock input circuitry of the NAND gate circuit 1002 having a first threshold voltage (V_{TH}) of approximately 350 millivolts and with the second NMOS transistor 1012 of the NAND gate circuit 1002 having a second threshold voltage (V_{TH}) of approximately sub-350 millivolts.

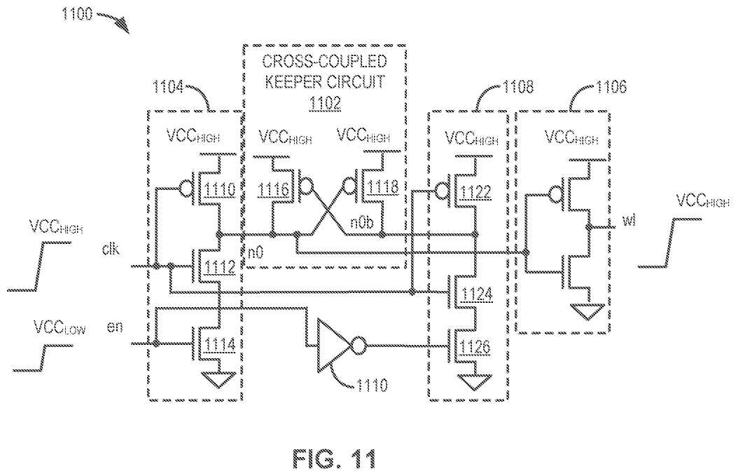

FIG. 11 is a schematic illustration of an example dual-rail contention-free wordline driver level-shifter circuit 1100 that includes a cross-coupled keeper circuit 1102. During an evaluation phase (e.g., a read phase), the example cross-coupled keeper circuit 1102 substantially reduces or eliminates contention current in the example dual-rail contention-free wordline driver level-shifter circuit 1100, thus, providing a wide voltage level conversion range between voltage levels of a clock input line (clk) and a decoded address enable input line (en).

The example dual-rail contention-free wordline driver level-shifter circuit 1100 includes a first PMOS transistor 1110, a first NMOS transistor 1112, and a second NMOS transistor 1114 that form a first NAND gate circuit 1104. In the example dual-rail contention-free wordline driver level-shifter circuit 1100, a first gate terminal of the first PMOS transistor 1110 is coupled to a second gate terminal of the first NMOS transistor 1112 to form the clock input line (clk). Also in the example dual-rail contention-free wordline driver level-shifter circuit 1100, a third gate terminal of the second NMOS transistor 1114 forms the decoded address enable input line (en). A first drain terminal of the second NMOS transistor 1114 is coupled to a first source terminal of the first NMOS transistor 1112.

The example cross-coupled keeper circuit 1102 includes a second PMOS transistor 1116 and a third PMOS transistor 1118. A fifth gate terminal of the third PMOS transistor 1118 is labeled node “n0” and is coupled to a second source terminal of the second PMOS transistor 1116 and a second drain terminal of the first NMOS transistor 1112. In example FIG. 11, the third PMOS transistor 1118 functions as a keeper circuit to hold up or maintain state in the node “n0”. A fourth gate terminal of the second PMOS transistor 1116 is labeled node “n0b” and is coupled to a third source terminal of the third PMOS transistor 1118. In example FIG. 11, the second PMOS transistor 1116 functions as a keeper circuit to hold up or maintain state in the node “nob”. The cross-coupled keeper circuit 1102 enables the dual-rail functionality of the dual-rail contention-free wordline driver level-shifter circuit 1100 because if one of the keepers (e.g., the third PMOS transistor 1118 corresponding to node “n0”) of the cross-coupled keeper circuit 1102 is involved in an evaluation, the other keeper (e.g., the second PMOS transistor 1116 corresponding to node “nob”) of the cross-coupled keeper circuit 1102 remains at the supply voltage (e.g., VCC_{HIGH}). The fifth gate terminal of the third PMOS transistor 1118 is coupled to a wordline (w1) output of the example dual-rail contention-free wordline driver level-shifter circuit 1100. The example wordline (w1) output can be used to drive a wordline of a register file or memory circuit to access data cells in a register file or memory circuit (e.g., during an evaluation phase) in response to, for example, read and/or write requests from a CPU. In the illustrated example, the fifth gate terminal of the third PMOS transistor 1118 is coupled to the wordline (w1) output via an inverter circuit 1106. In the illustrated example, the wordline (w1) output operates as a wordline “w1” of a memory circuit.

The example dual-rail contention-free wordline driver level-shifter circuit 1100 also includes a fourth PMOS transistor 1122, a third NMOS transistor 1124, and a fourth NMOS transistor 1126 that form a second NAND gate circuit 1108. A sixth gate terminal of the fourth PMOS transistor 1122 is coupled to a seventh gate terminal of the third NMOS transistor 1124 and the clock input line (clk). An example inverter circuit 1128 is in circuit between the decoded address enable input line (en) and an eighth gate terminal of the fourth NMOS transistor 1126. A third drain terminal of the fourth NMOS transistor 1126 is coupled to a fourth source terminal of the third NMOS transistor 1124.

In example FIG. 11, the input signal at the clock input line (clk) is at a high supply voltage (e.g., VCC_{HIGH}) and the input signal at the decoded address enable input line (en) is at a low supply voltage (e.g., VCC_{LOW}). For example, a high supply voltage may be 1.1 volts (e.g., VCC_{HIGH}=1.1V) and a low supply voltage may be 500 millivolts (e.g., VCC_{LOW}=500 mV). In such example, the voltage translation range over which the example dual-rail contention-free wordline driver level-shifter circuit 1100 performs level shifting is 0.6V (e.g., voltage translation range=VCC_{HIGH}−VCC_{LOW}). Alternatively, a high supply voltage may be 1.0 volt (e.g., VCC_{HIGH}=1.0V) and a low supply voltage may be 550 millivolts (e.g., VCC_{LOW}=550 mV). In such example, the voltage translation range over which the example dual-rail contention-free wordline driver level-shifter circuit 1100 performs level shifting is 450 mV (e.g., voltage translation range=VCC_{HIGH}−VCC_{LOW}). In example FIG. 11, the first PMOS transistor 1110 and the first NMOS transistor 1112 of the first NAND gate circuit 1104 have high threshold voltages (high-V_{TH}) to operate with a high supply voltage (e.g., VCC_{HIGH}), and the second NMOS transistor 1114 of the first NAND gate circuit 1104 has a low threshold voltage (low-V_{TH}) to operate with a low supply voltage (e.g., VCC_{LOW}). For example, for a high supply voltage of 1.1 volts (e.g., VCC_{HIGH}=1.1V), a high-V_{TH} of the first PMOS transistor 1110 and the first NMOS transistor 1112 is approximately 350 millivolts (mV). In addition, for a low supply voltage of 500 mV (e.g., VCC_{LOW}=500 mV), an example low-V_{TH} of the second NMOS transistor 1114 of the NAND gate circuit 1104 is approximately sub-350 mV. Alternatively, for a high supply voltage of 1.0 volt (e.g., VCC_{HIGH}=1.0V), a high-V_{TH} of the first PMOS transistor 1110 and the first NMOS transistor 1112 is approximately 400 millivolts (mV), and for a low supply voltage of 550 mV (e.g., VCC_{LOW}=550 mV), a low-V_{TH} of the second NMOS transistor 1114 of the NAND gate circuit 1104 is approximately 200 mV.

In operation, when the clock input line (clk) is at logic level low (e.g., logic zero (“0”)), the example dual-rail contention-free wordline driver level-shifter circuit 1100 is in a pre-charge phase, in which node “n0” and node “n0b” both go to logic level high “1” of the high supply voltage (e.g., VCC_{HIGH}). During the pre-charge phase, the wordline output (w1) is de-asserted at logic level low “0”, and it does not matter what logic level is at the decoded address enable input line (en). When the clock input line (clk) transitions to logic level high “1” (e.g., VCC_{HIGH}), the example dual-rail contention-free wordline driver level-shifter circuit 1100 transitions into an evaluation phase (e.g., a read phase). Then, if the decoded address enable input line (en) is set to logic level high “1” to enable the example dual-rail contention-free wordline driver level-shifter circuit 1100, the node “no” at the fifth gate of the third PMOS transistor 1118 of the cross-coupled keeper circuit 1102 discharges to logic level low “0”, thus, making the wordline output (w1) go to logic level high “1”. This causes the cross-coupled keeper circuit 1102 to also keep the node “n0b” at the fourth gate terminal of the second PMOS transistor 1116 of the cross-coupled keeper circuit 1102 at logic level high “1” (e.g., charged to VCC_{HIGH}). In the other case, if the decoded address enable input line (en) is set to logic level low “0” to disable the example dual-rail contention-free wordline driver level-shifter circuit 1100, the node “n0b” at the fourth gate terminal of the second PMOS transistor 1116 of the cross-coupled keeper circuit 1102 transitions to logic level low “0”. This causes the cross-coupled keeper circuit 1102 to maintain the node “n0” at logic level high “1”, and the wordline output (w1) of the example dual-rail contention-free wordline driver level-shifter circuit 1100 transitions to logic level low “0”. As a result, when in the evaluation phase, there is no contention current in the example dual-rail contention-free wordline driver level-shifter circuit 1100, thus, enabling a wide voltage level conversion range between the voltage levels applied to the clock input line (clk) and the decoded address enable input line (en) with substantially little or no electrical current leakage in the example dual-rail contention-free wordline driver level-shifter circuit 1100.

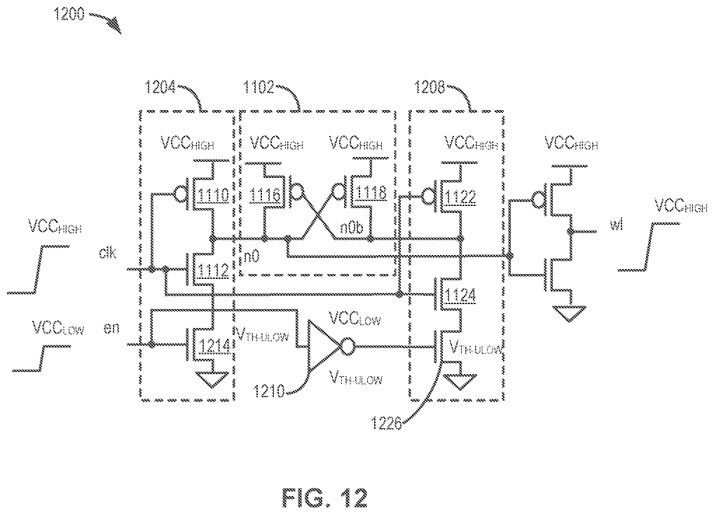

FIG. 12 is a schematic illustration of an example low-temperature optimized dual-rail contention-free wordline driver level-shifter circuit 1200. The example low-temperature optimized dual-rail contention-free wordline driver level-shifter circuit 1200 is similar to the example dual-rail contention-free wordline driver level-shifter circuit 1100 of FIG. 11 except that the example low-temperature optimized dual-rail contention-free wordline driver level-shifter circuit 1200 is optimized through the use of ultra-low-V_{TH} transistors for an even wider voltage translation range relative to the example dual-rail contention-free wordline driver level-shifter circuit 1100 of FIG. 11. In particular, an example second NMOS transistor 1214 of a first example NAND gate circuit 1204 of the example low-temperature optimized dual-rail contention-free wordline driver level-shifter circuit 1200 and a fourth NMOS transistor 1226 of a second example NAND gate circuit 1208 of the example low-temperature optimized dual-rail contention-free wordline driver level-shifter circuit 1200 are implemented using ultra-low-V_{TH} transistors. In addition, an example inverter circuit 1210 between the decoded address enable input line (en) and the gate of the fourth NMOS transistor 1226 is implemented using an ultra-low-V_{TH} inverter circuit.

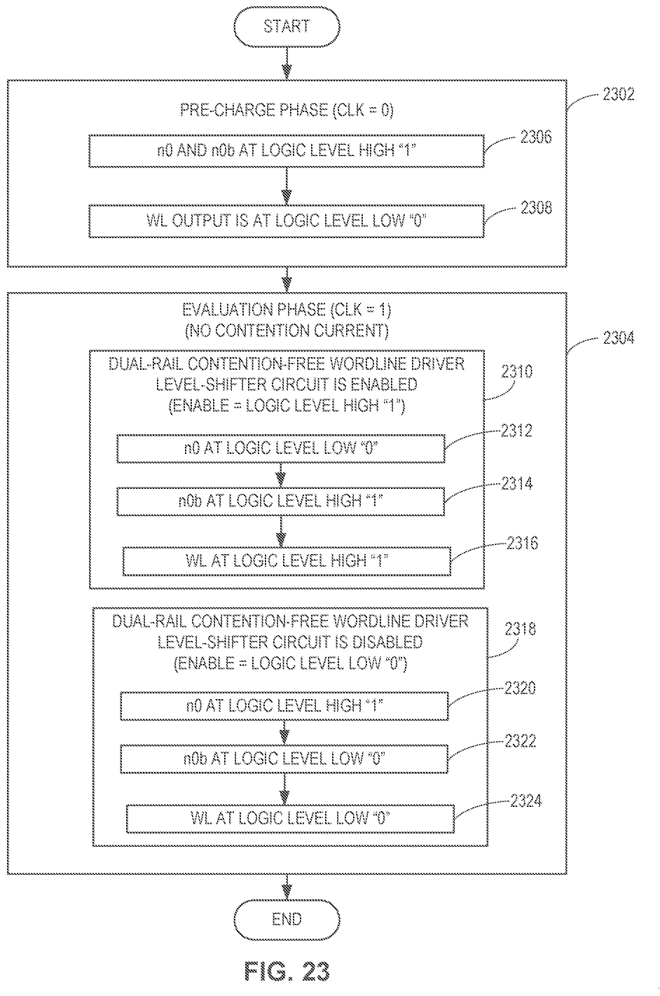

In example FIG. 12, a low supply voltage may be 500 mV (e.g., VCC_{LOW}=500 mV). As such, an example ultra-low-V_{TH} of the second NMOS transistor 1214 of the first NAND gate circuit 1204, the fourth NMOS transistor 1226 of the second NAND gate circuit 1208, and the inverter circuit 1210 is approximately sub-350 mV (e.g., less than 350 mV). In addition, an example higher threshold voltage of approximately 350 mV may be used as the threshold voltages of the other transistors in the example low-temperature optimized dual-rail contention-free wordline driver level-shifter circuit 1200 to work with a relatively higher supply voltage (e.g., VCC_{HIGH}=1.1V). Alternatively, a low supply voltage for example FIG. 12 may be 300 mV for a corresponding ultra-low-V_{TH} of the second NMOS transistor 1214 of the first NAND gate circuit 1204 and the fourth NMOS transistor 1226 of the second NAND gate circuit 1208 of approximately 100 mV, and a higher threshold voltage of approximately 400 mV may be used as the threshold voltages of the other transistors in the example low-temperature optimized dual-rail contention-free wordline driver level-shifter circuit 1200 to work with a relatively higher supply voltage such as VCC_{HIGH}=1.0V. An example flowchart representative of example operations of the example dual-rail contention-free wordline driver level-shifter circuit 1100, 1200 of FIGS. 11 and 12 is described below in connection with FIG. 23.

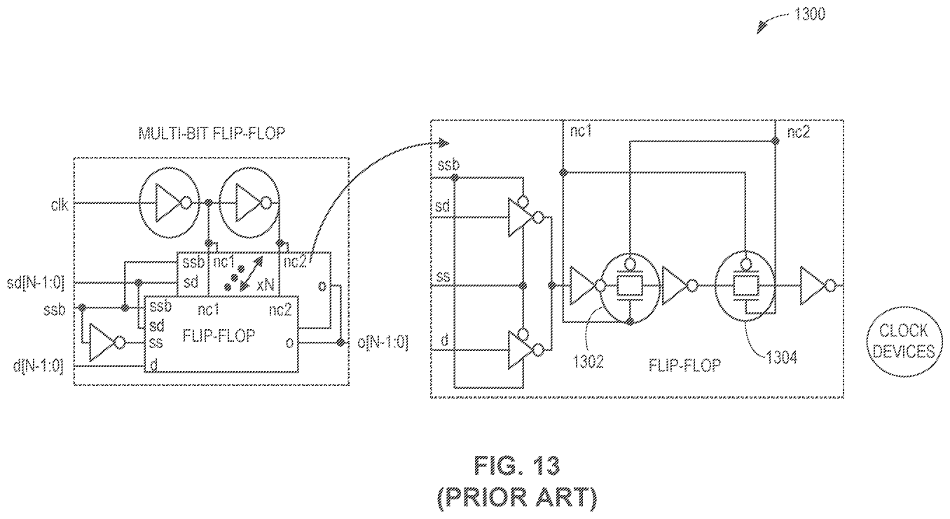

FIG. 13 is a schematic illustration of a prior multi-bit fully keeperless flip-flop circuit 1300. Prior solutions of fully keeperless flip-flops are used to reduce clock power. The prior multi-bit fully keeperless flip-flop circuit 1300 of FIG. 13 enables sharing of local clock inverters to reduce clock power. In FIG. 13, the prior multi-bit fully keeperless flip-flop circuit 1300 includes four clock devices shown as a first transmission gate 1302, which provides two clock devices, and a second transmission gate 1304, which provides an additional two clock devices. Although fully keeperless flip-flops reduce power, they cannot be used in a system where the flip-flops need to be clock gated. That is, prior keeperless flip-flops, such as the prior multi-bit fully keeperless flip-flop circuit 1300 of FIG. 13, require a minimum operating clock frequency to maintain state since there is no keeper circuit to retain state of the flip-flop circuit. Without the minimum operation clock frequency, and without a keeper circuit, the state of the prior multi-bit fully keeperless flip-flop circuit 1300 would eventually leak away, resulting in a loss of state. In addition, prior multi-bit flip-flop circuits have diminishing returns as the number of flip-flops combined exceeds eight.

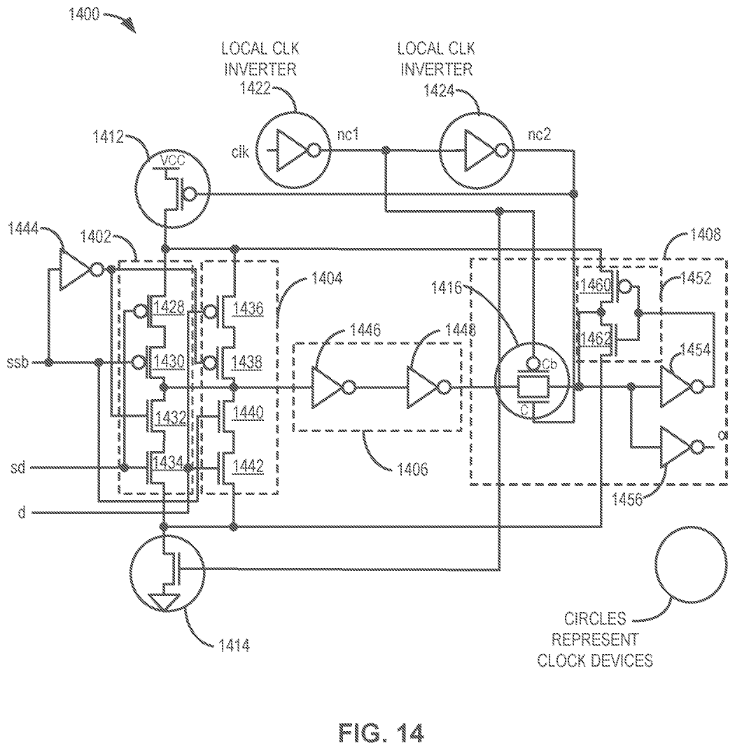

FIGS. 14-17 are schematic illustrations of example pseudo-keeperless flip-flop circuits 1400, 1500, 1600, 1700 that include intra-flip-flop shared clock devices. The example pseudo-keeperless flip-flop circuits 1400, 1500, 1600, 1700 may be implemented in CPUs, GPUs, DSPs, ASICs, FPGAs, hardware accelerators, etc. to implement register files, memory circuits, and/or any other circuit to store logic states (e.g., store digital bit values). The most significant portion of power consumption in a flip-flop device is the clock circuitry, whereas data activities have much lower toggle rates and, thus, lower power consumption. The example pseudo-keeperless flip-flop circuits 1400, 1500, 1600, 1700 of FIGS. 14-17 may be implemented in a ULT/ULV semiconductor device (e.g., the ULT/ULV semiconductor device 100 of FIG. 1) and used to implement shared-clock single-edge triggered flip-flops which only have four internal clock devices (e.g., the same as fully keeperless flip-flops) but have the ability to store state if a clock signal is gated. The example pseudo-keeperless flip-flop circuits 1400, 1500, 1600, 1700 of FIGS. 14-17 reduce clock power of flip-flop devices by: (a) intelligently maintaining the same polarity between primary and secondary state nodes to enable clock sharing between a first latch tri-state multiplexer and a second latch state feedback circuit, and (b) having keeperless operation for ULT/ULV semiconductor devices. Such clock sharing enables reducing the number of internal clock devices from eight to four relative to prior transmission-gate flip-flop circuits. Compared to the prior multi-bit fully keeperless flip-flop circuit 1300 of FIG. 13 which includes four internal clock devices, the number of internal clock devices of the example pseudo-keeperless flip-flop circuits 1400, 1500, 1600, 1700 of FIGS. 14-17 is also four. However, the example pseudo-keeperless flip-flop circuits 1400, 1500, 1600, 1700 of FIGS. 14-17 can store state indefinitely if they are clock gated. As used herein, clock gating is accomplished by routing a clock signal through a first input of a gating circuit (e.g., a NAND gate, an inverter, etc.) and connecting a second input of the gating circuit to a clock enable signal to enable the clock signal to appear at the output of the gating circuit and to disable the clock signal from appearing at the output of the gating circuit.

The example pseudo-keeperless flip-flop circuits 1400, 1500, 1600, 1700 of FIGS. 14-17 are keeperless pass-gate flip-flop circuits with substantially no performance penalty, enabling significant power reduction. Clock sharing cannot be performed arbitrarily within a prior transmission gate flip-flop circuit such as the prior multi-bit fully keeperless flip-flop circuit 1300 of FIG. 13. However, the example pseudo-keeperless flip-flop circuits 1400, 1500, 1600, 1700 of FIGS. 14-17 maintain the same polarity between first and second latch stages which enables the sharing of a primary latch tri-state multiplexer circuit and secondary latch state feedback clock devices without risk of charge-sharing across all combinations of clock and data toggling. Because of this, the states of the example pseudo-keeperless flip-flop circuits 1400, 1500, 1600, 1700 remain undisturbed, and are robust across charge-sharing noise.

Flip-flop circuits are a fundamental and highly used circuit in digital synchronous CPUs, GPUs, and artificial intelligence (AI) accelerators. As clock frequencies increase, clocking power also increases. The example pseudo-keeperless flip-flop circuits 1400, 1500, 1600, 1700 of FIGS. 14-17 are single-edge triggered flip-flop circuits which have only four internal clock transistors and can store state when clock-gated. This enables clock power reduction and usefulness beyond prior keeperless flip-flops such as the prior multi-bit fully keeperless flip-flop circuit 1300 of FIG. 13. The example pseudo-keeperless flip-flop circuits 1400, 1500, 1600, 1700 of FIGS. 14-17 demonstrate iso-performance/iso-area with up to 23.5% power savings using a standard cell library, which directly improves (e.g., reduces) chip-level power dissipation.

The example pseudo-keeperless flip-flop circuit 1400 of FIG. 14 includes a first tri-state multiplexer circuit 1402, a second tri-state multiplexer circuit 1404, a first latch state node 1406 (e.g., a first latch tri-state multiplexer circuit), and a second latch state node 1408 (e.g., a second latch state feedback circuit). Input signals to the example pseudo-keeperless flip-flop circuit 1400 include an active-low scan select signal (ssb), a scan data input signal (sd), a data input signal (d), and a local clock (clk). The active-low scan select signal (ssb) is to activate a line of memory that includes the example pseudo-keeperless flip-flop circuit 1400 for a memory access. The scan data input signal (sd) is to write data to a selected line of memory that includes the example pseudo-keeperless flip-flop circuit 1400. The data input signal (d) provides data to be written to the selected line of memory that includes the example pseudo-keeperless flip-flop circuit 1400. The first latch state node 1406 and the second latch state node 1408 form a datapath between the input signals (ssb, sd, d) and an output line (o) of the example pseudo-keeperless flip-flop circuit 1400. The local clock (clk) is provided from a clock source. In some examples, the clock source that provides the local clock (clk) is coupled to a multi-bit flip flop (MBFF) device in which the pseudo-keeperless flip-flop circuit 1400 is located with other pseudo-keeperless flip-flop circuits. In example FIG. 14, ones of the active-low scan select signal (ssb), the scan data input signal (sd), the data input signal (d), the local clock (clk), and the output line (o) are signal nets (e.g., a network of connections) and/or are dependent on pin values.

The example pseudo-keeperless flip-flop circuit 1400 includes four intra-flip-flop shared clock devices. For example, in FIG. 14, only four clock devices are provided in the example pseudo-keeperless flip-flop circuit 1400. A first clock device is an example PMOS transistor clock device 1412 and a second clock device is an example NMOS transistor clock device 1414. A drain terminal of the example PMOS transistor clock device 1412 is coupled to a voltage supply (VCC), and a source terminal of the NMOS transistor clock device 1414 is coupled to ground. A dual clock device is located in the second latch state node 1408 as an example transmission gate 1416 which includes third and fourth clock devices as opposing transistors (e.g., a PMOS transistor and an NMOS transistor). Two local clock inverters 1422 and 1424 are also shown as clock devices at a local clock input (clk) to the example pseudo-keeperless flip-flop circuit 1400. However, the two local clock inverters 1422 and 1424 are not counted as clock devices of the example pseudo-keeperless flip-flop circuit 1400 since they are shared across multiple flip-flop circuits (e.g., multiple pseudo-keeperless flip-flop circuits similar to the pseudo-keeperless flip-flop circuit 1400) in a multi-bit flip-flop (MBFF) device.

The example transmission gate 1416 is a dual clock source that functions to connect the output of the first latch state node 1406 to the input of the second latch state node 1408 whenever a clock signal to the NMOS gate terminal (C) is at logic level high “1” and a clock signal to the PMOS gate terminal (Cb) is at logic level low “0”. That is, when the clock signal at the NMOS gate terminal (C) of the example transmission gate 1416 is at logic level high “1” and the clock signal at the PMOS gate terminal (Cb) is at logic level low “0”, both of the NMOS and PMOS transistors of the transmission gate 1416 enter into a conducting state. However, when the clock signal at the NMOS gate terminal (C) of the example transmission gate 1416 is at logic level low “0” and the clock signal at the PMOS gate terminal (Cb) is at logic level high “1”, both of the NMOS and PMOS transistors forming the transmission gate 1416 are forced into cutoff, making the transmission gate 1416 an open circuit so that the output of the first latch state node 1406 is disconnected from the input of the second latch state node 1408.

The example first tri-state multiplexer circuit 1402 includes two PMOS transistors 1428, 1430 and two NMOS transistors 1432, 1434. In example FIG. 14, a drain terminal of the PMOS transistor clock device 1412 is coupled to a supply voltage (VCC), a source terminal of the PMOS transistor clock device 1412 is coupled to a drain terminal of the first PMOS transistor 1428, a source terminal of the first PMOS transistor 1428 is coupled to a drain terminal of the second PMOS transistor 1430, a source terminal of the second PMOS transistor 1430 is coupled to a drain terminal of the first NMOS transistor 1432 to form an output of the first tri-state multiplexer circuit 1402, a source terminal of the first NMOS transistor 1432 is coupled to a drain terminal of the second NMOS transistor 1434, and a source terminal of the second NMOS transistor 1434 is coupled to a drain terminal of the NMOS transistor clock device 1414. In example FIG. 14, an input line of the first tri-state multiplexer circuit 1402 is formed by a gate terminal of the first PMOS transistor 1428 coupled to a gate terminal of the second NMOS transistor 1434, which are coupled to the scan data input signal (sd). In example FIG. 14, the gate terminal of the second PMOS transistor 1430 forms an active-low output-enable line that is coupled to the active-low scan select signal (ssb), and the gate terminal of the first NMOS transistor 1432 forms an active-high output-enable line that is coupled to the active-low scan select signal (ssb) via an inverter circuit 1444.

The example second tri-state multiplexer circuit 1404 also includes two PMOS transistors 1436, 1438 and two NMOS transistors 1440, 1442. In example FIG. 14, a source terminal of the PMOS transistor clock device 1412 is coupled to a drain terminal of the first PMOS transistor 1436, a source terminal of the first PMOS transistor 1436 is coupled to a drain terminal of the second PMOS transistor 1438, a source terminal of the second PMOS transistor 1438 is coupled to a drain terminal of the first NMOS transistor 1440 to form an output of the second tri-state multiplexer circuit 1404, a source terminal of the first NMOS transistor 1440 is coupled to a drain terminal of the second NMOS transistor 1442, and a source terminal of the second NMOS transistor 1442 is coupled to a drain terminal of the NMOS transistor clock device 1414. In example FIG. 14, an input line of the second tri-state multiplexer circuit 1404 is formed by a gate terminal of the first PMOS transistor 1436 and a gate terminal of the second NMOS transistor 1442, which are coupled to the data input signal (d). In example FIG. 14, the gate terminal of the second PMOS transistor 1438 forms an active-high output-enable line that is coupled to the active-low scan select signal (ssb) via the inverter circuit 1444, and the gate terminal of the first NMOS transistor 1440 forms an active-low output-enable line that is coupled to the active-low scan select signal (ssb).

The example first latch state node 1406 (e.g., a first latch tri-state multiplexer circuit) includes a first inverter circuit 1446 and a second inverter circuit 1448. The example first latch state node 1406 includes the two inverter circuits 1446, 1448, instead of having just one inverter circuit, to prevent charge sharing between the first latch state node 1406 and the second latch state node 1408. In addition, the first latch state node 1406 is implemented without a keeper circuit (e.g., without being connected to a keeper circuit for the first latch state node 1406). In the example first latch state node 1406, an input of the first inverter circuit 1446 is coupled to outputs of the first and second tri-state multiplexer circuits 1402, 1404 (e.g., coupled to source terminals of the second PMOS transistors 1430 and 1438 of the first and second tri-state multiplexer circuits 1402, 1404), and an output of the first inverter circuit 1446 is coupled to an input of the second inverter circuit 1448. In addition, an output of the second inverter circuit 1448 is coupled to a drain terminal of the transmission gate 1416.

The example second latch state node 1408 (e.g., a second latch state feedback circuit) includes the transmission gate 1416, a keeper circuit 1452, and two inverter circuits 1454, 1456. The example pseudo-keeperless flip-flop circuit 1400 is referred to as “pseudo-keeperless” because although the second latch state node 1408 does include the keeper circuit 1452, the first latch state node 1406 does not include a keeper circuit. In the example second latch state node 1408, a PMOS gate terminal (Cb) of the transmission gate 1416 is coupled to an output of the first local clock inverter circuit 1422 and the gate terminal of the NMOS transistor clock device 1414. In addition, an NMOS gate terminal (C) of the example transmission gate 1416 is coupled to an output of the second local clock inverter circuit 1424 and the gate terminal of the PMOS transistor clock device 1412.

The example keeper circuit 1452 includes a PMOS transistor 1460 coupled to an NMOS transistor 1462. A drain terminal of the example PMOS transistor 1460 is coupled to drain terminals of the first PMOS transistors 1428, 1436 of the first and second tri-state multiplexers 1402, 1404. A source terminal of the example PMOS transistor 1460 is coupled to a drain terminal of the NMOS transistor 1462, a source terminal of the transmission gate 1416, and inputs of the inverter circuits 1454, 1456. A source terminal of the example NMOS transistor 1462 is coupled to the source terminals of the second NMOS transistors 1434, 1442 of the first and second tri-state multiplexer circuits 1402, 1404. The gate terminal of the example PMOS transistor 1460 and the gate terminal of the NMOS transistor 1462 are coupled to an output of the first inverter circuit 1454. An output of the second inverter circuit 1456 provides the output (o) of the example pseudo-keeperless flip-flop circuit 1400.

The example pseudo-keeperless flip-flop circuit 1400 of FIG. 14 can store state indefinitely if it is clock gated. During operation of the example pseudo-keeperless flip-flop circuit 1400, when the local clock input (clk) is off, the intra-flip-flop clock devices (e.g., the PMOS transistor clock device 1412, the NMOS transistor clock device 1414, and the transmission gate 1416) that are in circuit with the first latch state node 1406 and the second latch state node 1408 are shared, thereby fully activating the keeper circuit 1452 in the second latch state node 1408 to store data without a clock signal from the local clock (clk) (e.g., store the data indefinitely). Since the clock devices (e.g., the PMOS transistor clock device 1412, the NMOS transistor clock device 1414, and the transmission gate 1416) are shared in the pseudo-keeperless flip-flop circuit 1400, the example pseudo-keeperless flip-flop circuit 1400 still has only four internal clock devices, which is similar to fully keeperless flip-flops (e.g., the prior multi-bit fully keeperless flip-flop circuit 1300 of FIG. 13). The sharing of the clock devices (e.g., the PMOS transistor clock device 1412, the NMOS transistor clock device 1414, and the transmission gate 1416) in this manner prevents charge sharing between the first latch state node 1406 and the second latch state node 1408, and the example pseudo-keeperless flip-flop circuit 1400 is fully static when the local clock (clk) is gated (e.g., a clock signal from the local clock (clk) is blocked from the example pseudo-keeperless flip-flop circuit 1400). For example, charge sharing occurs when electrical charge from one component in a circuit transfers to another component in the circuit, thereby degrading intended voltage levels or signal states in the circuit. The reduced number of clock devices from eight to four directly translates into cell-level power reduction and chip-level power reduction.

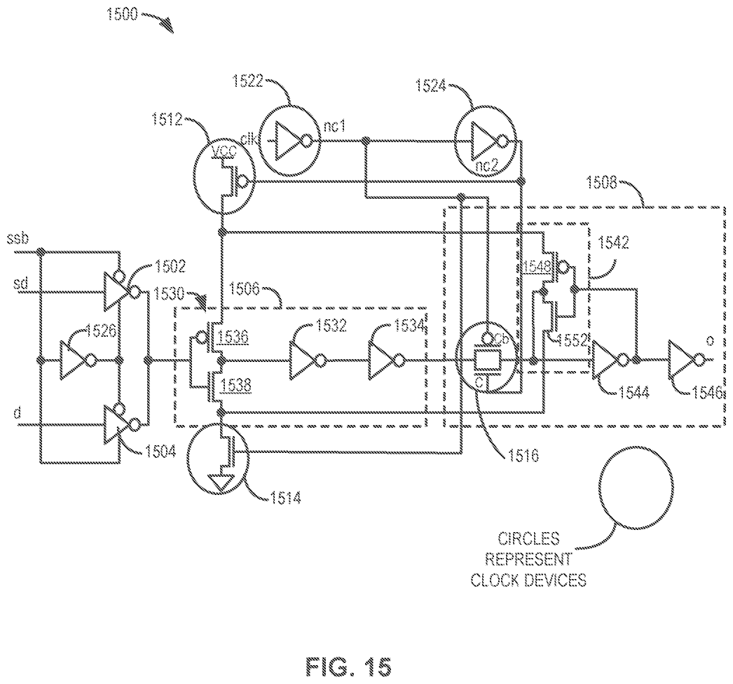

An alternate example of the example pseudo-keeperless flip-flop circuit 1400 of FIG. 14 is shown in FIG. 15 as an example pseudo-keeperless flip-flop circuit 1500 that includes intra-flip-flop shared clock devices. The example pseudo-keeperless flip-flop circuit 1500 uses an additional inverter in the datapath relative to the example pseudo-keeperless flip-flop circuit 1400 and has the same functionality as the example pseudo-keeperless flip-flop circuit 1400. Both of the example pseudo-keeperless flip-flop circuit 1400 of FIG. 14 and the example pseudo-keeperless flip-flop circuit 1500 of FIG. 15 are compatible with existing multi-bit flip-flop techniques, falling-edge triggered designs, and set/reset configurations. Both of the example pseudo-keeperless flip-flop circuits 1400, 1500 are able to reduce power dissipation relative to prior multi-bit flip-flop techniques.

Turning in detail to FIG. 15, the example pseudo-keeperless flip-flop circuit 1500 includes a first tri-state multiplexer circuit 1502, a second tri-state multiplexer circuit 1504, a first latch state node 1506 (e.g., a first latch tri-state multiplexer circuit), and a second latch state node 1508 (e.g., a second latch state feedback circuit). Input signals to the example pseudo-keeperless flip-flop circuit 1500 include an active-low scan select signal (ssb), a scan data input signal (sd), a data input signal (d), and a local clock (clk), which are as described above in connection with FIG. 15. The first latch state node 1506 and the second latch state node 1508 form a datapath between the input signals (ssb, sd, d) and an output line (o) of the example pseudo-keeperless flip-flop circuit 1500. In example FIG. 15, ones of the active-low scan select signal (ssb), the scan data input signal (sd), the data input signal (d), the local clock (clk), and the output line (o) are signal nets (e.g., a network of connections) and/or are dependent on pin values.

The example pseudo-keeperless flip-flop circuit 1500 includes four intra-flip-flop shared clock devices. For example, in FIG. 15, only four clock devices are provided in the example pseudo-keeperless flip-flop circuit 1500. A first clock device is an example PMOS transistor clock device 1512 and a second clock device is an example NMOS transistor clock device 1514. A drain terminal of the example PMOS transistor clock device 1512 is coupled to a voltage supply (VCC), and a source terminal of the NMOS transistor clock device 1514 is coupled to ground. A dual clock device is located in the second latch state node 1508 as an example transmission gate 1516 which includes third and fourth clock devices as opposing transistors (e.g., a PMOS transistor and an NMOS transistor). The example transmission gate 1516 operates similar to the example transmission gate 1416 as described above in connection with FIG. 14. Two local clock inverters 1522 and 1524 are also shown as clock devices at clock inputs to the example pseudo-keeperless flip-flop circuit 1500. However, the two local clock inverters 1522 and 1524 are not counted as clock devices of the example pseudo-keeperless flip-flop circuit 1500 since they are shared across multiple flip-flop circuits (e.g., multiple pseudo-keeperless flip-flop circuits similar to the pseudo-keeperless flip-flop circuit 1500) in a multi-bit flip-flop (MBFF) device.

Each of the example tri-state multiplexer circuits 1502, 1504 includes an active-low output-enable line, an active-high output-enable line, an input line, and an output line. In the example first tri-state multiplexer circuit 1502, the active-low output-enable line is coupled to an active-low scan select signal (ssb), the active-high output-enable line is coupled to the active-low scan select signal (ssb) via an inverter circuit 1526, the input line is coupled to a scan data input signal (sd), and the output line is coupled to the first latch state node 1506. In the example second tri-state multiplexer circuit 1504, the active-low output-enable line is coupled to the active-low scan select signal (ssb) via the inverter circuit 1526, the active-high output-enable line is coupled to the active-low scan select signal (ssb), the input line is coupled to the data input signal (d), and the output line is coupled to the first latch state node 1506.

The example first latch state node 1506 (e.g., a first latch tri-state multiplexer circuit) includes three inverter circuits 1530, 1532, 1534. The multiple inverter circuits 1530, 1532, 1534 in the example first latch state node 1506 (e.g., instead of having just one inverter circuit in the example first latch state node 1506) prevent charge sharing between the first latch state node 1506 and the second latch state node 1508. In addition, the first latch state node 1506 is implemented without a keeper circuit (e.g., without being connected to a keeper circuit for the first latch state node 1506). The example first inverter circuit 1530 is implemented as a reverse tri-state inverter circuit. In the example first inverter circuit 1530, gate terminals of a PMOS transistor 1536 and an NMOS transistor 1538 form an input of the first inverter circuit 1530 and are coupled to the output lines of the tri-state multiplexer circuits 1502, 1504. A drain terminal of the PMOS transistor 1536 is coupled to a source terminal of the PMOS transistor clock device 1512 and a source terminal of the PMOS transistor 1536 is coupled to a drain terminal of the NMOS transistor 1538. In the example first inverter circuit 1530, the source terminal of the PMOS transistor 1536 and the drain terminal of the NMOS transistor 1538 are the active-high and active-low output enable lines of the first inverter circuit 1530. A source terminal of the NMOS transistor 1538 is coupled to a drain terminal of the NMOS transistor clock device 1514. An input line of the second inverter circuit 1532 is coupled to the source terminal of the PMOS transistor 1536 and the drain terminal of the NMOS transistor 1538. An output line of the second inverter circuit 1532 is coupled to an input line of the third inverter circuit 1534. An output line of the third inverter circuit 1534 is coupled to a drain terminal of the transmission gate 1516.

The example second latch state node 1508 (e.g., a second latch state feedback circuit) includes the transmission gate 1516, a keeper circuit 1542, and two inverter circuits 1544, 1546. The example pseudo-keeperless flip-flop circuit 1500 is referred to as “pseudo-keeperless” because although the second latch state node 1508 does include the keeper circuit 1542, the first latch state node 1506 does not include a keeper circuit. In the example second latch state node 1508, a PMOS gate terminal (Cb) of the transmission gate 1516 is coupled to an output of the first local clock inverter circuit 1522 and the gate terminal of the NMOS transistor clock device 1514. In addition, an NMOS gate terminal (C) of the example transmission gate 1516 is coupled to the second local clock inverter circuit 1524 and the gate terminal of the PMOS transistor clock device 1512.

The example keeper circuit 1542 includes a PMOS transistor 1548 coupled to an NMOS transistor 1552. A drain terminal of the example PMOS transistor 1548 is coupled to a drain terminal of the first PMOS transistor 1536 of the first inverter circuit 1530 in the first latch state node 1506 and a source terminal of the PMOS transistor clock device 1512. A source terminal of the example PMOS transistor 1548 is coupled to a drain terminal of the NMOS transistor 1552, with a source terminal of the transmission gate 1516, and with an input line of the inverter circuit 1544. A source terminal of the example NMOS transistor 1552 is coupled to the source terminal of the NMOS transistor 1538 of the first latch state node 1506 and a drain terminal of the NMOS transistor clock device 1514. The gate terminal of the PMOS transistor 1548 and the gate terminal of the NMOS transistor 1552 are coupled to an output of the first inverter circuit 1544 and an input of the second inverter circuit 1546. An output of the second inverter circuit 1546 provides the output (o) of the example pseudo-keeperless flip-flop circuit 1500.

The example pseudo-keeperless flip-flop circuit 1500 of FIG. 15 can store state indefinitely if it is clock gated. During operation of the example pseudo-keeperless flip-flop circuit 1500, when the local clock input (clk) is off, the clock devices (e.g., the PMOS transistor clock device 1512, the NMOS transistor clock device 1514, and the transmission gate 1516) that are in circuit with the first latch state node 1506 and the second latch state node 1508 are shared, thereby fully activating the keeper circuit 1542 in the second latch state node 1508 to store data without a clock signal from the local clock (clk) (e.g., store the data indefinitely). Since the clock devices (e.g., the PMOS transistor clock device 1512, the NMOS transistor clock device 1514, and the transmission gate 1516) are shared in the pseudo-keeperless flip-flop circuit 1500, the example pseudo-keeperless flip-flop circuit 1500 still has only four internal clock devices, which is similar to fully keeperless flip-flops (e.g., the prior multi-bit fully keeperless flip-flop circuit 1300 of FIG. 13). The sharing of the clock devices (e.g., the PMOS transistor clock device 1512, the NMOS transistor clock device 1514, and the transmission gate 1516) in this manner prevents charge sharing between the first latch state node 1506 and the second latch state node 1508, and the example pseudo-keeperless flip-flop circuit 1500 is fully static when the local clock (clk) is gated (e.g., a clock signal from the local clock (clk) is blocked from the example pseudo-keeperless flip-flop circuit 1500). For example, charge sharing occurs when electrical charge from one component in a circuit transfers to another component in the circuit, thereby degrading intended voltage levels or signal states in the circuit. The reduced number of clock devices from eight to four directly translates into cell-level power reduction and chip-level power reduction.

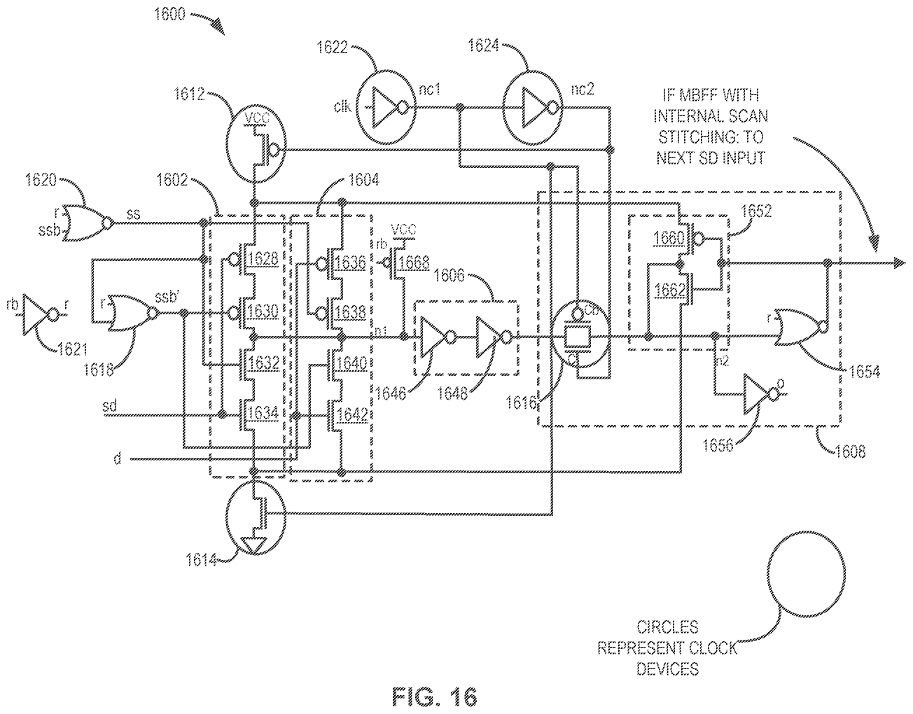

FIG. 16 is a schematic illustration of an example asynchronous reset pseudo-keeperless flip-flop circuit 1600. The example asynchronous reset pseudo-keeperless flip-flop circuit 1600 is controllable to reset its state so that an output (o) is forced to logic level low “0”. The example asynchronous reset pseudo-keeperless flip-flop circuit 1600 includes a first tri-state multiplexer circuit 1602, a second tri-state multiplexer circuit 1604, a first latch state node 1606 (e.g., a first latch tri-state multiplexer circuit), and a second latch state node 1608 (e.g., a second latch state feedback circuit). Input signals to the example asynchronous reset pseudo-keeperless flip-flop circuit 1600 include an active-high reset signal (r), an active-low reset signal (rb), an active-low scan select signal (ssb), a scan data input signal (sd), a data input signal (d), and a local clock (clk). The active-high reset signal (r) and the active-low reset signal (rb) are to reset a state (e.g., a stored bit) of the example asynchronous reset pseudo-keeperless flip-flop circuit 1600. The active-low scan select signal (ssb) is to activate a line of memory that includes the example asynchronous reset pseudo-keeperless flip-flop circuit 1600 for a memory access. The scan data input signal (sd) is to write data to a selected line of memory that includes the example asynchronous reset pseudo-keeperless flip-flop circuit 1600. The data input signal (d) provides data to be written to the selected line of memory that includes the example asynchronous reset pseudo-keeperless flip-flop circuit 1600. The first latch state node 1606 and the second latch state node 1608 form a datapath between the input signals (r, rb, ssb, sd, d) and an output line (o) of the example asynchronous reset pseudo-keeperless flip-flop circuit 1600. The local clock (clk) is provided from a clock source. In some examples, the clock source that provides the local clock (clk) is coupled to a multi-bit flip flop (MBFF) device in which the asynchronous reset pseudo-keeperless flip-flop circuit 1600 is located with other asynchronous reset pseudo-keeperless flip-flop circuits. In example FIG. 16, the active-low scan select signal (ssb), the active-low reset signal (rb), the scan data input signal (sd), the data input signal (d), the local clock (clk), and the output line (o) are signal nets (e.g., a network of connections) and/or are dependent on pin values.

The example asynchronous reset pseudo-keeperless flip-flop circuit 1600 includes four intra-flip-flop shared clock devices. For example, in FIG. 16, only four clock devices are provided to the example asynchronous reset pseudo-keeperless flip-flop circuit 1600. A first clock device is an example PMOS transistor clock device 1612 and a second clock device is an example NMOS transistor clock device 1614. A drain terminal of the example PMOS transistor clock device 1612 is coupled to a voltage supply (VCC), and a source terminal of the NMOS transistor clock device 1614 is coupled to ground. A dual clock device is located in the second latch state node 1608 as an example transmission gate 1616 which includes third and fourth clock devices as opposing transistors (e.g., a PMOS transistor and an NMOS transistor). Two local clock inverters 1622 and 1624 are also shown as clock devices at a local clock input (clk) to the example asynchronous reset pseudo-keeperless flip-flop circuit 1600. However, the two local clock inverters 1622 and 1624 are not counted as clock devices of the example asynchronous reset pseudo-keeperless flip-flop circuit 1600 since they are shared across multiple flip-flop circuits (e.g., multiple asynchronous reset pseudo-keeperless flip-flop circuits similar to the asynchronous reset pseudo-keeperless flip-flop circuit 1600) in a multi-bit flip-flop (MBFF) device.

The example transmission gate 1616 is a dual clock source that functions to connect the output of the first latch state node 1606 to the input of the second latch state node 1608 whenever a clock signal to the NMOS gate terminal (C) is at logic level high “1” and a clock signal to the PMOS gate terminal (Cb) is at logic level low “0”. That is, when the clock signal at the NMOS gate terminal (C) is at logic level high “1” and the clock signal at the PMOS gate terminal (Cb) is at logic level low “0”, both of the NMOS and PMOS transistors of the transmission gate 1616 enter into a conducting state. However, when the clock signal at the NMOS gate terminal (C) is at logic level low “0” and the clock signal at the PMOS gate terminal (Cb) is at logic level high “1”, both of the NMOS and PMOS transistors forming the transmission gate 1616 are forced into cutoff, making the transmission gate 1616 an open circuit so that the output of the first latch state node 1606 is disconnected from the input of the second latch state node 1608.

The example first tri-state multiplexer circuit 1602 includes two PMOS transistors 1628, 1630 and two NMOS transistors 1632, 1634. In example FIG. 16, a drain terminal of the PMOS transistor clock device 1612 is coupled to a supply voltage (VCC), a source terminal of the PMOS transistor clock device 1612 is coupled to a drain terminal of the first PMOS transistor 1628, a source terminal of the first PMOS transistor 1628 is coupled to a drain terminal of the second PMOS transistor 1630, a source terminal of the second PMOS transistor 1630 is coupled to a drain terminal of the first NMOS transistor 1632 to form an output of the first tri-state multiplexer circuit 1602 at a node labeled “n1”, a source terminal of the first NMOS transistor 1632 is coupled to a drain terminal of the second NMOS transistor 1634, and a source terminal of the second NMOS transistor 1634 is coupled to a drain terminal of the NMOS transistor clock device 1614. A source terminal of the example NMOS transistor clock device 1614 is coupled to ground.

In example FIG. 16, an input line of the first tri-state multiplexer circuit 1602 is formed by a gate terminal of the first PMOS transistor 1628 coupled to a gate terminal of the second NMOS transistor 1634, which are coupled to the scan data input signal (sd). In example FIG. 16, the gate terminal of the second PMOS transistor 1630 forms an active-low output-enable line that is coupled to a gated active-low scan select signal (ssb′), and the gate terminal of the first NMOS transistor 1632 forms an active-high output-enable line that is coupled to the active-low scan select signal (ssb) via a first NOR gate circuit 1618.

In example FIG. 16, the gated active-low scan select signal (ssb′) is gated because it is a version of the active-low scan select signal (ssb) that propagates through two NOR gates shown as the first NOR gate circuit 1618 and a second NOR gate circuit 1620. For example, the active-high reset signal (r) is provided to a first input of the first NOR gate circuit 1618 and to a first input of the second NOR gate circuit 1620. The active-low scan select signal (ssb) is provided to a second input of the second NOR gate circuit 1620, and an output (e.g., the active-high scan select signal (ss)) of the second NOR gate circuit 1620 is coupled to a second input of the first NOR gate circuit 1618. In example FIG. 16, the second NOR gate circuit 1620 outputs the active-high scan select signal (ss) based on the active-high reset signal (r) and the active-low scan select signal (ssb) at its inputs. In example FIG. 16, the active-high reset signal (r) is obtained from an output of an inverter circuit 1621 having an active-low reset signal (rb) at its input.

The example second tri-state multiplexer circuit 1604 also includes two PMOS transistors 1636, 1638 and two NMOS transistors 1640, 1642. In example FIG. 16, a source terminal of the PMOS transistor clock device 1612 is coupled to a drain terminal of the first PMOS transistor 1636, a source terminal of the first PMOS transistor 1636 is coupled to a drain terminal of the second PMOS transistor 1638, a source terminal of the second PMOS transistor 1638 is coupled to a drain terminal of the first NMOS transistor 1640 to form an output of the second tri-state multiplexer circuit 1604 at the node labeled “n1”, a source terminal of the first NMOS transistor 1640 is coupled to a drain terminal of the second NMOS transistor 1642, and a source terminal of the second NMOS transistor 1642 is coupled to a drain terminal of the NMOS transistor clock device 1614.

In example FIG. 16, an input line of the second tri-state multiplexer circuit 1604 is formed by a gate terminal of the first PMOS transistor 1636 and a gate terminal of the second NMOS transistor 1642, which are coupled to the data input signal (d). In example FIG. 16, the gate terminal of the second PMOS transistor 1638 forms an active-high output-enable line that is coupled to the active-high scan select signal (ss) from the second NOR gate 1620. The gate terminal of the first NMOS transistor 1640 forms an active-low output-enable line that is coupled to the gated active-low scan select signal (ssb′).

The example first latch state node 1606 (e.g., a first latch tri-state multiplexer circuit) includes a first inverter circuit 1646 and a second inverter circuit 1648. The example first latch state node 1606 includes the two inverter circuits 1646, 1648, instead of having just one inverter circuit, to prevent charge sharing between the first latch state node 1606 and the second latch state node 1608. In addition, the first latch state node 1606 is implemented without a keeper circuit (e.g., without being connected to a keeper circuit for the first latch state node 1606). In the example first latch state node 1606, an input of the first inverter circuit 1646 is coupled to outputs of the first and second tri-state multiplexer 1602, 1604 (e.g., coupled to source terminals of the second PMOS transistors 1630 and 1638 of the first and second tri-state multiplexer 1602, 1604) at the node labeled “n1”, and an output of the first inverter circuit 1646 is coupled to an input of the second inverter circuit 1648. In addition, an output of the second inverter circuit 1648 is coupled to a drain terminal of the transmission gate 1616.

The example second latch state node 1608 (e.g., a second latch state feedback circuit) includes the transmission gate 1616, a keeper circuit 1652, a third NOR gate circuit 1654, and an inverter circuit 1656. The example asynchronous reset pseudo-keeperless flip-flop circuit 1600 is referred to as “pseudo-keeperless” because although the second latch state node 1608 does include the keeper circuit 1652, the first latch state node 1606 does not include a keeper circuit. In the example second latch state node 1608, a PMOS gate terminal (Cb) of the transmission gate 1616 is coupled to an output of the first local clock inverter circuit 1622 and the gate terminal of the NMOS transistor clock device 1614. In addition, an NMOS gate terminal (C) of the example transmission gate 1616 is coupled to an output of the second local clock inverter circuit 1624 and the gate terminal of the PMOS transistor clock device 1612.

The example keeper circuit 1652 includes a PMOS transistor 1660 coupled to an NMOS transistor 1662. A drain terminal of the example PMOS transistor 1660 is coupled to drain terminals of the first PMOS transistors 1628, 1636 of the first and second tri-state multiplexers 1602, 1604 and a source terminal of the PMOS transistor clock device 1612. A source terminal of the example PMOS transistor 1660 is coupled to a drain terminal of the NMOS transistor 1662, a source terminal of the transmission gate 1616, a first input of the third NOR gate circuit 1654, and an input of the inverter circuit 1656 at a node labeled “n2”. A source terminal of the example NMOS transistor 1662 is coupled to the source terminals of the second NMOS transistors 1634, 1642 of the first and second tri-state multiplexers 1602, 1604 and a drain terminal of the NMOS transistor clock device 1614. The gate terminal of the PMOS transistor 1660 and the gate terminal of the NMOS transistor 1662 are coupled to an output of the third NOR gate circuit 1654. If a multi-bit flip-flip (MBFF) device in which the example asynchronous reset pseudo-keeperless flip-flop circuit 1600 is implemented includes internal scan stitching, the output of the third NOR gate circuit 1654 is coupled to a scan data input signal (sd) of a next asynchronous reset pseudo-keeperless flip-flop circuit that is substantially similar or identical to the asynchronous reset pseudo-keeperless flip-flop circuit 1600. As used herein, scan stitching refers to connecting multiple flip-flops together in serial fashion to form a scan chain. An output of the inverter circuit 1656 provides the output (o) of the example asynchronous reset pseudo-keeperless flip-flop circuit 1600.

The example asynchronous reset pseudo-keeperless flip-flop circuit 1600 also includes an active-low reset circuit 1668 implemented by a PMOS transistor. In example FIG. 16, a drain terminal of the active-low reset circuit 1668 is coupled to VCC, and a source terminal of the active-low reset circuit 1668 is coupled to the outputs of the first and second tri-state multiplexer circuits 1602, 1604 at the node labeled “n1” and an input of the first inverter circuit 1646 of the first latch state node 1606. Also in example FIG. 16, an active-low reset signal (rb) is provided to a gate terminal of the active-low reset circuit 1668.

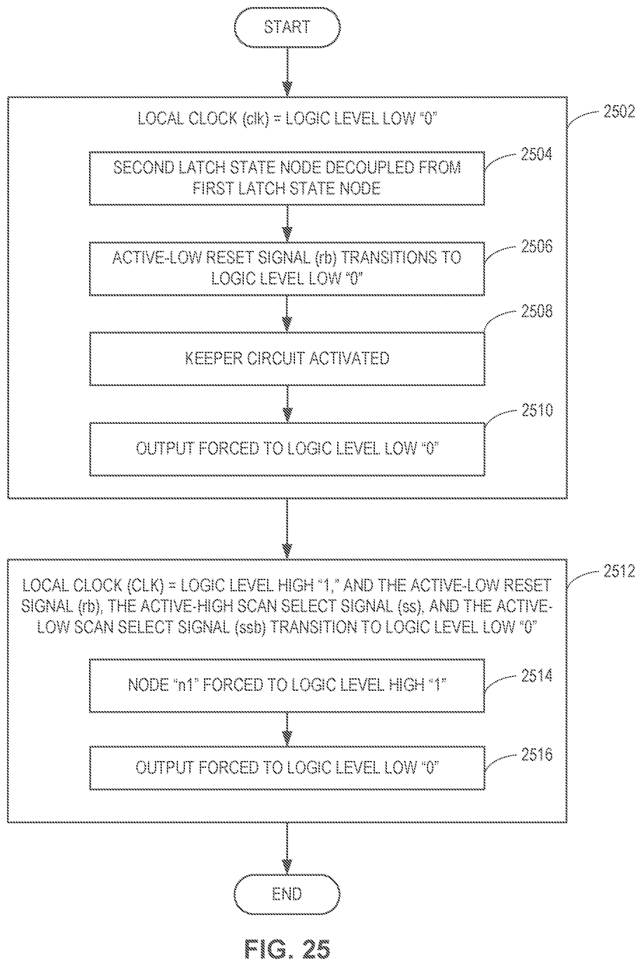

During operation of the example asynchronous reset pseudo-keeperless flip-flop circuit 1600, when the active-low reset signal (rb) transitions to logic level low “0”, the state of the asynchronous reset pseudo-keeperless flip-flop circuit 1600 is reset and the output (o) is forced to logic level low “0”. This occurs regardless of the state of the local clock input (clk). Therefore, a reset to logic level low “0” at the output (o) can occur if the local clock input (clk) is at logic level low “0” or logic level high “1”. When the local clock input (clk) is at logic level low “0”, the second latch state node 1608 is decoupled from the first latch state node 1606. When the active-low reset signal (rb) transitions to logic level low “0”, the example keeper circuit 1652 in the second latch state node 1608 is activated, which forces the output (o) to be at logic level low “0”. However, when the local clock input (clk) is at logic level high “1”, and the active-low reset signal (rb), the active-high scan select signal (ss), and the active-low scan select signal (ssb) transition to logic level low “0”, this forces node “n1” at the outputs of the first and second tri-state multiplexer circuits 1602, 1604 to logic level high “1” which propagates through the second latch state node 1608 resetting the state of the asynchronous reset pseudo-keeperless flip-flop circuit 1600 and forcing the output (o) to logic level low “0”. Thus, in the example asynchronous reset pseudo-keeperless flip-flop circuit 1600, asynchronous reset occurs regardless of the state of the local clock input (clk) (e.g., regardless of whether clk=logic level low “0” or clk=logic level high “1”). Example operations of the asynchronous reset pseudo-keeperless flip-flop circuit 1600 are described below in connection with the flowchart of FIG. 25.

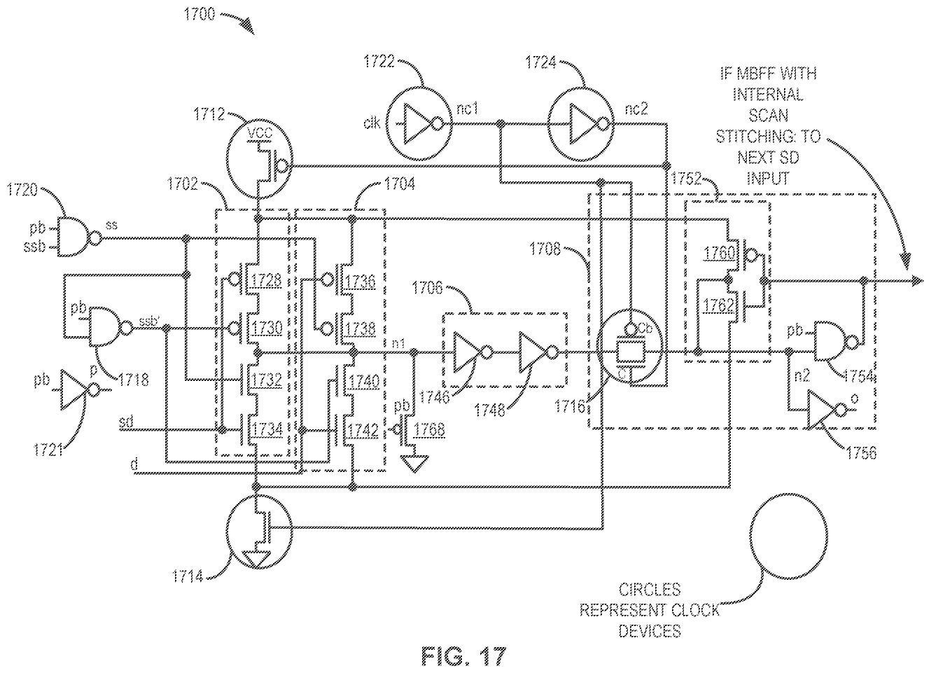

FIG. 17 is a schematic illustration of an example asynchronous preset pseudo-keeperless flip-flop circuit 1700. The example asynchronous preset pseudo-keeperless flip-flop circuit 1700 is controllable to preset its state so that an output (o) is forced to logic level high “1”. The example asynchronous preset pseudo-keeperless flip-flop circuit 1700 includes a first tri-state multiplexer circuit 1702, a second tri-state multiplexer circuit 1704, a first latch state node 1706 (e.g., a first latch tri-state multiplexer circuit), and a second latch state node 1708 (e.g., a second latch state feedback circuit). Input signals to the example asynchronous preset pseudo-keeperless flip-flop circuit 1700 include an active-high preset signal (pr), an active-low preset signal (pb), an active-low scan select signal (ssb), a scan data input signal (sd), a data input signal (d), and a local clock (clk). The active-high preset signal (p) and the active-low preset signal (pb) are to reset a state (e.g., a stored bit) of the example asynchronous preset pseudo-keeperless flip-flop circuit 1700. The active-low scan select signal (ssb) is to activate a line of memory that includes the example asynchronous preset pseudo-keeperless flip-flop circuit 1700 for a memory access. The scan data input signal (sd) is to write data to a selected line of memory that includes the example asynchronous preset pseudo-keeperless flip-flop circuit 1700. The data input signal (d) provides data to be written to the selected line of memory that includes the example asynchronous preset pseudo-keeperless flip-flop circuit 1700. The first latch state node 1706 and the second latch state node 1708 form a datapath between the input signals (p, pb, ssb, sd, d) and an output line (o) of the example asynchronous preset pseudo-keeperless flip-flop circuit 1700. The local clock (clk) is provided from a clock source. In some examples, the clock source that provides the local clock (clk) is coupled to a multi-bit flip flop (MBFF) device in which the asynchronous preset pseudo-keeperless flip-flop circuit 1700 is located with other asynchronous preset pseudo-keeperless flip-flop circuits. In example FIG. 17, the active-low scan select signal (ssb), the active-low preset signal (pb), the scan data input signal (sd), the data input signal (d), the local clock (clk), and the output line (o) are signal nets (e.g., a network of connections) and/or are dependent on pin values.

The example asynchronous preset pseudo-keeperless flip-flop circuit 1700 includes four intra-flip-flop shared clock devices. For example, in FIG. 17, only four clock devices are provided in the example asynchronous preset pseudo-keeperless flip-flop circuit 1700. A first clock device is an example PMOS transistor clock device 1712 and a second clock device is an example NMOS transistor clock device 1714. A drain terminal of the example PMOS transistor clock device 1712 is coupled to a voltage supply (VCC), and a source terminal of the NMOS transistor clock device 1714 is coupled to ground. A dual clock device is located in the second latch state node 1708 as an example transmission gate 1716 which includes third and fourth clock devices as opposing transistors (e.g., a PMOS transistor and an NMOS transistor). The example transmission gate 1716 operates similar to the example transmission gate 1616 as described above in connection with FIG. 16. Two local clock inverters 1722 and 1724 are also shown as clock devices at a local clock input (clk) to the example asynchronous preset pseudo-keeperless flip-flop circuit 1700. However, the two local clock inverters 1722 and 1724 are not counted as clock devices of the example asynchronous preset pseudo-keeperless flip-flop circuit 1700 since they are shared across multiple flip-flop circuits (e.g., multiple asynchronous preset pseudo-keeperless flip-flop circuits similar to the asynchronous preset pseudo-keeperless flip-flop circuit 1700) in a multi-bit flip-flop (MBFF) device.

The example first tri-state multiplexer circuit 1702 includes two PMOS transistors 1728, 1730 and two NMOS transistors 1732, 1734. In example FIG. 17, a drain terminal of the PMOS transistor clock device 1712 is coupled to a supply voltage (VCC), a source terminal of the PMOS transistor clock device 1712 is coupled to a drain terminal of the first PMOS transistor 1728, a source terminal of the first PMOS transistor 1728 is coupled to a drain terminal of the second PMOS transistor 1730, a source terminal of the second PMOS transistor 1730 is coupled to a drain terminal of the first NMOS transistor 1732 to form an output of the first tri-state multiplexer circuit 1702 at a node labeled “n1”, a source terminal of the first NMOS transistor 1732 is coupled to a drain terminal of the second NMOS transistor 1734, and a source terminal of the second NMOS transistor 1734 is coupled to a drain terminal of the NMOS transistor clock device 1714. A source terminal of the example NMOS transistor clock device 1714 is coupled to ground.

In example FIG. 17, an input line of the first tri-state multiplexer circuit 1702 is formed by a gate terminal of the first PMOS transistor 1728 coupled to a gate terminal of the second NMOS transistor 1734, which are coupled to the scan data input signal (sd). In example FIG. 17, the gate terminal of the second PMOS transistor 1730 forms an active-low output-enable line that is coupled to a gated active-low scan select signal (ssb′), and the gate terminal of the first NMOS transistor 1732 forms an active-high output-enable line that is coupled to the active-low scan select signal (ssb) via a first NAND gate circuit 1718.

In example FIG. 17, the gated active-low scan select signal (ssb′) is gated because it is a version of the active-low scan select signal (ssb) that propagates through two NAND gates shown as the first NAND gate circuit 1718 and a second NAND gate circuit 1720. For example, the active-low preset signal (pb) is provided to a first input of the first NAND gate circuit 1718 and to a first input of the second NAND gate circuit 1720. The active-low scan select signal (ssb) is provided to a second input of the second NAND gate circuit 1720, and an output (e.g., the active-high scan select signal (ss)) of the second NAND gate circuit 1720 is coupled to a second input of the first NAND gate circuit 1718. In example FIG. 17, the second NAND gate circuit 1720 outputs the active-high scan select signal (ss) based on the active-high preset signal (p) and the active-low scan select signal (ssb) at its inputs. In example FIG. 17, the active-high preset signal (p) is obtained from an output of an inverter circuit 1721 having an active-low preset signal (pb) at its input.

The example second tri-state multiplexer circuit 1704 includes two PMOS transistors 1736, 1738 and two NMOS transistors 1740, 1742. In example FIG. 17, a source terminal of the PMOS transistor clock device 1712 is coupled to a drain terminal of the first PMOS transistor 1736, a source terminal of the first PMOS transistor 1736 is coupled to a drain terminal of the second PMOS transistor 1738, a source terminal of the second PMOS transistor 1738 is coupled to a drain terminal of the first NMOS transistor 1740 to form an output of the second tri-state multiplexer circuit 1604 at the node labeled “n1”, a source terminal of the first NMOS transistor 1740 is coupled to a drain terminal of the second NMOS transistor 1742, and a source terminal of the second NMOS transistor 1742 is coupled to a drain terminal of the NMOS transistor clock device 1714.

In example FIG. 17, an input line of the second tri-state multiplexer circuit 1704 is formed by a gate terminal of the first PMOS transistor 1736 and a gate terminal of the second NMOS transistor 1742, which are coupled to the data input signal (d). In example FIG. 17, the gate terminal of the second PMOS transistor 1738 forms an active-high output-enable line that is coupled to the active-high scan select signal (ss) from the second NAND gate 1720. The gate terminal of the first NMOS transistor 1740 forms an active-low output-enable line that is coupled to the gated active-low scan select signal (ssb′).

The example first latch state node 1706 (e.g., a first latch tri-state multiplexer circuit) includes a first inverter circuit 1746 and a second inverter circuit 1748. The example first latch state node 1706 includes the two inverter circuits 1746, 1748, instead of having just one inverter circuit, to prevent charge sharing between the first latch state node 1706 and the second latch state node 1708. In addition, the first latch state node 1706 is implemented without a keeper circuit (e.g., without being connected to a keeper circuit for the first latch state node 1706). In the example first latch state node 1706, an input of the first inverter circuit 1746 is coupled to outputs of the first and second tri-state multiplexer 1702, 1704 (e.g., coupled to source terminals of the second PMOS transistors 1730 and 1738 of the first and second tri-state multiplexer 1702, 1704) at the node labeled “n1”, and an output of the first inverter circuit 1746 is coupled to an input of the second inverter circuit 1748. In addition, an output of the second inverter circuit 1748 is coupled to a drain terminal of the transmission gate 1716.

The example second latch state node 1708 (e.g., a second latch state feedback circuit) includes the transmission gate 1716, a keeper circuit 1752, a third NAND gate circuit 1754, and an inverter circuit 1756. The example asynchronous preset pseudo-keeperless flip-flop circuit 1700 is referred to as “pseudo-keeperless” because although the second latch state node 1708 does include the keeper circuit 1752, the first latch state node 1706 does not include a keeper circuit. In the example second latch state node 1708, a PMOS gate terminal (Cb) of the transmission gate 1716 is coupled to an output of the first local clock inverter circuit 1722 and the gate terminal of the NMOS transistor clock device 1714. In addition, an NMOS gate terminal (C) of the example transmission gate 1716 is coupled to an output of the second local clock inverter circuit 1724 and the gate terminal of the PMOS transistor clock device 1712.

The example keeper circuit 1752 includes a PMOS transistor 1760 coupled to an NMOS transistor 1762. A drain terminal of the example PMOS transistor 1760 is coupled to drain terminals of the first PMOS transistors 1728, 1736 of the first and second tri-state multiplexers 1702, 1704 and a source terminal of the PMOS transistor clock device 1712. A source terminal of the example PMOS transistor 1760 is coupled to a drain terminal of the NMOS transistor 1762, a source terminal of the transmission gate 1716, a first input of the third NAND gate circuit 1754, and an input of the inverter circuit 1756 at a node labeled “n2”. A source terminal of the example NMOS transistor 1762 is coupled to the source terminals of the second NMOS transistors 1734, 1742 of the first and second tri-state multiplexers 1702, 1704 and a drain terminal of the NMOS clock device 1714. The gate terminal of the PMOS transistor 1760 and the gate terminal of the NMOS transistor 1762 are coupled to an output of the third NAND gate circuit 1754. If a multi-bit flip-flip (MBFF) device in which the example asynchronous preset pseudo-keeperless flip-flop circuit 1700 is implemented includes internal scan stitching (e.g., connecting multiple flip-flops together in serial fashion to form a scan chain), the output of the third NAND gate circuit 1754 is coupled to a scan data input signal (sd) of a next asynchronous preset pseudo-keeperless flip-flop circuit that is substantially similar or identical to the asynchronous preset pseudo-keeperless flip-flop circuit 1700. An output of the inverter circuit 1756 provides the output (o) of the example asynchronous preset pseudo-keeperless flip-flop circuit 1700.

The example asynchronous preset pseudo-keeperless flip-flop circuit 1700 also includes an active-low preset circuit 1768 implemented by a PMOS transistor. In example FIG. 17, a source terminal of the active-low preset circuit 1768 is coupled to ground, and a drain terminal of the active-low preset circuit 1768 is coupled to the outputs of the first and second tri-state multiplexer circuits 1702, 1704 at the node labeled “n1” and an input of the first inverter circuit 1746 of the first latch state node 1706. Also in example FIG. 17, an active-low preset signal (pb) is provided to a gate terminal of the active-low preset circuit 1768.

During operation of the example asynchronous preset pseudo-keeperless flip-flop circuit 1700, when the active-low preset signal (pb) transitions to logic level low “0”, the state of the asynchronous preset pseudo-keeperless flip-flop circuit 1700 is preset and the output (o) is forced to logic level high “1”. This occurs regardless of the state of the local clock input (clk). Therefore, a preset to logic level high “1” at the output (o) can occur if the local clock input (clk) is at logic level low “0” or logic level high “1”. When the local clock input (clk) is at logic level low “0”, the second latch state node 1708 is decoupled from the first latch state node 1706. When the active-low preset signal (pb) transitions to logic level low “0”, the example keeper circuit 1752 in the second latch state node 1708 is activated, which forces the output (o) to be at logic level high “1”. However, when the local clock input (clk) is at logic level high “1”, the active-low preset signal (pb) is at logic level low “0”, and the active-low scan select signal (ssb) transitions to logic level low “0”, this causes both the active-high scan select signal (ss) and the gated active-low scan select signal (ssb′) to transition logic level high “1” and forces node “n1” at the outputs of the first and second tri-state multiplexer circuits 1702, 1704 to logic level high “1”. This propagates through the second latch state node 1708 resetting the state of the asynchronous preset pseudo-keeperless flip-flop circuit 1700 and forcing the output (o) to logic level high “1”.

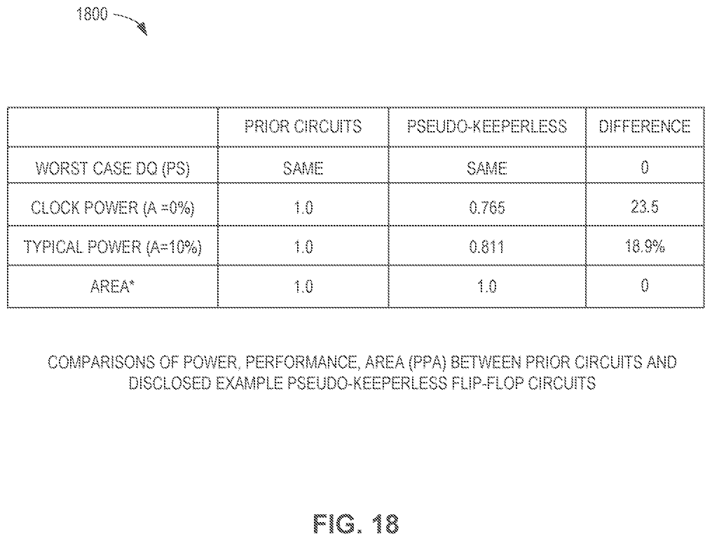

FIG. 18 is an example table 1800 showing comparisons of example power, performance, area (PPA) data between prior circuits and example pseudo-keeperless flip-flop circuits disclosed herein in connection with FIGS. 14-17. In particular, the example table 1800 shows results of detailed PPA simulation comparisons (w/layout extraction) that were performed using standard cell libraries. A tested circuit implemented in accordance with structures of the pseudo-keeperless flip-flop circuits described above in connection with FIGS. 14-17 demonstrates iso-performance and iso-area with up to 23.5% power savings at a typical process 0.65V, 100° C. (e.g., TTTT=typical nMOS, typical pMOS, typical voltage supply, typical temperature). For high-frequency chips with many flip-flops, total chip-level power can be up to 60%, where 30% is due to the flip-flops. Based on these estimates, example pseudo-keeperless flip-flop circuits disclosed herein can save up to 5% total chip level power, depending on flip-flop usage.

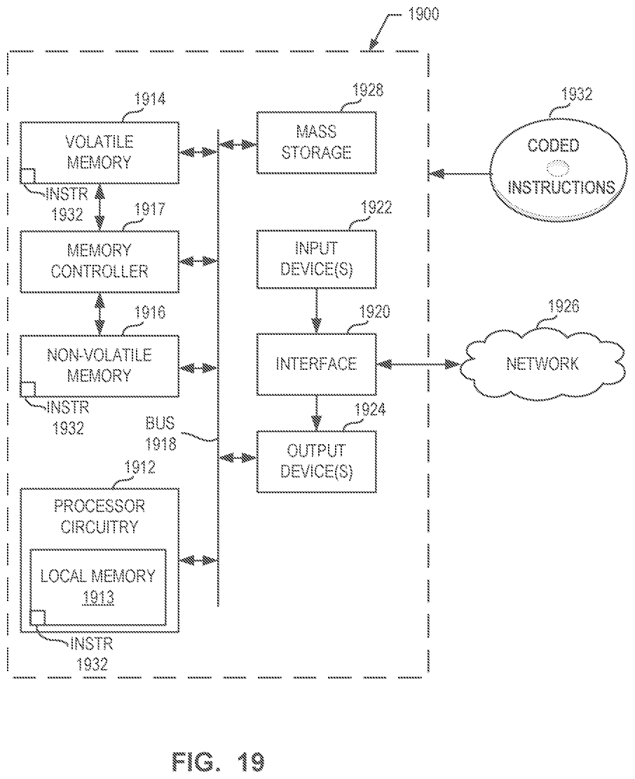

FIG. 19 is a block diagram of an example programmable circuitry platform 1900 structured to execute and/or instantiate the example machine-readable instructions and/or the example operations of FIGS. 22-26 to implement example circuits disclosed herein. The programmable circuitry platform 1900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1900 of the illustrated example includes programmable circuitry 1912. The programmable circuitry 1912 of the illustrated example is hardware. For example, the programmable circuitry 1912 can be implemented by one or more integrated circuits, logic circuits, FPGAs, microprocessors, CPUs, GPUs, DSPs, and/or microcontrollers from any desired family or manufacturer. The programmable circuitry 1912 may be implemented by one or more semiconductor based (e.g., silicon based) devices. In this example, the programmable circuitry 1912 implements the semiconductor device 100 of FIG. 1 and/or one or more of the example circuits disclosed herein.

The programmable circuitry 1912 of the illustrated example includes a local memory 1913 (e.g., a cache, registers, etc.). The programmable circuitry 1912 of the illustrated example is in communication with main memory 1914, 1916, which includes a volatile memory 1914 and a non-volatile memory 1916, by a bus 1918. The volatile memory 1914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1916 may be implemented by flash memory and/or any other desired type of memory device. Access to the main memory 1914, 1916 of the illustrated example is controlled by a memory controller 1917. In some examples, the memory controller 1917 may be implemented by one or more integrated circuits, logic circuits, microcontrollers from any desired family or manufacturer, or any other type of circuitry to manage the flow of data going to and from the main memory 1914, 1916.

The programmable circuitry platform 1900 of the illustrated example also includes interface circuitry 1920. The interface circuitry 1920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1922 are connected to the interface circuitry 1920. The input device(s) 1922 permit(s) a user (e.g., a human user, a machine user, etc.) to enter data and/or commands into the programmable circuitry 1912. The input device(s) 1922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1924 are also connected to the interface circuitry 1920 of the illustrated example. The output device(s) 1924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1920 of the illustrated example, thus, typically includes a graphics driver card, a graphics driver chip, and/or graphics processor circuitry such as a GPU.

The interface circuitry 1920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1926. The communication can be by, for example, an Ethernet connection, a digital subscriber line (DSL) connection, a telephone line connection, a coaxial cable system, a satellite system, a beyond-line-of-site wireless system, a line-of-site wireless system, a cellular telephone system, an optical connection, etc.

The programmable circuitry platform 1900 of the illustrated example also includes one or more mass storage discs or devices 1928 to store firmware, software, and/or data. Examples of such mass storage discs or devices 1928 include magnetic storage devices (e.g., floppy disk, drives, hard disk drives (HDDs), etc.), optical storage devices (e.g., Blu-ray disks, compact disks (CDs), digital versatile disks (DVDs), etc.), RAID systems, and/or solid-state storage discs or devices such as flash memory devices and/or solid-state drives (SSDs).

The machine-readable instructions 1932, which may be implemented by machine-readable instructions to implement the operations of FIGS. 22-26, may be stored in the mass storage device 1928, in the volatile memory 1914, in the non-volatile memory 1916, and/or on at least one non-transitory computer-readable storage medium such as a CD or DVD which may be removable.

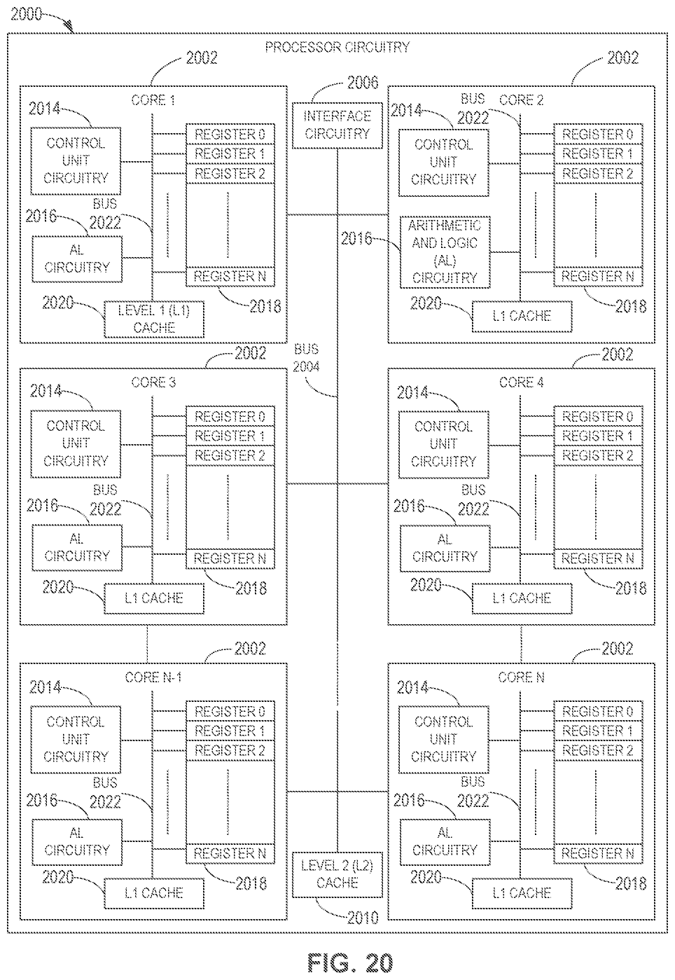

FIG. 20 is a block diagram of an example implementation of the programmable circuitry 1912 of FIG. 19. In this example, the programmable circuitry 1912 of FIG. 19 is implemented by a microprocessor 2000. For example, the microprocessor 2000 may be a general-purpose microprocessor (e.g., general-purpose microprocessor circuitry). The microprocessor 2000 executes machine-readable instructions to implement operations of the flowcharts of FIGS. 22-26 to effectively instantiate circuitry disclosed herein as logic circuits to perform operations corresponding to those machine-readable instructions. In some such examples, circuitry disclosed herein is instantiated by the hardware circuits of the microprocessor 2000 in combination with the machine-readable instructions. For example, the microprocessor 2000 may be implemented by multi-core hardware circuitry such as a CPU, a DSP, a GPU, an XPU, etc. Although it may include any number of example cores 2002 (e.g., 1 core), the microprocessor 2000 of this example is a multi-core semiconductor device including N cores. The cores 2002 of the microprocessor 2000 may operate independently or may cooperate to execute machine-readable instructions. For example, machine code corresponding to a firmware program, an embedded software program, or a software program may be executed by one of the cores 2002 or may be executed by multiple ones of the cores 2002 at the same or different times. In some examples, the machine code corresponding to the firmware program, the embedded software program, or the software program is split into threads and executed in parallel by two or more of the cores 2002. The software program may correspond to a portion or all of the machine-readable instructions and/or operations represented by the flowcharts of FIGS. 22-26.

The cores 2002 may communicate by a first example bus 2004. In some examples, the first bus 2004 may be implemented by a communication bus to effectuate communication associated with one(s) of the cores 2002. For example, the first bus 2004 may be implemented by at least one of an Inter-Integrated Circuit (I2C) bus, a Serial Peripheral Interface (SPI) bus, a PCI bus, or a PCIe bus. Additionally or alternatively, the first bus 2004 may be implemented by any other type of computing or electrical bus. The cores 2002 may obtain data, instructions, and/or signals from one or more external devices by example interface circuitry 2006. The cores 2002 may output data, instructions, and/or signals to the one or more external devices by the interface circuitry 2006. Although the cores 2002 of this example include example local memory 2020 (e.g., Level 1 (L1) cache that may be split into an L1 data cache and an L1 instruction cache), the microprocessor 2000 also includes example shared memory 2010 that may be shared by the cores (e.g., Level 2 (L2 cache)) for high-speed access to data and/or instructions. Data and/or instructions may be transferred (e.g., shared) by writing to and/or reading from the shared memory 2010. The local memory 2020 of each of the cores 2002 and the shared memory 2010 may be part of a hierarchy of storage devices including multiple levels of cache memory and the main memory (e.g., the main memory 1914, 1916 of FIG. 19). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2002 may be referred to as a CPU, DSP, GPU, etc., or any other type of hardware circuitry. Each core 2002 includes control unit circuitry 2014, arithmetic and logic (AL) circuitry (sometimes referred to as an ALU) 2016, a plurality of registers 2018, the local memory 2020, and a second example bus 2022. Other structures may be present. For example, each core 2002 may include vector unit circuitry, single instruction multiple data (SIMD) unit circuitry, load/store unit (LSU) circuitry, branch/jump unit circuitry, floating-point unit (FPU) circuitry, etc. The control unit circuitry 2014 includes semiconductor-based circuits structured to control (e.g., coordinate) data movement within the corresponding core 2002. The AL circuitry 2016 includes semiconductor-based circuits structured to perform one or more mathematic and/or logic operations on the data within the corresponding core 2002. The AL circuitry 2016 of some examples performs integer-based operations. In other examples, the AL circuitry 2016 also performs floating-point operations. In yet other examples, the AL circuitry 2016 may include first AL circuitry that performs integer-based operations and second AL circuitry that performs floating-point operations. In some examples, the AL circuitry 2016 may be referred to as an Arithmetic Logic Unit (ALU).

The registers 2018 are semiconductor-based structures to store data and/or instructions such as results of one or more of the operations performed by the AL circuitry 2016 of the corresponding core 2002. For example, the registers 2018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 2018 may be arranged in a bank as shown in FIG. 20. Alternatively, the registers 2018 may be organized in any other arrangement, format, or structure, such as by being distributed throughout the core 2002 to shorten access time. The second bus 2022 may be implemented by at least one of an I2C bus, a SPI bus, a PCI bus, or a PCIe bus.

Each core 2002 and/or, more generally, the microprocessor 2000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2000 is a semiconductor device fabricated to include many transistors interconnected to implement the structures described above in one or more integrated circuits (ICs) contained in one or more packages.

The microprocessor 2000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 2000, in the same chip package as the microprocessor 2000 and/or in one or more separate packages from the microprocessor 2000.

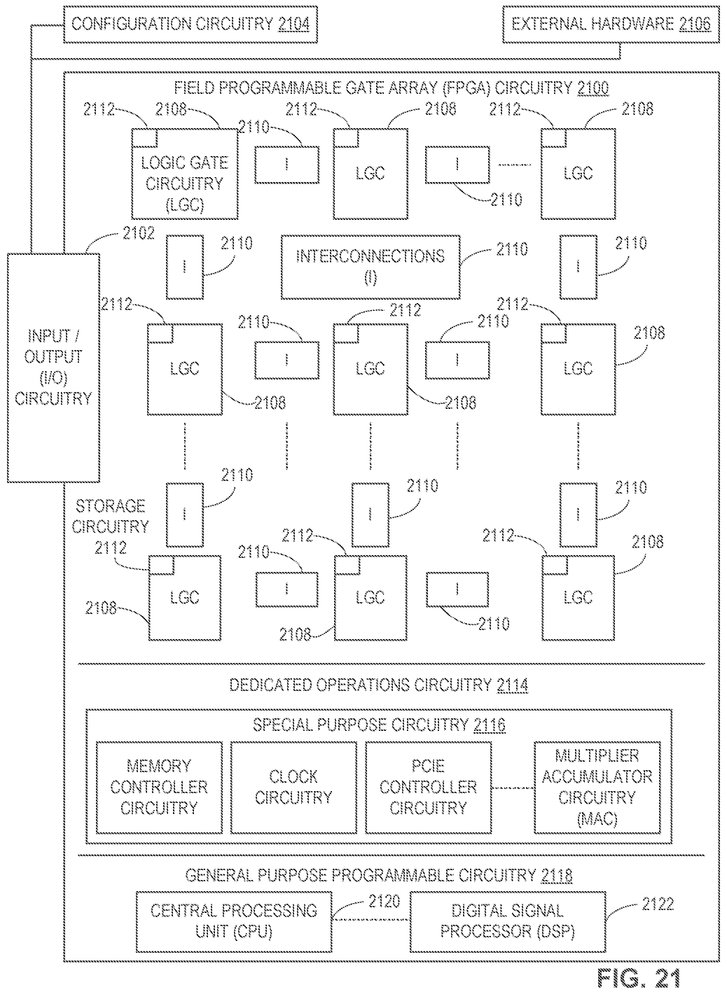

FIG. 21 is a block diagram of another example implementation of the programmable circuitry 1912 of FIG. 19. In this example, the programmable circuitry 1912 is implemented by FPGA circuitry 2100. For example, the FPGA circuitry 2100 may be implemented by an FPGA. The FPGA circuitry 2100 can be used, for example, to perform operations that could otherwise be performed by the example microprocessor 2000 of FIG. 20 executing corresponding machine-readable instructions. However, once configured, the FPGA circuitry 2100 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 2000 of FIG. 20 described above (which is a general purpose device that may be programmed to execute machine-readable instructions to implement operations represented by the flowcharts of FIGS. 22-26 but whose interconnections and logic circuitry are fixed once fabricated), the FPGA circuitry 2100 of the example of FIG. 21 includes interconnections and logic circuitry that may be configured, structured, programmed, and/or interconnected in different ways after fabrication to instantiate, for example, some or all of the operations/functions corresponding to the flowcharts of FIGS. 22-26. In particular, the FPGA circuitry 2100 may be thought of as an array of logic gates, interconnections, and switches. The switches can be programmed to change how the logic gates are interconnected by the interconnections, effectively forming one or more dedicated logic circuits (unless and until the FPGA circuitry 2100 is reprogrammed). The configured logic circuits enable the logic gates to cooperate in different ways to perform different operations on data received by input circuitry. Those operations may correspond to one or more of the flowcharts of FIGS. 22-26. As such, the FPGA circuitry 2100 may be configured and/or structured to effectively instantiate some or all of the operations/functions corresponding to one or more of the flowcharts of FIGS. 22-26 as dedicated logic circuits to perform the operations/functions corresponding to those software instructions in a dedicated manner analogous to an ASIC. Therefore, the FPGA circuitry 2100 may perform the operations/functions corresponding to one or more of the flowcharts of FIGS. 22-26 faster than the general-purpose microprocessor can execute the same.

In the example of FIG. 21, the FPGA circuitry 2100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 2100 of FIG. 21 may access and/or load the binary file to cause the FPGA circuitry 2100 of FIG. 21 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 2100 of FIG. 21 to cause configuration and/or structuring of the FPGA circuitry 2100 of FIG. 21, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 2100 of FIG. 21 may access and/or load the binary file to cause the FPGA circuitry 2100 of FIG. 21 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 2100 of FIG. 21 to cause configuration and/or structuring of the FPGA circuitry 2100 of FIG. 21, or portion(s) thereof.

The FPGA circuitry 2100 of FIG. 21, includes example input/output (I/O) circuitry 2102 to obtain and/or output data to/from example configuration circuitry 2104 and/or external hardware 2106. For example, the configuration circuitry 2104 may be implemented by interface circuitry that may obtain a binary file, which may be implemented by a bit stream, data, and/or machine-readable instructions, to configure the FPGA circuitry 2100, or portion(s) thereof. In some such examples, the configuration circuitry 2104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 2106 may be implemented by external hardware circuitry. For example, the external hardware 2106 may be implemented by the microprocessor 2000 of FIG. 20.

The FPGA circuitry 2100 also includes an array of example logic gate circuitry 2108, a plurality of example configurable interconnections 2110, and example storage circuitry 2112. The logic gate circuitry 2108 and the configurable interconnections 2110 are configurable to instantiate one or more operations/functions that may correspond to at least some of the flowcharts of FIGS. 22-26 and/or other desired operations. The logic gate circuitry 2108 shown in FIG. 21 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2108 to enable configuration of the electrical structures and/or the logic gates to form circuits to perform desired operations/functions. The logic gate circuitry 2108 may include other electrical structures such as look-up tables (LUTs), registers (e.g., flip-flops or latches), multiplexers, etc.

The configurable interconnections 2110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2108 to program desired logic circuits.

The storage circuitry 2112 of the illustrated example is structured to store result(s) of the one or more of the operations performed by corresponding logic gates. The storage circuitry 2112 may be implemented by registers or the like. In the illustrated example, the storage circuitry 2112 is distributed amongst the logic gate circuitry 2108 to facilitate access and increase execution speed.

The example FPGA circuitry 2100 of FIG. 21 also includes example dedicated operations circuitry 2114. In this example, the dedicated operations circuitry 2114 includes special purpose circuitry 2116 that may be invoked to implement commonly used functions to avoid the need to program those functions in the field. Examples of such special purpose circuitry 2116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2100 may also include example general purpose programmable circuitry 2118 such as an example CPU 2120 and/or an example DSP 2122. Other general purpose programmable circuitry 2118 may additionally or alternatively be present such as a GPU, an XPU, etc., that can be programmed to perform other operations.

Although FIGS. 20 and 21 illustrate two example implementations of the programmable circuitry 1912 of FIG. 19, many other approaches are contemplated. For example, FPGA circuitry may include an on-board CPU, such as one or more of the example CPU 2120 of FIG. 20. Therefore, the programmable circuitry 1912 of FIG. 19 may additionally be implemented by combining at least the example microprocessor 2000 of FIG. 20 and the example FPGA circuitry 2100 of FIG. 21. In some such hybrid examples, one or more cores 2002 of FIG. 20 may execute a first portion of the operations represented by the flowcharts of FIGS. 22-26 to perform first operation(s)/function(s), the FPGA circuitry 2100 of FIG. 21 may be configured and/or structured to perform second operation(s)/function(s) corresponding to a second portion of the operations represented by the flowcharts of FIG. 22-26, and/or an ASIC may be configured and/or structured to perform third operation(s)/function(s) corresponding to a third portion of the operations represented by the flowcharts of FIGS. 22-26.

It should be understood that some or all of the circuitry disclosed herein may, thus, be instantiated at the same or different times. For example, same and/or different portion(s) of the microprocessor 2000 of FIG. 20 may be programmed to execute portion(s) of machine-readable instructions at the same and/or different times. In some examples, same and/or different portion(s) of the FPGA circuitry 2100 of FIG. 21 may be configured and/or structured to perform operations/functions corresponding to portion(s) of machine-readable instructions at the same and/or different times.

In some examples, some or all of the circuitry disclosed herein may be instantiated, for example, in one or more threads executing concurrently and/or in series. For example, the microprocessor 2000 of FIG. 20 may execute machine-readable instructions in one or more threads executing concurrently and/or in series. In some examples, the FPGA circuitry 2100 of FIG. 21 may be configured and/or structured to carry out operations/functions concurrently and/or in series. Moreover, in some examples, some or all of the circuitry disclosed herein may be implemented within one or more virtual machines and/or containers executing on the microprocessor 2000 of FIG. 20.

In some examples, the programmable circuitry 1912 of FIG. 19 may be in one or more packages. For example, the microprocessor 2000 of FIG. 20 and/or the FPGA circuitry 2100 of FIG. 21 may be in one or more packages. In some examples, an XPU may be implemented by the programmable circuitry 1912 of FIG. 19, which may be in one or more packages. For example, the XPU may include a CPU (e.g., the microprocessor 2000 of FIG. 20, the CPU 2120 of FIG. 21, etc.) in one package, a DSP (e.g., the DSP 2122 of FIG. 21) in another package, a GPU in yet another package, and an FPGA (e.g., the FPGA circuitry 2100 of FIG. 21) in still yet another package.

FIG. 22 is a flowchart representative of example operations of the example RdLBL circuit 500 based on a delayed keeper circuit 502 of FIG. 5 to generate a long keeper delay. Input signaling to the example RdLBL circuit 500 to implement the operations of FIG. 22 may be provided by a timing controller (e.g., the timing controller 508 of FIG. 5 or the timing controller 606 of FIG. 6) and/or any other suitable device. In example FIG. 22, the timing controller 508 (FIG. 5) uses an “m-inverters delay” of FIG. 5 to create a relatively longer duration for an evaluation phase between a first time at which the timing controller 508 deactivates the pre-charge circuit 514 (e.g., PRE0 transitions from logic level low to logic level high) and a subsequent, second time at which the timing controller 508 activates the keeper circuit 502 (e.g., DKPR transitions from logic level high to logic level low). The example operations of FIG. 22 begin during a first time at block 2202 when the timing controller 508 deactivates the pre-charge circuit 514 after a pre-charge phase. For example, the timing controller 508 deactivates the pre-charge circuit 514 by causing a logic level high voltage to be applied to the PRE0 input of the pre-charge circuit 514. At block 2204, the example timing controller 508 waits the “m-inverters delay” duration while logic level high applied to the DKPR input keeps the keeper circuit 502 in an inactive state during an evaluation phase (e.g., a read phase). During the evaluation phase, contention current is substantially reduced or eliminated in the example keeper circuit 502 (block 2206). During the evaluation phase between the first time and the second time defined by the “m-inverters delay” (e.g., when both the keeper circuit 502 and the pre-charge circuit 514 are inactive), the read buffer 510 stores values read from the data cells (D[0]-D[15]) of the pulldown circuits 504 (block 2208). After the “m-inverters delay” and the evaluation phase, the example timing controller 508 activates the keeper circuit 502 (block 2210). For example, the example timing controller 508 activates the keeper circuit 502 by causing an applying of a logic level low to the DKPR input of the keeper circuit 502. The operations 2200 end.

FIG. 23 is a flowchart representative of example operations of the example dual-rail contention-free wordline driver level-shifter circuit 1100, 1200 of FIGS. 11 and 12. Input signaling to the example dual-rail contention-free wordline driver level-shifter circuit 1100, 1200 to implement the operations of FIG. 23 may be provided by a timing controller (e.g., the timing controller 508 of FIG. 5 or the timing controller 606 of FIG. 6) and/or any other suitable device. In example FIG. 23, the cross-coupled keeper circuit 1102 is operated to substantially prevent contention current in the dual-rail contention-free wordline driver level-shifter circuit 1100, 1200 during an evaluation phase. The operations of FIG. 23 include a pre-charge phase 2302 and an evaluation phase 2304 (e.g., a read phase). During the pre-charge phase 2302, the clock input line (clk) of the example dual-rail contention-free wordline driver level-shifter circuit 1100, 1200 is at logic level low (e.g., logic zero (“0”)), and nodes “n” and “n0b” both go to logic level high “1” of the high supply voltage (e.g., VCC_{HIGH}) (block 2306). Also during the pre-charge phase 2302, the wordline output (w1) of the example dual-rail contention-free wordline driver level-shifter circuit 1100, 1200 is de-asserted at logic level low “0” (block 2308), and it does not matter what logic level is at the decoded address enable input line (en).

When the clock input line (clk) transitions to logic level high “1” (e.g., VCC_{HIGH}), the example dual-rail contention-free wordline driver level-shifter circuit 1100, 1200 transitions to the evaluation phase 2304 (e.g., a read phase). During the evaluation phase 2304, the example dual-rail contention-free wordline driver level-shifter circuit 1100, 1200 is in an enabled state (block 2310) when the decoded address enable input line (en) is at logic level high “1” and is in a disabled state (block 2318) when the decoded address enable input line (en) is at logic level is at logic level low “0”. Under both conditions, the cross-coupled keeper circuit 1102 substantially prevents contention current in the example dual-rail contention-free wordline driver level-shifter circuit 1100, 1200.

When the decoded address enable input line (en) of the example dual-rail contention-free wordline driver level-shifter circuit 1100, 1200 is set to logic level high “1” (block 2310), the node “no” at the fifth gate of the third PMOS transistor 1118 of the cross-coupled keeper circuit 1102 discharges to logic level low “0” (block 2312), and the node “n0b” at the fourth gate terminal of the second PMOS transistor 1116 of the cross-coupled keeper circuit 1102 remains at logic level high “1” (e.g., charged to VCC_{HIGH}) (block 2314). This makes the wordline output (w1) of the example dual-rail contention-free wordline driver level-shifter circuit 1100, 1200 transition to logic level high “1” (block 2316).

Also during the evaluation phase 2304, when the decoded address enable input line (en) is set to logic level low “0” to disable the example dual-rail contention-free wordline driver level-shifter circuit 1100, 1200 (block 2318), the node “nob” at the fourth gate terminal of the second PMOS transistor 1116 of the cross-coupled keeper circuit 1102 transitions to logic level low “0” (block 2320). This causes the cross-coupled keeper circuit 1102 to maintain the node “n0” at logic level high “1” (block 2322), and causes the wordline output (w1) of the example dual-rail contention-free wordline driver level-shifter circuit 1100, 1200 to transition to logic level low “0” (block 2324). The example operations of FIG. 23 end.

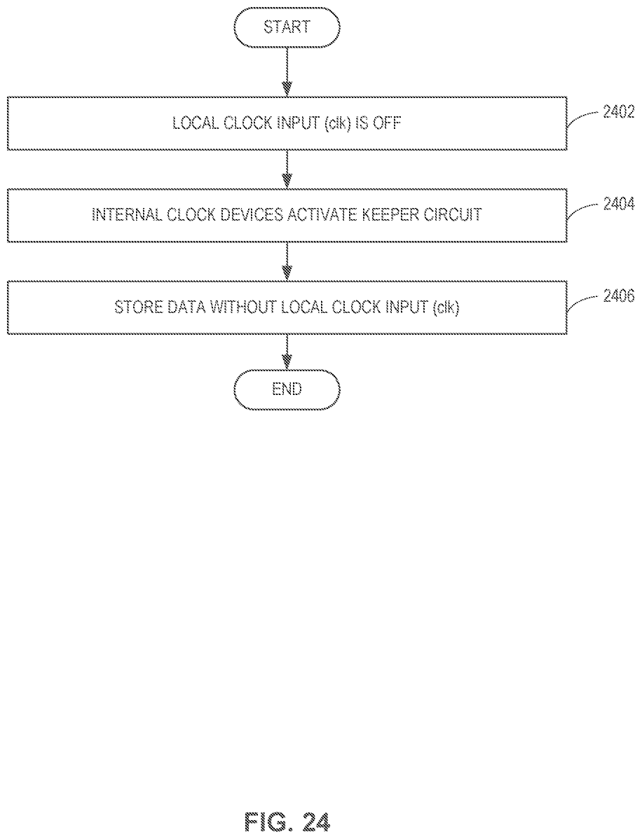

FIG. 24 is a flowchart representative of example operations of the example pseudo-keeperless flip-flop circuit 1400 of FIG. 14 and/or the example pseudo-keeperless flip-flop circuit 1500 of FIG. 15. Input signaling to the example pseudo-keeperless flip-flop circuit 1400 of FIG. 14 and/or the example pseudo-keeperless flip-flop circuit 1500 of FIG. 15 to implement the operations of FIG. 24 may be provided by a timing controller (e.g., the timing controller 508 of FIG. 5 or the timing controller 606 of FIG. 6) and/or any other suitable device. The example pseudo-keeperless flip-flop circuits 1400, 1500 can be operated as described below to store state indefinitely when they are clock gated. The operations of FIG. 24 begin at block 2402 when the local clock input (clk) is off (e.g., the local clock input (clk) is blocked from propagating a clock signal into the example pseudo-keeperless flip-flop circuits 1400, 1500). The intra-flip-flop shared clock devices (e.g., the PMOS transistor clock device 1412, 1512, the NMOS transistor clock device 1414, 1514, and the transmission gate 1416, 1516) that are in circuit with the first latch state node 1406, 1506 and the second latch state node 1408, 1508 activate the keeper circuit 1452, 1542 in the second latch state node 1408, 1508 (block 2404). The first latch state node 1406, 1506 and the second latch state node 1408, 1508 store data without a clock signal from the local clock (clk) (block 2406). For example, the activating of the keeper circuit 1452, 1542 causes the first latch state node 1406, 1506 and the second latch state node 1408, 1508 to store data (e.g., store state) indefinitely without the local clock (clk). The operations of FIG. 24 end.

FIG. 25 is a flowchart representative of example operations of the example asynchronous reset pseudo-keeperless flip-flop circuit 1600 of FIG. 16. Input signaling to the example asynchronous reset pseudo-keeperless flip-flop circuit 1600 to implement the operations of FIG. 25 may be provided by a timing controller (e.g., the timing controller 508 of FIG. 5 or the timing controller 606 of FIG. 6) and/or any other suitable device. The example operations of FIG. 25 may be used to reset the state of the asynchronous reset pseudo-keeperless flip-flop circuit 1600 and force the output (o) to logic level low “0” when the active-low reset signal (rb) transitions to logic level low “0”. This occurs regardless of the state of the local clock input (clk). Therefore, a reset to logic level low “0” at the output (o) can occur if the local clock input (clk) is at logic level low “0” or logic level high “1”.

Turning in detail to example FIG. 25, when the local clock input (clk) is at logic level low “0” (block 2502), the second latch state node 1608 (FIG. 16) is decoupled from the first latch state node 1606 (FIG. 16) (block 2504). When the active-low reset signal (rb) transitions to logic level low “0” (block 2506), the example keeper circuit 1652 (FIG. 16) in the second latch state node 1608 is activated (block 2508). This forces the output (o) of the example asynchronous reset pseudo-keeperless flip-flop circuit 1600 to be at logic level low “0” (block 2510).

As also shown in example FIG. 25, when the local clock input (clk) is at logic level high “1”, and the active-low reset signal (rb), the active-high scan select signal (ss), and the active-low scan select signal (ssb) transition to logic level low “0” (block 2512), this forces node “n1” at the outputs of the first and second tri-state multiplexer circuits 1602, 1604 to logic level high “1” (block 2514). This propagates through the second latch state node 1608, resetting the state of the asynchronous reset pseudo-keeperless flip-flop circuit 1600 and forcing the output (o) to logic level low “0” (block 2516). The example operations of FIG. 25 end.

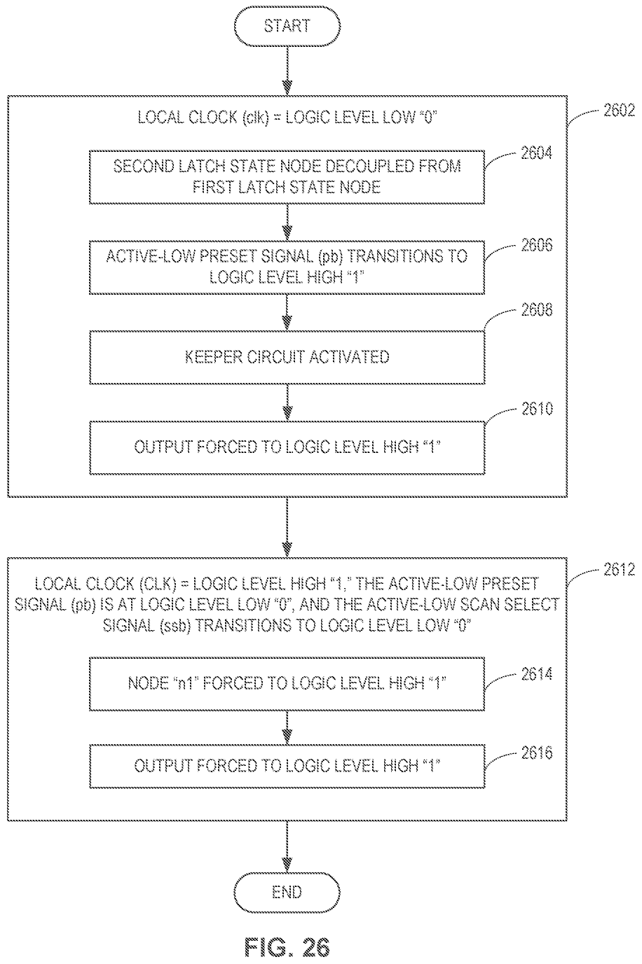

FIG. 26 is a flowchart representative of example operations of the example asynchronous preset pseudo-keeperless flip-flop circuit 1700 of FIG. 17. Input signaling to the example asynchronous preset pseudo-keeperless flip-flop circuit 1700 to implement the operations of FIG. 26 may be provided by a timing controller (e.g., the timing controller 508 of FIG. 5 or the timing controller 606 of FIG. 6) and/or any other suitable device. The example operations of FIG. 25 may be used to preset the state of the example asynchronous preset pseudo-keeperless flip-flop circuit 1700 and force the output (o) to logic level high “1” when the active-high preset signal (p) transitions to logic level high “1”. This occurs regardless of the state of the local clock input (clk). Therefore, a preset to logic level high “1” at the output (o) can occur if the local clock input (clk) is at logic level low “0” or logic level high “1”.

Turning in detail to example FIG. 26, when the local clock input (clk) is at logic level low “0” (block 2602), the second latch state node 1708 (FIG. 17) is decoupled from the first latch state node 1706 (FIG. 17) (block 2604). When the active-high preset signal (p) transitions to logic level high “1” (block 2606), the example keeper circuit 1752 (FIG. 17) in the second latch state node 1708 is activated (block 2608). This forces the output (o) of the example asynchronous preset pseudo-keeperless flip-flop circuit 1700 to be at logic level high “1” (block 2610).

As also shown in FIG. 26, when the local clock input (clk) is at logic level high “1”, the active-high preset signal (p) is at logic level high “1”, and the active-low scan select signal (ssb) transitions to logic level low “0” (block 2612), this forces node “n1” at the outputs of the first and second tri-state multiplexer circuits 1702, 1704 to logic level high “1” (block 2614). This propagates through the second latch state node 1708, resetting the state of the asynchronous preset pseudo-keeperless flip-flop circuit 1700 and forcing the output (o) to logic level high “1” (block 2616). The example operations of FIG. 26 end.

The example operations represented in the flowcharts of FIGS. 22-26 may be implemented using executable instructions (e.g., computer-readable and/or machine-readable instructions) stored on one or more non-transitory computer-readable and/or machine-readable media. As used herein, the terms non-transitory computer-readable medium, non-transitory computer-readable storage medium, non-transitory machine-readable medium, and/or non-transitory machine-readable storage medium are expressly defined to include any type of computer-readable storage device and/or storage disk and to exclude propagating signals and to exclude transmission media. Examples of such non-transitory computer-readable medium, non-transitory computer-readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer-readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer-readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B. (5) A with C. (6) B with C, or (7) A with B and with C. As used herein in the context of describing structures, components, items, objects and/or things, the phrase “at least one of A and B” is intended to refer to implementations including any of (1) at least one A. (2) at least one B, or (3) at least one A and at least one B. Similarly, as used herein in the context of describing structures, components, items, objects and/or things, the phrase “at least one of A or B” is intended to refer to implementations including any of (1) at least one A. (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A. (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that, among other things, reduce contention current in electrical circuits relative to prior circuits. With such reduced contention current, disclosed systems, methods, apparatus, and articles of manufacture improve the efficiency of using a computing device by to reduce power consumption in many circuits including power consumption savings for higher frequency CPUs, graphics, AI accelerators, and any circuits employing deeper pipelines that require more clocking power. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to reduce contention current in electrical circuits are disclosed herein. Further examples and combinations thereof include the following:

Example 1 includes a circuit comprising a read local bitline, and a plurality of pulldown transistor circuits coupled to the read local bitline, a first one of the pulldown transistor circuits including a first low threshold voltage transistor, the first low threshold voltage transistor including a first drain terminal coupled to the read local bitline, and a second low threshold voltage transistor, the second low threshold voltage transistor including a second drain terminal coupled to a first source terminal of the first low threshold voltage transistor, the second low threshold voltage transistor to persist a voltage level detectable at a gate terminal of the second low threshold voltage transistor, the voltage level representative of a bit of information.

Example 2 includes the circuit of example 1, further comprising a keeper circuit and a pre-charge circuit coupled to the read local bitline.

Example 3 includes the circuit of example 2, wherein the plurality of pulldown transistor circuits include at least sixteen pulldown transistor circuits coupled to the read local bitline, the keeper circuit, and the pre-charge circuit.

Example 4 includes the circuit of example 1, further comprising an ultra-low-temperature (ULT) and ultra-low-voltage (ULV) semiconductor material, the ultra-low-temperature (ULT) and ultra-low-voltage (ULV) semiconductor material to include the read local bitline and the plurality of pulldown transistor circuits.

Example 5 includes the circuit of example 1, wherein the first and second low threshold voltage transistors are n-channel metal-oxide semiconductor (NMOS) transistors.

Example 6 includes an apparatus that includes the circuit of example 1, and further including programmable circuitry, a network interface, and a memory controller.

Example 7 includes an integrated circuit chip that includes the circuit of example 1, and further including an interface, and at least one of a register file, a static random access memory, or a read-only-memory.

Example 8 includes a central processing unit that includes the circuit of example 1, and further including an interface, and at least one core.

Example 9 includes a circuit comprising a read local bitline coupled to a pre-charge circuit and a keeper circuit in an ultra-low-voltage and ultra-low-temperature semiconductor device, a timing controller in circuit with the read local bitline, the timing controller to cause the pre-charge circuit to deactivate at a first time, and cause the keeper circuit to be in an inactive state at the first time and to transition to an active state at a second time, the second time to be after the first time, and a buffer in in circuit with the read local bitline, the buffer to store a value read from a pulldown transistor circuit of the read local bitline during an evaluation phase, the evaluation phase to occur between the first time and the second time.

Example 10 includes the circuit of example 9, wherein a first delay duration corresponding to the evaluation phase between the first time and the second time in the ultra-low-voltage and ultra-low-temperature semiconductor device is longer than a second delay duration corresponding to a second evaluation phase employed in a second semiconductor device that does not include ultra-low-voltage and ultra-low-temperature characteristics.

Example 11 includes the circuit of example 9, wherein the keeper circuit is to not generate contention current during the inactive state.

Example 12 includes the circuit of example 9, further comprising a first low threshold voltage transistor coupled to a second low threshold voltage transistor in the pulldown transistor circuit of the read local bitline, the second low threshold voltage transistor to store the value.

Example 13 includes the circuit of example 12, wherein the first and second low threshold voltage transistors have a threshold voltage of 500 millivolts.

Example 14 includes the circuit of example 12, wherein the first and second low threshold voltage transistors have a threshold voltage of 350 millivolts.

Example 15 includes a circuit comprising a read local bitline coupled to a pre-charge circuit in an ultra-low-voltage and ultra-low-temperature semiconductor device, the read local bitline not coupled to a keeper circuit, a timing controller in in circuit with the read local bitline, the timing controller to cause the pre-charge circuit to deactivate at a first time, and cause the pre-charge circuit to transition to an active state at a second time, the second time to be after the first time, and a buffer in circuit with the read local bitline, the buffer to store a value read from a pulldown circuit of the read local bitline during an evaluation phase, the evaluation phase between the first time and the second time.

Example 16 includes the circuit of example 15, further comprising a first low threshold voltage transistor coupled to a second low threshold voltage transistor in the pulldown circuit of the read local bitline, the second low threshold voltage transistor to store the value.

Example 17 includes the circuit of example 16, wherein the first and second low threshold voltage transistors have a threshold voltage of 500 millivolts.

Example 18 includes the circuit of example 17, wherein the first and second low threshold voltage transistors have a threshold voltage of 350 millivolts.

Example 19 includes the circuit of example 15, wherein the ultra-low-voltage and ultra-low-temperature semiconductor device is capable of operating in a temperature range of −40 degrees Celsius and zero degrees Celsius.

Example 20 includes a wordline driver level-shifter circuit comprising a NAND circuit including first input circuitry and second input circuitry, the first input circuitry including first and second transistors, the second input circuitry including a third transistor, a first gate terminal of the first transistor coupled to a second gate terminal of the second transistor to form a first input line of the NAND circuit, a third gate terminal of the third transistor coupled to a second input line of the NAND circuit, and an inverter circuit including fourth and fifth transistors, a fourth gate terminal of the fourth transistor and a fifth gate terminal of the fifth transistor coupled to a source terminal of the first transistor and a drain terminal of the second transistor without being coupled to a keeper circuit.

Example 21 includes the circuit of example 20, wherein the NAND circuit and the inverter circuit are in an ultra-low-voltage and ultra-low-temperature semiconductor device.

Example 22 includes the circuit of example 20, wherein the first transistor is a p-channel metal-oxide semiconductor (PMOS) transistor, the second transistor is an n-channel metal-oxide semiconductor (NMOS) transistor, and the third transistor is an NMOS transistor.

Example 23 includes the circuit of example 20, wherein the first and second transistors are high threshold voltage transistors and the third transistor is a low threshold voltage transistor having a lower threshold voltage than the high threshold voltage transistors.

Example 24 includes the circuit of example 23, wherein a first threshold voltage of the first and second transistors is approximately 350 millivolts and a second threshold voltage of the third transistor is approximately less than 350 millivolts.

Example 25 includes the wordline driver level-shifter circuit of example 20, wherein the first input line is a clock input line and the second input line is a decoded address enable input line.

Example 26 includes a dual-rail wordline driver level-shifter circuit comprising first and second transistors, a first gate terminal of the first transistor coupled to a second gate terminal of the second transistor to form a first input line, a third transistor, a third gate terminal of the third transistor to form a second input line, a first drain terminal of the third transistor coupled to a first source terminal of the second transistor, a cross-coupled keeper circuit including fourth and fifth transistors, a fifth gate terminal of the fifth transistor is coupled to a second source terminal of the fourth transistor and a second drain terminal of the second transistor, a fourth gate terminal of the fourth transistor is coupled to a third source terminal of the fifth transistor, the fifth gate terminal of the fifth transistor coupled to an output line, sixth and seventh transistors, a sixth gate terminal of the sixth transistor coupled to a seventh gate terminal of the seventh transistor and the first input line, and an inverter circuit in circuit between the second input line and an eighth gate terminal of an eighth transistor, a third drain terminal of the eighth transistor coupled to a fourth source terminal of the eighth transistor.

Example 27 includes the circuit of example 26, wherein the fifth gate terminal of the fifth transistor is coupled to the output line via a second inverter circuit.

Example 28 includes the circuit of example 26, wherein the third and eighth transistors are low threshold voltage transistors, the inverter circuit is a low threshold voltage inverter circuit, first threshold voltages of the low threshold voltage transistors and the low threshold voltage inverter circuit being less than second threshold voltages of the first and second transistors.

Example 29 includes the circuit of example 28, wherein the first threshold voltages of the low threshold voltage transistors and the low threshold voltage inverter circuit are approximately less than 350 millivolts, and the second threshold voltages of the first and second transistors are approximately 350 millivolts.

Example 30 includes the circuit of example 26, further comprising an ultra-low-temperature (ULT) and ultra-low-voltage (ULV) semiconductor material.

Example 31 includes the circuit of example 26 to be in a pre-charge phase of a memory when logic level low is applied to the first input line, the fourth gate terminal of the fourth transistor and the fifth gate terminal of the fifth transistor to be at logic level high, and the output line to be at logic level low.

Example 32 includes the circuit of example 31 to be in an evaluation phase of the memory when logic level high is applied to the first input line, and when logic level high is applied to the second input line, the fifth gate terminal of the fifth transistor is at logic level low, the output line to be at logic level high, and the fourth gate terminal of the fourth transistor is maintained at logic level high by the cross-coupled keeper circuit, and when logic level low is applied to the second input line, the fourth gate terminal of the fourth transistor is at logic level low, and the fifth gate terminal of the fifth transistor is maintained at logic level high by the cross-coupled keeper circuit.

Example 33 includes a pseudo-keeperless flip-flop circuit comprising a tri-state multiplexer circuit coupled to an input of the pseudo-keeperless flip-flop circuit, a first latch state node coupled to the tri-state multiplexer circuit, a second latch state node coupled to the first latch state node, the second latch state node including a keeper circuit, a transmission gate in circuit between the first latch state node and the keeper circuit, the transmission gate including first and second clock devices, the first clock device including a first gate terminal, the second clock device including a second gate terminal, the first gate terminal of the first clock device coupled to a third gate terminal of a third clock device, the second gate terminal of the second clock device coupled to a fourth gate terminal of a fourth clock device, and an output line of the pseudo-keeperless flip-flop circuit coupled to the keeper circuit.

Example 34 includes the pseudo-keeperless flip-flop circuit of example 33, wherein the first, second, third, and fourth clock devices are the only clock devices in the pseudo-keeperless flip-flop circuit.

Example 35 includes the pseudo-keeperless flip-flop circuit of example 33, wherein the tri-state multiplexer circuit is a first tri-state multiplexer circuit, the pseudo-keeperless flip-flop circuit further including a second tri-state multiplexer circuit, the first tri-state multiplexer circuit coupled to a source terminal of the third clock device, the second tri-state multiplexer circuit coupled to a drain terminal of the fourth clock device.

Example 36 includes the pseudo-keeperless flip-flop circuit of example 33, wherein the first latch state node includes first and second inverter circuits in circuit between the tri-state multiplexer circuit and the transmission gate.

Example 37 includes the pseudo-keeperless flip-flop circuit of example 33, wherein the first latch state node includes first, second, and third inverter circuits in circuit between the tri-state multiplexer circuit and the transmission gate, the first inverter circuit coupled to a source terminal of the third clock device and a drain terminal of the fourth clock device.

Example 38 includes the pseudo-keeperless flip-flop circuit of example 33, wherein the first and third clock devices include PMOS transistors, and the second and fourth clock devices include NMOS transistors.

Example 39 includes the pseudo-keeperless flip-flop circuit of example 33, further comprising an active-low reset circuit coupled to an output of the tri-state multiplexer circuit and an input of the first latch state node.

Example 40 includes the pseudo-keeperless flip-flop circuit of example 33, further comprising an active-low preset circuit coupled to an output of the tri-state multiplexer circuit and an input of the first latch state node.

Example 41 includes a method performed by a computer comprising deactivating a pre-charge circuit of a read local bitline in an ultra-low-voltage and ultra-low-temperature semiconductor device after a pre-charge phase, and substantially eliminating contention current during an evaluation phase by maintaining a keeper circuit of the read local bitline inactive for a duration.

Example 42 includes the method of example 41, further comprising storing a value read from a pulldown transistor circuit of the read local bitline during the evaluation phase.

Example 43 includes the method of example 41, further comprising, after the duration and the evaluation phase, activating the keeper circuit.

Example 44 includes the method of example 41, wherein the duration is an m-inverters delay, the duration being for a signal to propagate through a number of inverters connected in series, the number of inverters selected as one of: seven inverters, eight inverters, or nine inverters.

Example 45 includes an apparatus comprising means for performing a method of any one or more of examples 41-44.

Example 46 includes machine-readable storage including machine-readable instructions which, when executed, cause a computer to implement a method of any one or more of examples 41-44.

Example 47 includes a computer program comprising instructions which, when the program is executed by a computer, cause the computer to carry out the method of any one or more of examples 41-44.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. A circuit comprising:
a read local bitline; and
a plurality of pulldown transistor circuits coupled to the read local bitline, a first one of the pulldown transistor circuits including:
a first low threshold voltage transistor, the first low threshold voltage transistor including a first drain terminal coupled to the read local bitline; and
a second low threshold voltage transistor, the second low threshold voltage transistor including a second drain terminal coupled to a first source terminal of the first low threshold voltage transistor, the second low threshold voltage transistor to persist a voltage level detectable at a gate terminal of the second low threshold voltage transistor, the voltage level representative of a bit of information.

2. The circuit of claim 1, further comprising a keeper circuit and a pre-charge circuit coupled to the read local bitline.

3. The circuit of claim 2, wherein the plurality of pulldown transistor circuits include at least sixteen pulldown transistor circuits coupled to the read local bitline, the keeper circuit, and the pre-charge circuit.

4. The circuit of claim 1, further comprising an ultra-low-temperature (ULT) and ultra-low-voltage (ULV) semiconductor material, the ultra-low-temperature (ULT) and ultra-low-voltage (ULV) semiconductor material to include the read local bitline and the plurality of pulldown transistor circuits.

5. The circuit of claim 1, wherein the first and second low threshold voltage transistors are n-channel metal-oxide semiconductor (NMOS) transistors.

6. An apparatus that includes the circuit of claim 1, and further including:
programmable circuitry;
a network interface; and
a memory controller.

7. An integrated circuit chip that includes the circuit of claim 1, and further including:
an interface; and
at least one of a register file, a static random access memory, or a read-only-memory.

8. A central processing unit that includes the circuit of claim 1, and further including:
an interface; and
at least one core.

9. A circuit comprising:
a read local bitline coupled to a pre-charge circuit and a keeper circuit in an ultra-low-voltage and ultra-low-temperature semiconductor device;
a timing controller in circuit with the read local bitline, the timing controller to:
cause the pre-charge circuit to deactivate at a first time; and
cause the keeper circuit to be in an inactive state at the first time and to transition to an active state at a second time, the second time to be after the first time;
and
a buffer in in circuit with the read local bitline, the buffer to store a value read from a pulldown transistor circuit of the read local bitline during an evaluation phase, the evaluation phase to occur between the first time and the second time.

10. The circuit of claim 9, wherein a first delay duration corresponding to the evaluation phase between the first time and the second time in the ultra-low-voltage and ultra-low-temperature semiconductor device is longer than a second delay duration corresponding to a second evaluation phase employed in a second semiconductor device that does not include ultra-low-voltage and ultra-low-temperature characteristics.

11. The circuit of claim 9, wherein the keeper circuit is to not generate contention current during the inactive state.

12. The circuit of claim 9, further comprising a first low threshold voltage transistor coupled to a second low threshold voltage transistor in the pulldown transistor circuit of the read local bitline, the second low threshold voltage transistor to store the value.

13. The circuit of claim 12, wherein the first and second low threshold voltage transistors have a threshold voltage of 500 millivolts.

14. The circuit of claim 12, wherein the first and second low threshold voltage transistors have a threshold voltage of 350 millivolts.

15-19. (canceled)

20. A wordline driver level-shifter circuit comprising:
a NAND circuit including first input circuitry and second input circuitry, the first input circuitry including first and second transistors, the second input circuitry including a third transistor, a first gate terminal of the first transistor coupled to a second gate terminal of the second transistor to form a first input line of the NAND circuit, a third gate terminal of the third transistor coupled to a second input line of the NAND circuit; and
an inverter circuit including fourth and fifth transistors, a fourth gate terminal of the fourth transistor and a fifth gate terminal of the fifth transistor coupled to a source terminal of the first transistor and a drain terminal of the second transistor without being coupled to a keeper circuit.

21. The circuit of claim 20, wherein the NAND circuit and the inverter circuit are in an ultra-low-voltage and ultra-low-temperature semiconductor device.

22. The circuit of claim 20, wherein the first transistor is a p-channel metal-oxide semiconductor (PMOS) transistor, the second transistor is an n-channel metal-oxide semiconductor (NMOS) transistor, and the third transistor is an NMOS transistor.

23. The circuit of claim 20, wherein the first and second transistors are high threshold voltage transistors and the third transistor is a low threshold voltage transistor having a lower threshold voltage than the high threshold voltage transistors.

24. The circuit of claim 23, wherein a first threshold voltage of the first and second transistors is approximately 350 millivolts and a second threshold voltage of the third transistor is approximately less than 350 millivolts.

25. The wordline driver level-shifter circuit of claim 20, wherein the first input line is a clock input line and the second input line is a decoded address enable input line.

26-47. (canceled)
